(19) United States
(12) Patent Application Publication
(10) Pub. No.: US 2013/0256644 A1
(43) Pub. Date: Oct. 3, 2013

(54) COMPOUND FOR ORGANIC OPTOELECTRONIC DEVICE, ORGANIC LIGHT EMITTING DIODE INCLUDING THE SAME AND DISPLAY INCLUDING THE ORGANIC LIGHT EMITTING DIODE

(71) Applicants: Hyung-Sun KIM, Uiwang-si (KR); Soo-Hyun MIN, Uiwang-si (KR); Eun-Sun YU, Uiwang-si (KR); Mi-Young CHAE, Uiwang-si (KR)

(72) Inventors: Hyung-Sun KIM, Uiwang-si (KR); Soo-Hyun MIN, Uiwang-si (KR); Eun-Sun YU, Uiwang-si (KR); Mi-Young CHAE, Uiwang-si (KR)

(21) Appl. No.: 13/908,075

(22) Filed: Jun. 3, 2013

Related U.S. Application Data
(63) Continuation of application No. PCT/KR2011/007538, filed on Oct. 11, 2011.

(30) Foreign Application Priority Data
Dec. 1, 2010 (KR) 10-2010-0121440

(51) Int. Cl. H01L 51/00; H01L 51/50

(52) U.S. Cl. CPC H01L 51/0071; H01L 51/0054; H01L 51/50
USPC 257/40; 546/276.7; 544/331

(57) ABSTRACT

A compound for an organic optoelectronic device, the compound being represented by the following Chemical Formula 1:

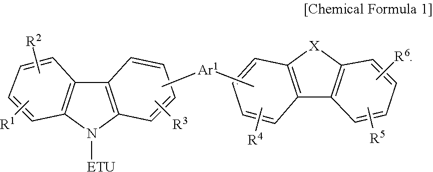

### CROSS-REFERENCE TO RELATED APPLICATIONS

This application is a continuation of pending International Application No. PCT/KR2011/007538, entitled “Compound for Organic Optoelectronic Device, Organic Light Emitting Diode including the Same and Display including the Organic Light Emitting Diode,” which was filed on Oct. 11, 2011, the entire contents of which are incorporated herein by reference.

This application claims the benefit of and priority under 35 U.S.C. §119 to Korean Patent Application No. 10-2010-0121440, filed on Dec. 1, 2010, in the Korean Intellectual Property Office, and entitled: “Compound for Organic Optoelectronic Device, Organic Light Emitting Diode including the Same and Display including the Organic Light Emitting Diode,” which is incorporated by reference herein in its entirety.

### BACKGROUND

1. Field

Embodiments relate to a compound for organic optoelectronic device, an organic light emitting diode including the same, and a display including the organic light emitting diode.

2. Description of the Related Art

An organic photoelectric device is a device using a charge exchange between an electrode and an organic material by using holes or electrons. An organic optoelectronic device may be an electronic device driven as follows: excitons are generated in an organic material layer by photons from an external light source; the excitons are separated into electrons and holes; and the electrons and holes are transferred to different electrodes as a current source (voltage source). An organic optoelectronic device may be an electronic device driven as follows: a voltage or a current is applied to at least two electrodes to inject holes and/or electrons into an organic material semiconductor positioned at an interface of the electrodes, and the device is driven by the injected electrons and holes.

Examples of an organic optoelectronic device include an organic photoelectric device, an organic light emitting diode (OLED), an organic solar cell, an organic photo conductor drum, an organic transistor, and the like, which use a hole injecting or transport material, an electron injecting or transport material, or a light emitting material. The organic light emitting diode (OLED) has recently drawn attention due to an increase in demand for flat panel displays. In general, organic light emission refers to conversion of electrical energy into photo-energy.

### SUMMARY

Embodiments are directed to a compound for an organic optoelectronic device, the compound being represented by the following Chemical Formula 1:

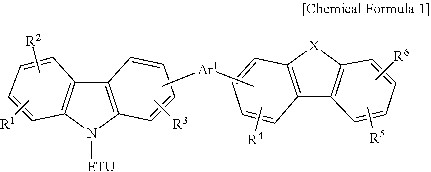

In the above Chemical Formula 1,

X may be S, O, or Se,

ETU may be a substituted or unsubstituted C2 to C30 heteroaryl group having electron characteristics,

Ar¹ may be a substituted or unsubstituted C6 to C30 aryl group; or a substituted or unsubstituted C2 to C30 heteroaryl group, and

R¹ to R⁶ may each independently be hydrogen; deuterium; a substituted or unsubstituted C1 to C20 alkyl group; a substituted or unsubstituted C6 to C30 aryl group; or a substituted or unsubstituted C2 to C30 heteroaryl group having electron characteristics.

Embodiments are also directed to a compound for an organic optoelectronic device, the compound being represented by the following Chemical Formula 3:

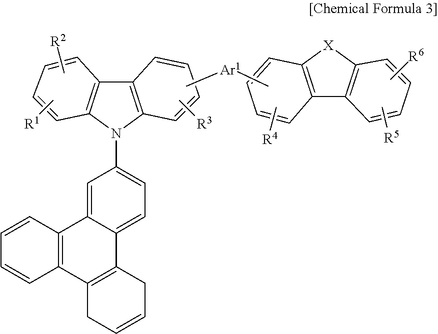

In the above Chemical Formula 3,

X may be S, O, or Se,

Ar¹ may be a substituted or unsubstituted C6 to C30 aryl group; or a substituted or unsubstituted C2 to C30 heteroaryl group, and

R¹ to R⁶ may each independently be hydrogen; deuterium; a substituted or unsubstituted C1 to C20 alkyl group; a substituted or unsubstituted C6 to C30 aryl group; or a substituted or unsubstituted C2 to C30 heteroaryl group having electron characteristics.

Embodiments are also directed to an organic light emitting diode, including an anode, a cathode, and at least one organic thin layer between the anode and the cathode. The at least one organic thin layer may include a compound for an organic optoelectronic device according to an embodiment.

Embodiments are also directed to a display device including an organic light emitting diode according to an embodiment.

### BRIEF DESCRIPTION OF THE DRAWINGS

Features will become apparent to those of skill in the art by describing in detail exemplary embodiments with reference to the attached drawings in which:

FIGS. 1 to 5 illustrate cross-sectional views showing organic light emitting diodes according to various example embodiments including a compound for an organic optoelectronic device according to an example embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art. In the drawing figures, the dimensions of layers and regions may be exaggerated for clarity of illustration. Like reference numerals refer to like elements throughout.

In the present specification, when specific definition is not otherwise provided, the term “substituted” refers to one substituted with a C1 to C30 alkyl group; a C1 to C10 alkylsilyl group; a C3 to C30 cycloalkyl group; a C6 to C30 aryl group; a C2 to C30 heteroaryl group; a C1 to C10 alkoxy group; a fluoro group, a C1 to C10 trifluoro alkyl group such as trifluoromethyl group; or a cyano group.

In the present specification, when specific definition is not otherwise provided, the term “hetero” refers to one including 1 to 3 heteroatoms selected from the group consisting of N, O, S, and P, and remaining carbons in one compound.

In the specification, when a definition is not otherwise provided, “alkyl group” may refer to “a saturated group” without any alkene group or alkyne group.

The alkyl group may be a C1 to C20 alkyl group, and specifically a C1 to C6 lower alkyl group, a C7 to C10 medium-sized alkyl group, or a C11 to C20 higher alkyl group.

For example, a C1 to C4 alkyl group may have 1 to 4 carbon atoms and may be selected from the group consisting of methyl, ethyl, propyl, iso-propyl, n-butyl, iso-butyl, sec-butyl, and t-butyl.

Typical examples of alkyl group may be a methyl group, an ethyl group, a propyl group, an isopropyl group, a butyl group, an isobutyl group, a t-butyl group, a pentyl group, a hexyl group, a cyclopropyl group, a cyclobutyl group, a cyclopentyl group, a cyclohexyl group, and the like.

The “alkene group” may refer to a substituent of at least one carbon-carbon double bond of at least two carbons, and the “alkyne group” may refer to a substituent of at least one carbon-carbon triple bond of at least two carbons. The alkyl group may be branched, linear, or cyclic.

“Aromatic group” may refer to a substituent including all element of the cycle having p-orbitals which form conjugation. Examples may include an aryl group and a heteroaryl group.

“Aryl group” may refer to a monocyclic or fused ring polycyclic (i.e., rings sharing adjacent pairs of carbon atoms) substituent.

“Heteroaryl group” may refer to an aryl group including 1 to 3 heteroatoms selected from the group consisting of N, O, S, and P, and remaining carbons in one functional group. The aryl group may be a fused ring cyclic group where each cycle may include the 1 to 3 heteroatoms.

In the aryl group and heteroaryl group, the number of cyclic group is a sum of numbers of carbon and non-carbon.

A compound for an organic optoelectronic device according to an example embodiment may include a core moiety including two carbazole or carbazole-based derivatives bonded to each other and a substituent selectively bonded to the core moiety.

In this specification, the carbazole-based derivative may refer to a structure where nitrogen of a substituted or unsubstituted carbazole or carbazolyl group is substituted with a heteroatom except nitrogen. The heteroatom may be O, P, S, or Se.

At least one of the substituents bonded to the core part may be a substituent having excellent electronic properties.

Accordingly, the compound may satisfy requirements of an emission layer by complementing excellent hole characteristics of its carbazole structure with electronic properties. In an implementation, the compound may be used as a host material for an emission layer.

The hole characteristics refer to characteristics that holes from the anode are easily injected into the emission layer and transported in the emission layer due to conductive characteristics according to HOMO level.

The electron characteristics refer to characteristics that electrons from the cathode are easily injected into the emission layer and transported in the emission layer due to conductive characteristics according to LUMO level.

The compound for an organic optoelectronic device may include a core moiety and various substituents for substituting the core moiety, and thus may have various energy bandgaps. Accordingly, the compound may be used in an electron injection layer (EIL) and transport layer, or a hole injection layer (HIL) and transport layer.

The compound may have an appropriate energy level depending on the substituents and thus, may have similar hole transport rate to electron transport rate and bring about excellent effects on efficiency and driving voltage and also, have excellent electrochemical and thermal stability and thus, improve life-span characteristics during the operation of the organic photoelectric device.

According to an example embodiment, a compound represented by the following Chemical Formula 1 for an organic optoelectronic device is provided.

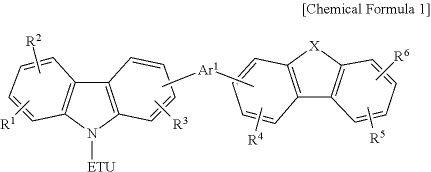

In the above Chemical Formula 1, X may be S, O, or Se. ETU may be a substituted or unsubstituted C2 to C30 heteroaryl group having electron characteristics. Ar¹ may be a substituted or unsubstituted C6 to C30 aryl group; or a substituted or unsubstituted C2 to C30 heteroaryl group. R¹ to R⁶ may each independently be hydrogen; deuterium; a substituted or unsubstituted C1 to C20 alkyl group; a substituted or unsubstituted C6 to C30 aryl group; or a substituted or unsubstituted C2 to C30 heteroaryl group having electron characteristics.

The compound represented by the above Chemical Formula 1 may include a carbazole and/or a carbazole-based derivative having bi-polar characteristics as a core.

A substituent having a pi-bond (π-bond) of the R¹ to R⁶ may increase a triplet energy bandgap by controlling the total π-conjugation length of compound, which may enhance the characteristics thereof when applied to the emission layer of organic photoelectric device as phosphorescent host.

In addition, the substituents may be selected to provide a compound having excellent thermal stability or resistance against oxidation.

The substituents may be selected to provide a compound having asymmetric bi-polar characteristics. The asymmetric bipolar characteristics may improve hole and electron transport capability and thus, luminous efficiency and performance of a device.

In addition, the substituents may be selected to make the structure of a compound bulky and thus, decrease crystallinity of the compound. Accordingly, the compound may have low crystallinity and may thus improve life-span of a device.

As described above, the ETU of substituents of the compound may be a substituted or unsubstituted C2 to C30 heteroaryl group having electron characteristics.

The substituted or unsubstituted C2 to C30 heteroaryl group having electron characteristics may include a substituted or unsubstituted imidazolyl group, a substituted or unsubstituted triazolyl group, a substituted or unsubstituted tetrazolyl group, a substituted or unsubstituted oxadiazolyl group, a substituted or unsubstituted oxatriazolyl group, a substituted or unsubstituted thiatriazolyl group, a substituted or unsubstituted benzimidazolyl group, a substituted or unsubstituted benzotriazolyl group, a substituted or unsubstituted pyridinyl group, a substituted or unsubstituted pyrimidinyl group, a substituted or unsubstituted triazinyl group, a substituted or unsubstituted pyrazinyl group, a substituted or unsubstituted pyridazinyl group, a substituted or unsubstituted purinyl group, a substituted or unsubstituted quinolinyl group, a substituted or unsubstituted isoquinolinyl group, a substituted or unsubstituted phthalazinyl group, a substituted or unsubstituted naphpyridinyl group, a substituted or unsubstituted quinoxalinyl group, a substituted or unsubstituted quinazolinyl group, a substituted or unsubstituted acridinyl group, a substituted or unsubstituted phenanthrolinyl group, a substituted or unsubstituted phenazinyl group, or a combination thereof.

In another example embodiment, a compound for an organic optoelectronic device represented by the following Chemical Formula 2-1 or 2-2 is provided.

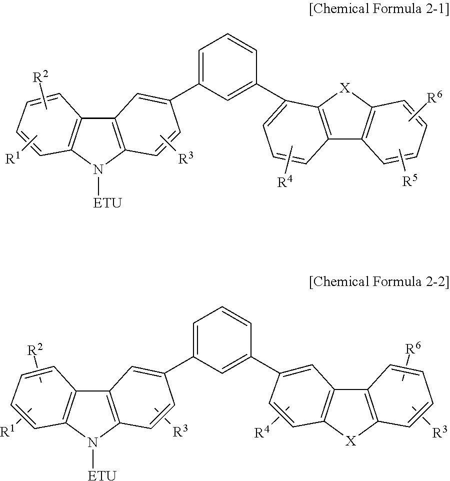

In the above Chemical Formulae 2-1 and 2-2, X may be S, O, or Se. ETU may be a substituted or unsubstituted C2 to C30 heteroaryl group having electron characteristics. R¹ to R⁶ may each independently be hydrogen; deuterium; a substituted or unsubstituted C1 to C20 alkyl group; a substituted or unsubstituted C6 to C30 aryl group; or a substituted or unsubstituted C2 to C30 heteroaryl group having electron characteristics.

The above Chemical Formula 2 has a structure where a phenyl group is provided in the core, and binding positions of both carbazolyl groups or carbazole-based derivative are set. Such a structure may provide an appropriate energy band and provide easy synthesis. Additional substituents having electron transfer/transport characteristics may be introduced.

The substituent having electron characteristics is the same as described in the above Chemical Formula 1 and thus details thereof are not repeated.

In another example embodiment, a compound for an organic optoelectronic device represented by the following Chemical Formula 3 is provided.

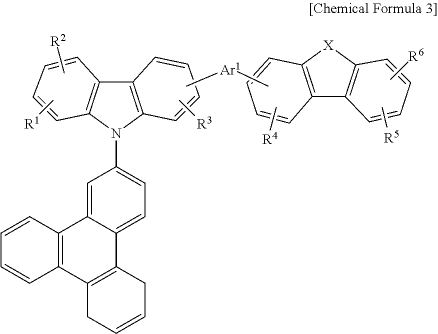

In the above Chemical Formula 3, X may be S, O, or Se. Ar¹ may be a substituted or unsubstituted C6 to C30 aryl group; or a substituted or unsubstituted C2 to C30 heteroaryl group. R¹ to R⁶ may each independently be hydrogen; deuterium; a substituted or unsubstituted C1 to C20 alkyl group; a substituted or unsubstituted C6 to C30 aryl group; or a substituted or unsubstituted C2 to C30 heteroaryl group having electron characteristics.

The above Chemical Formula 3 may have a structure having a triphenylenyl group compared with the above Chemical Formula 1.

In the compound, the triphenylenyl group may provide a bulky structure and cause a resonance effect and thus, may suppress a side reaction possibly occurring in a solid state and may improve performance of an organic light emitting diode.

In addition, the triphenylenyl group may make the compound bulky and thus, may have an effect on lowering crystallinity and increasing life-span.

The triphenylenyl group may provide a wider band gap and high triplet excitation energy. The triphenylenyl group may be bonded with carbazole without a decrease in the band gap or triplet excitation energy of the compound.

The Ar¹ may be a substituted or unsubstituted phenylene group, a substituted or unsubstituted biphenylene group, a substituted or unsubstituted naphthylene group, or a combination thereof. In this case, the compound may have improved thermal stability and oxidation stability.

The Ar¹ may be a substituted or unsubstituted pyridinylene group, a substituted or unsubstituted pyrimidinylene group, a substituted or unsubstituted triazinylene group, or a combination thereof. In this case, the compound may have fortified electron transfer and transport characteristics.

The compound for an organic optoelectronic device may be represented by the following Chemical Formula 4-1 or 4-2.

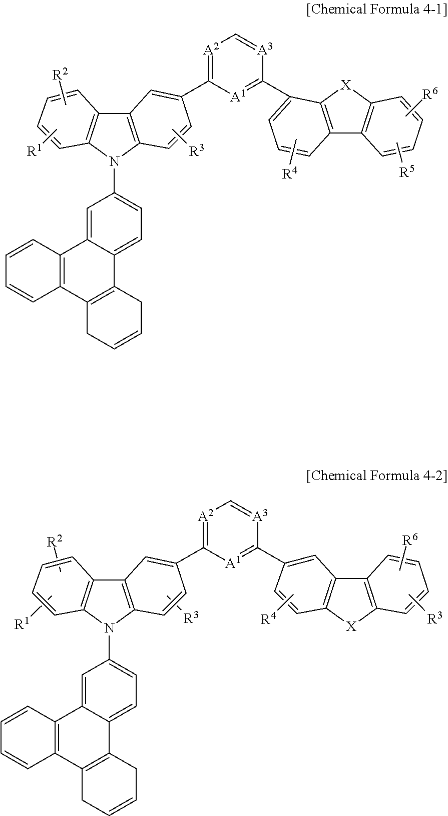

In the above Chemical Formulae 4-1 and 4-2, X may be S, O, or Se. A¹ to A³ may each independently be CR′ or a heteroatom. R′ and R¹ to R⁶ may each independently be hydrogen; deuterium; a substituted or unsubstituted C1 to C20 alkyl group; a substituted or unsubstituted C6 to C30 aryl group; or a substituted or unsubstituted C2 to C30 heteroaryl group having electron characteristics.

The structures where a substituent of Ar¹ is a 6-membered arylene or heteroarylene in the above Chemical Formula 3 may minimize energy level change of the compound and may provide easy synthesis.

In addition, the bonds as in the above Chemical Formula 4-1 or 4-2 may minimize energy level change of the compound and may provide easy synthesis.

The A¹ to A³ may each independently be CR′ or a nitrogen atom. In an implementation, at least one of A¹ to A³ may be nitrogen. In this case, more improved bipolar characteristics may be provided.

The compound for an organic optoelectronic device may be represented by one of the following Chemical Formulae (CF) 1a to 144a. However, it is not limited to the following compounds.

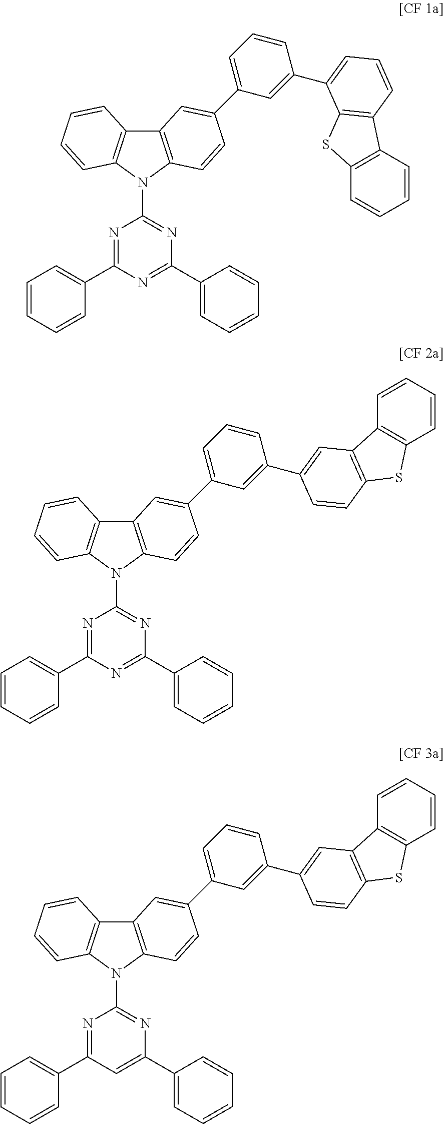 [SMILES: c1ccc(-c2nc(-c3ccccc3)nc(-n3c4ccccc4c4cc(-c5cccc(-c6cccc7c6sc6ccccc67)c5)ccc43)n2)cc1 ; c1ccc(-c2nc(-c3ccccc3)nc(-n3c4ccccc4c4cc(-c5cccc(-c6ccc7sc8ccccc8c7c6)c5)ccc43)n2)cc1 ; c1ccc(-c2cc(-c3ccccc3)nc(-n3c4ccccc4c4cc(-c5cccc(-c6ccc7sc8ccccc8c7c6)c5)ccc43)n2)cc1]

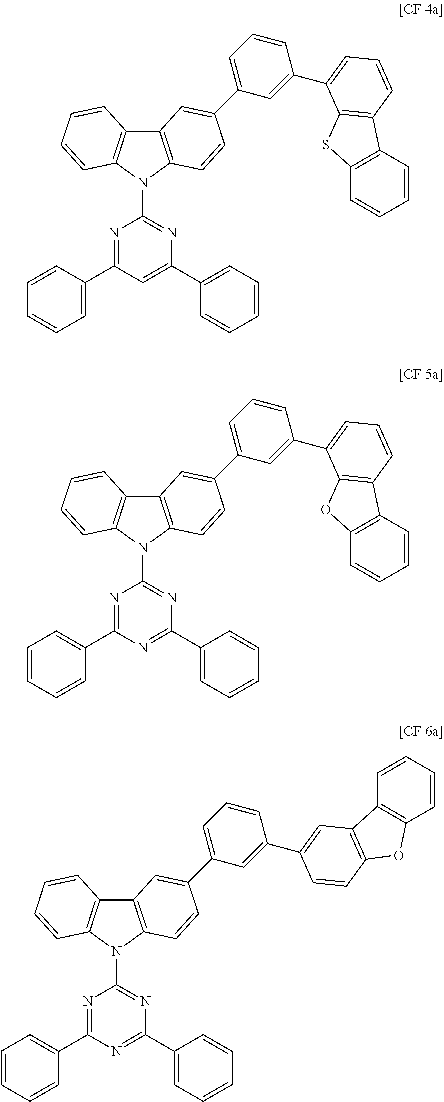 [SMILES: c1ccc(-c2cc(-c3ccccc3)nc(-n3c4ccccc4c4cc(-c5cccc(-c6cccc7c6sc6ccccc67)c5)ccc43)n2)cc1 ; c1ccc(-c2nc(-c3ccccc3)nc(-n3c4ccccc4c4cc(-c5cccc(-c6cccc7c6oc6ccccc67)c5)ccc43)n2)cc1 ; c1ccc(-c2nc(-c3ccccc3)nc(-n3c4ccccc4c4cc(-c5cccc(-c6ccc7oc8ccccc8c7c6)c5)ccc43)n2)cc1]

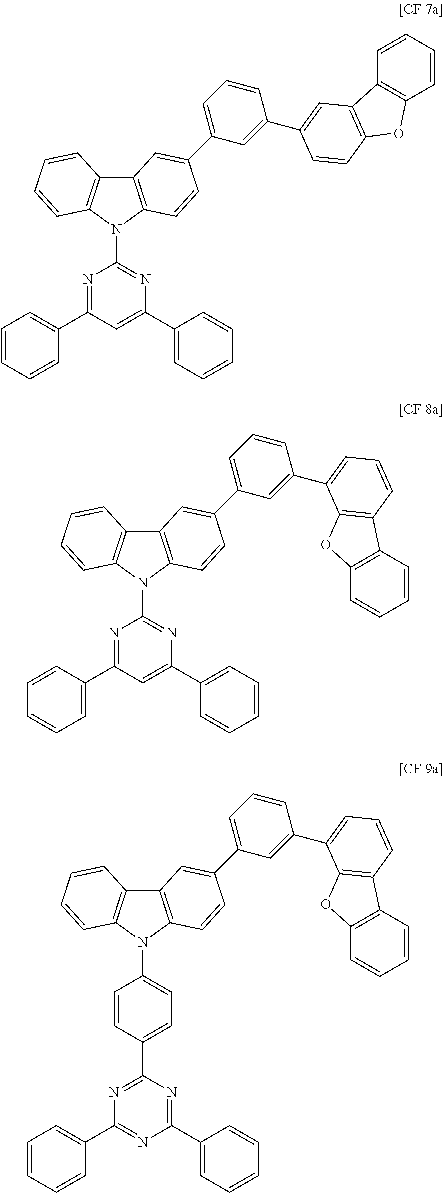 [SMILES: c1ccc(-c2cc(-c3ccccc3)nc(-n3c4ccccc4c4cc(-c5cccc(-c6ccc7oc8ccccc8c7c6)c5)ccc43)n2)cc1 ; c1ccc(-c2cc(-c3ccccc3)nc(-n3c4ccccc4c4cc(-c5cccc(-c6cccc7c6oc6ccccc67)c5)ccc43)n2)cc1 ; c1ccc(-c2nc(-c3ccccc3)nc(-c3ccc(-n4c5ccccc5c5cc(-c6cccc(-c7cccc8c7oc7ccccc78)c6)ccc54)cc3)n2)cc1]

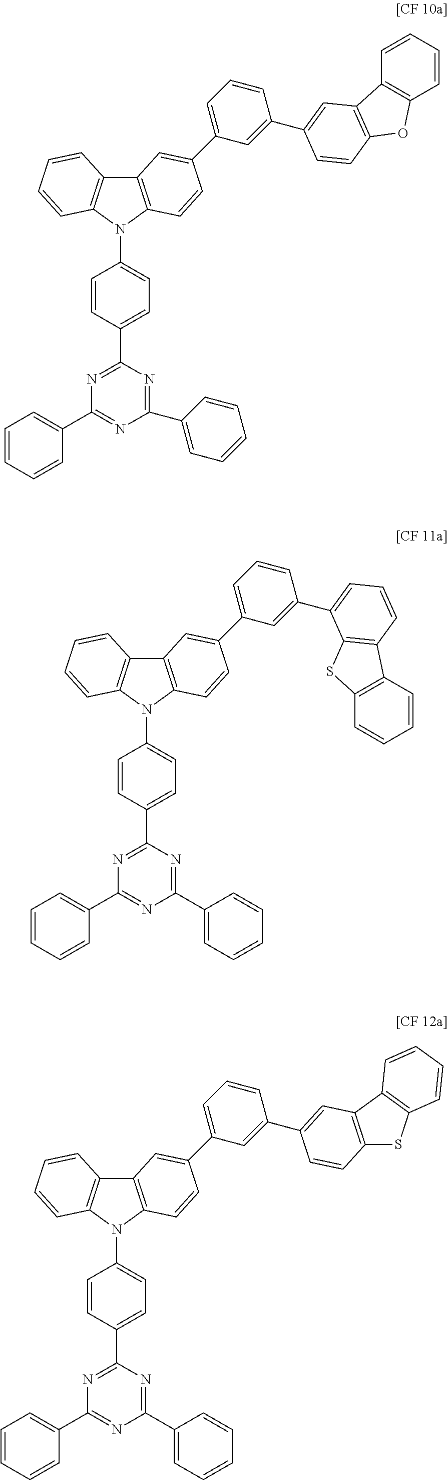 [SMILES: c1ccc(-c2nc(-c3ccccc3)nc(-c3ccc(-n4c5ccccc5c5cc(-c6cccc(-c7ccc8oc9ccccc9c8c7)c6)ccc54)cc3)n2)cc1 ; c1ccc(-c2nc(-c3ccccc3)nc(-c3ccc(-n4c5ccccc5c5cc(-c6cccc(-c7cccc8c7sc7ccccc78)c6)ccc54)cc3)n2)cc1 ; c1ccc(-c2nc(-c3ccccc3)nc(-c3ccc(-n4c5ccccc5c5cc(-c6cccc(-c7ccc8sc9ccccc9c8c7)c6)ccc54)cc3)n2)cc1]

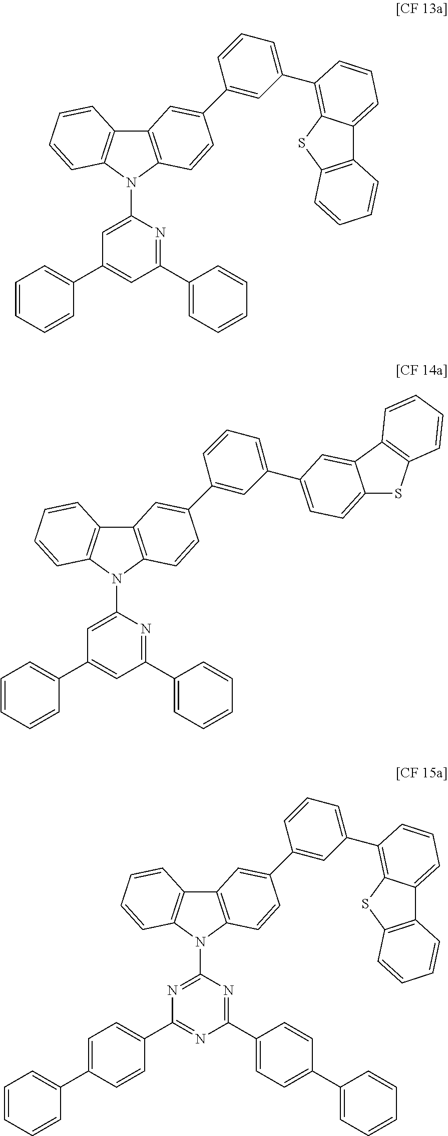 [SMILES: c1ccc(-c2cc(-c3ccccc3)nc(-n3c4ccccc4c4cc(-c5cccc(-c6cccc7c6sc6ccccc67)c5)ccc43)c2)cc1 ; c1ccc(-c2cc(-c3ccccc3)nc(-n3c4ccccc4c4cc(-c5cccc(-c6ccc7sc8ccccc8c7c6)c5)ccc43)c2)cc1 ; c1ccc(-c2ccc(-c3nc(-c4ccc(-c5ccccc5)cc4)nc(-n4c5ccccc5c5cc(-c6cccc(-c7cccc8c7sc7ccccc78)c6)ccc54)n3)cc2)cc1]

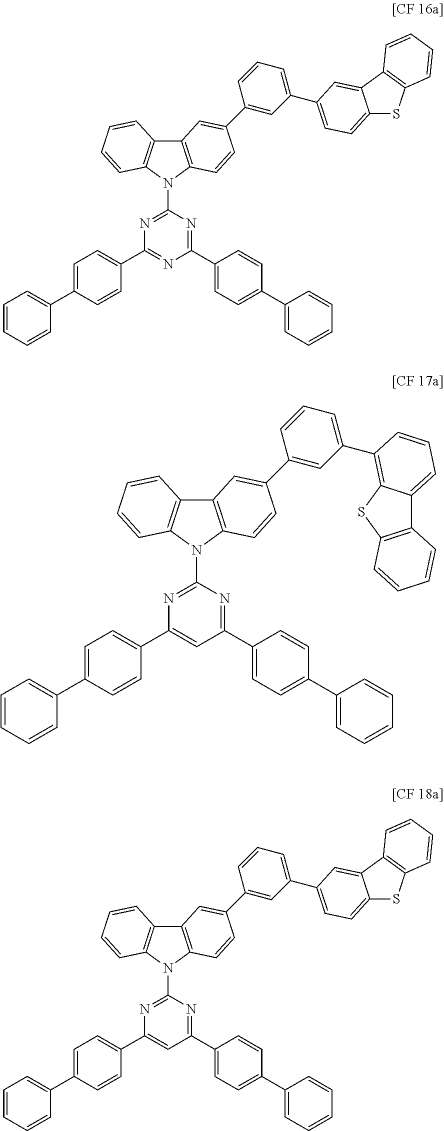 [SMILES: c1ccc(-c2ccc(-c3nc(-c4ccc(-c5ccccc5)cc4)nc(-n4c5ccccc5c5cc(-c6cccc(-c7ccc8sc9ccccc9c8c7)c6)ccc54)n3)cc2)cc1 ; c1ccc(-c2ccc(-c3cc(-c4ccc(-c5ccccc5)cc4)nc(-n4c5ccccc5c5cc(-c6cccc(-c7cccc8c7sc7ccccc78)c6)ccc54)n3)cc2)cc1 ; c1ccc(-c2ccc(-c3cc(-c4ccc(-c5ccccc5)cc4)nc(-n4c5ccccc5c5cc(-c6cccc(-c7ccc8sc9ccccc9c8c7)c6)ccc54)n3)cc2)cc1]

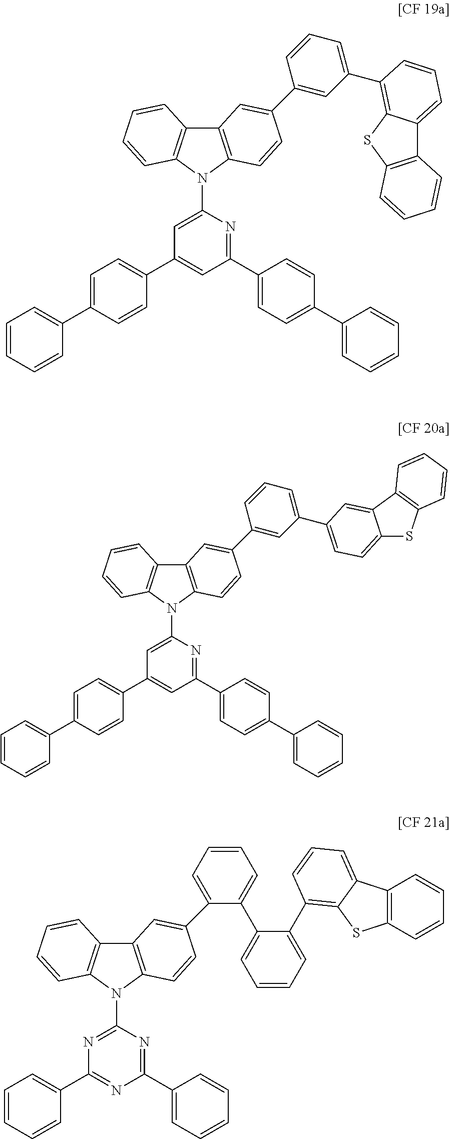 [SMILES: c1ccc(-c2ccc(-c3cc(-c4ccc(-c5ccccc5)cc4)nc(-n4c5ccccc5c5cc(-c6cccc(-c7cccc8c7sc7ccccc78)c6)ccc54)c3)cc2)cc1 ; c1ccc(-c2ccc(-c3cc(-c4ccc(-c5ccccc5)cc4)nc(-n4c5ccccc5c5cc(-c6cccc(-c7ccc8sc9ccccc9c8c7)c6)ccc54)c3)cc2)cc1 ; c1ccc(-c2nc(-c3ccccc3)nc(-n3c4ccccc4c4cc(-c5ccccc5-c5ccccc5-c5cccc6c5sc5ccccc56)ccc43)n2)cc1]

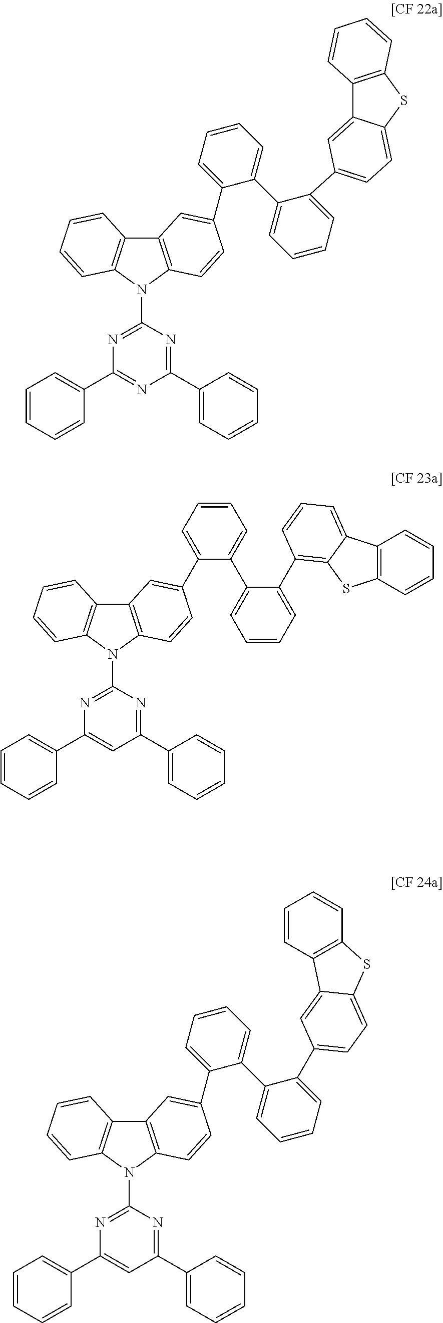 [SMILES: c1ccc(-c2nc(-c3ccccc3)nc(-n3c4ccccc4c4cc(-c5ccccc5-c5ccccc5-c5ccc6sc7ccccc7c6c5)ccc43)n2)cc1 ; c1ccc(-c2cc(-c3ccccc3)nc(-n3c4ccccc4c4cc(-c5ccccc5-c5ccccc5-c5cccc6c5sc5ccccc56)ccc43)n2)cc1 ; c1ccc(-c2cc(-c3ccccc3)nc(-n3c4ccccc4c4cc(-c5ccccc5-c5ccccc5-c5ccc6sc7ccccc7c6c5)ccc43)n2)cc1]

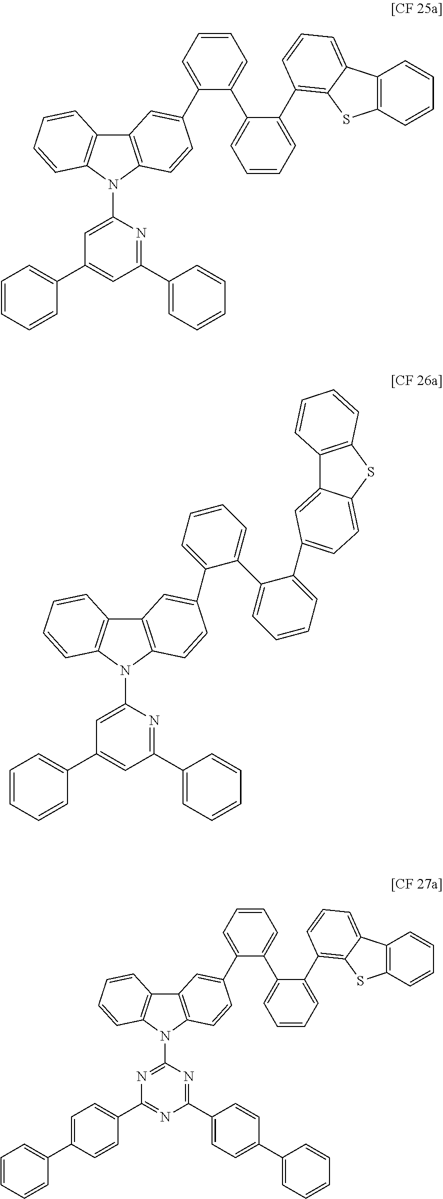 [SMILES: c1ccc(-c2cc(-c3ccccc3)nc(-n3c4ccccc4c4cc(-c5ccccc5-c5ccccc5-c5cccc6c5sc5ccccc56)ccc43)c2)cc1 ; c1ccc(-c2cc(-c3ccccc3)nc(-n3c4ccccc4c4cc(-c5ccccc5-c5ccccc5-c5ccc6sc7ccccc7c6c5)ccc43)c2)cc1 ; c1ccc(-c2ccc(-c3nc(-c4ccc(-c5ccccc5)cc4)nc(-n4c5ccccc5c5cc(-c6ccccc6-c6ccccc6-c6cccc7c6sc6ccccc67)ccc54)n3)cc2)cc1]

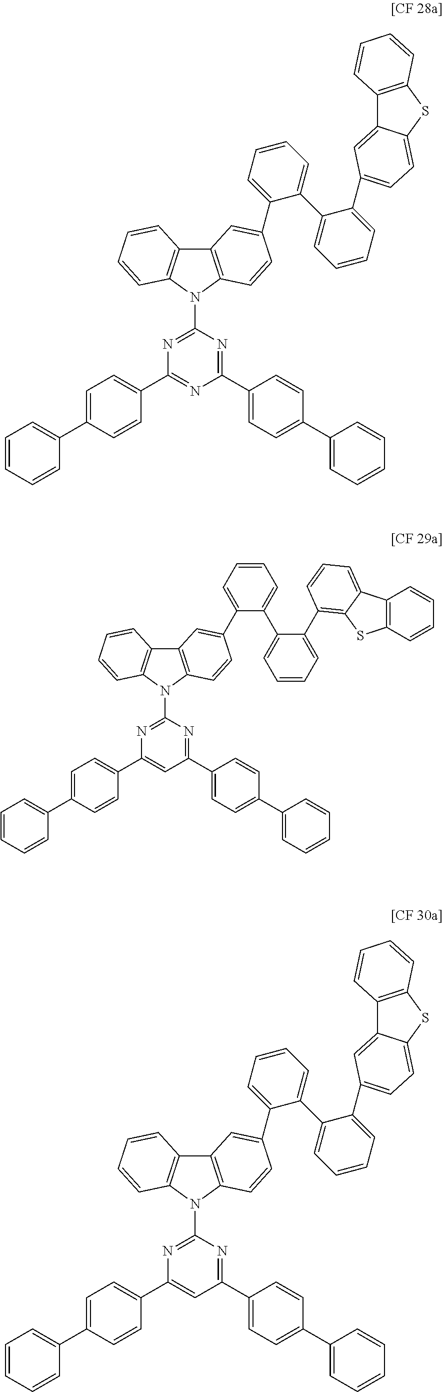 [SMILES: c1ccc(-c2ccc(-c3nc(-c4ccc(-c5ccccc5)cc4)nc(-n4c5ccccc5c5cc(-c6ccccc6-c6ccccc6-c6ccc7sc8ccccc8c7c6)ccc54)n3)cc2)cc1 ; c1ccc(-c2ccc(-c3cc(-c4ccc(-c5ccccc5)cc4)nc(-n4c5ccccc5c5cc(-c6ccccc6-c6ccccc6-c6cccc7c6sc6ccccc67)ccc54)n3)cc2)cc1 ; c1ccc(-c2ccc(-c3cc(-c4ccc(-c5ccccc5)cc4)nc(-n4c5ccccc5c5cc(-c6ccccc6-c6ccccc6-c6ccc7sc8ccccc8c7c6)ccc54)n3)cc2)cc1]

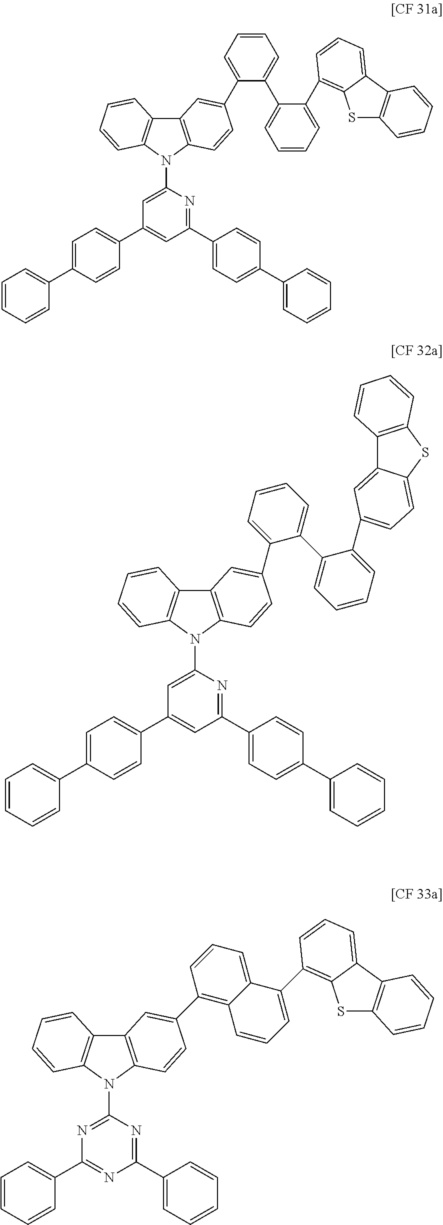 [SMILES: c1ccc(-c2ccc(-c3cc(-c4ccc(-c5ccccc5)cc4)nc(-n4c5ccccc5c5cc(-c6ccccc6-c6ccccc6-c6cccc7c6sc6ccccc67)ccc54)c3)cc2)cc1 ; c1ccc(-c2ccc(-c3cc(-c4ccc(-c5ccccc5)cc4)nc(-n4c5ccccc5c5cc(-c6ccccc6-c6ccccc6-c6ccc7sc8ccccc8c7c6)ccc54)c3)cc2)cc1 ; c1ccc(-c2nc(-c3ccccc3)nc(-n3c4ccccc4c4cc(-c5cccc6c(-c7cccc8c7sc7ccccc78)cccc56)ccc43)n2)cc1]

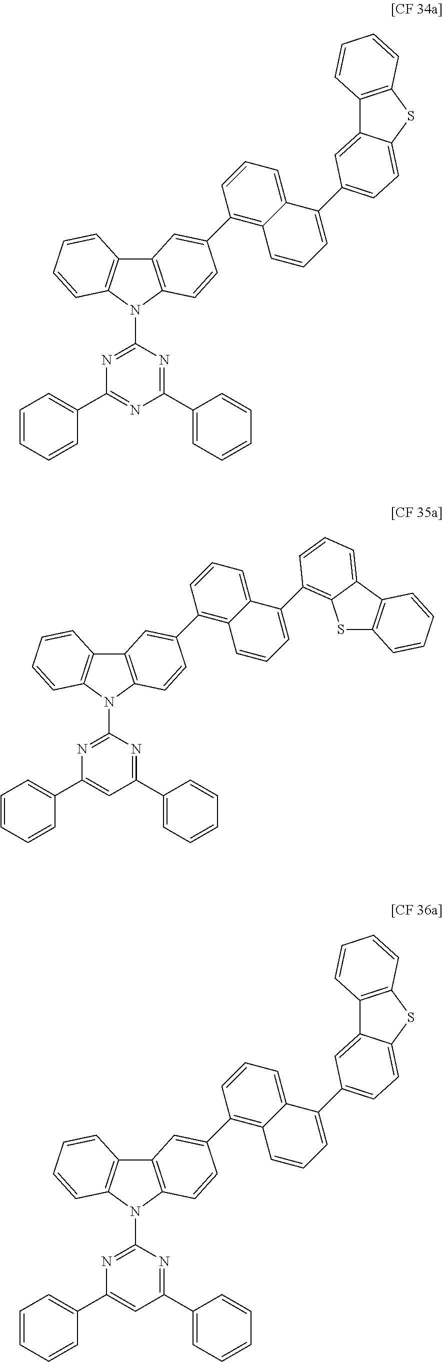 [SMILES: c1ccc(-c2nc(-c3ccccc3)nc(-n3c4ccccc4c4cc(-c5cccc6c(-c7ccc8sc9ccccc9c8c7)cccc56)ccc43)n2)cc1 ; c1ccc(-c2cc(-c3ccccc3)nc(-n3c4ccccc4c4cc(-c5cccc6c(-c7cccc8c7sc7ccccc78)cccc56)ccc43)n2)cc1 ; c1ccc(-c2cc(-c3ccccc3)nc(-n3c4ccccc4c4cc(-c5cccc6c(-c7ccc8sc9ccccc9c8c7)cccc56)ccc43)n2)cc1]

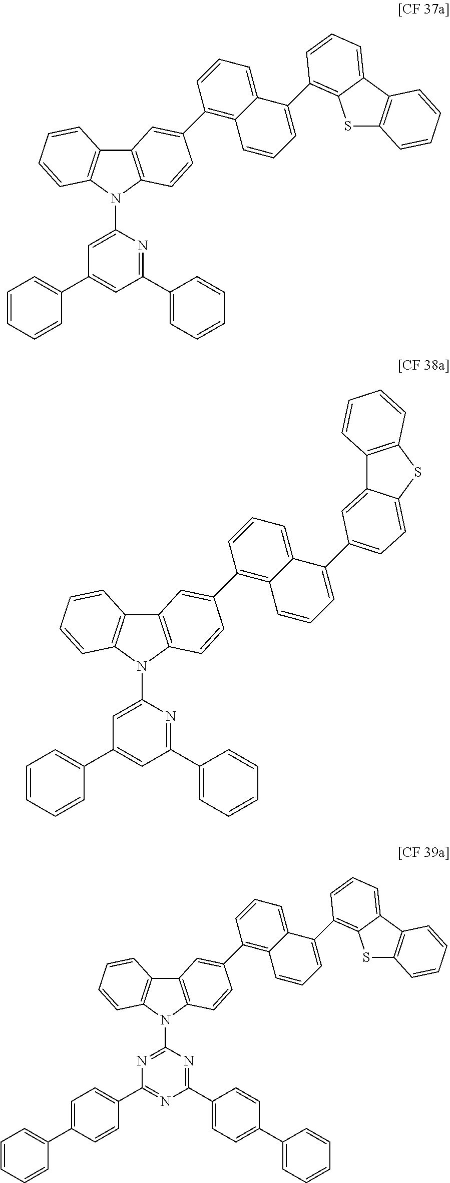 [SMILES: c1ccc(-c2cc(-c3ccccc3)nc(-n3c4ccccc4c4cc(-c5cccc6c(-c7cccc8c7sc7ccccc78)cccc56)ccc43)c2)cc1 ; c1ccc(-c2cc(-c3ccccc3)nc(-n3c4ccccc4c4cc(-c5cccc6c(-c7ccc8sc9ccccc9c8c7)cccc56)ccc43)c2)cc1 ; c1ccc(-c2ccc(-c3nc(-c4ccc(-c5ccccc5)cc4)nc(-n4c5ccccc5c5cc(-c6cccc7c(-c8cccc9c8sc8ccccc89)cccc67)ccc54)n3)cc2)cc1]

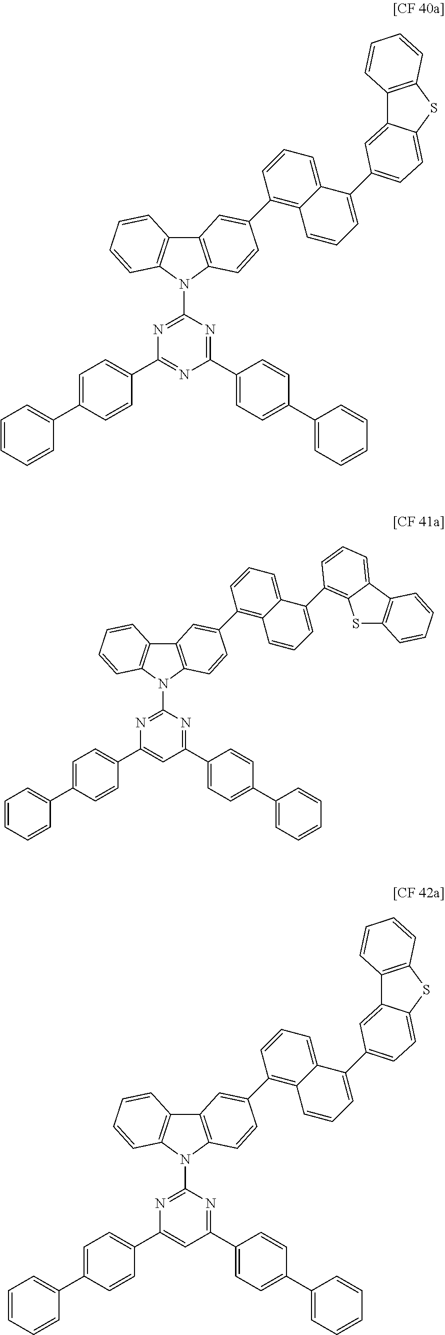 [SMILES: c1ccc(-c2ccc(-c3nc(-c4ccc(-c5ccccc5)cc4)nc(-n4c5ccccc5c5cc(-c6cccc7c(-c8ccc9sc%10ccccc%10c9c8)cccc67)ccc54)n3)cc2)cc1 ; c1ccc(-c2ccc(-c3cc(-c4ccc(-c5ccccc5)cc4)nc(-n4c5ccccc5c5cc(-c6cccc7c(-c8cccc9c8sc8ccccc89)cccc67)ccc54)n3)cc2)cc1 ; c1ccc(-c2ccc(-c3cc(-c4ccc(-c5ccccc5)cc4)nc(-n4c5ccccc5c5cc(-c6cccc7c(-c8ccc9sc%10ccccc%10c9c8)cccc67)ccc54)n3)cc2)cc1]

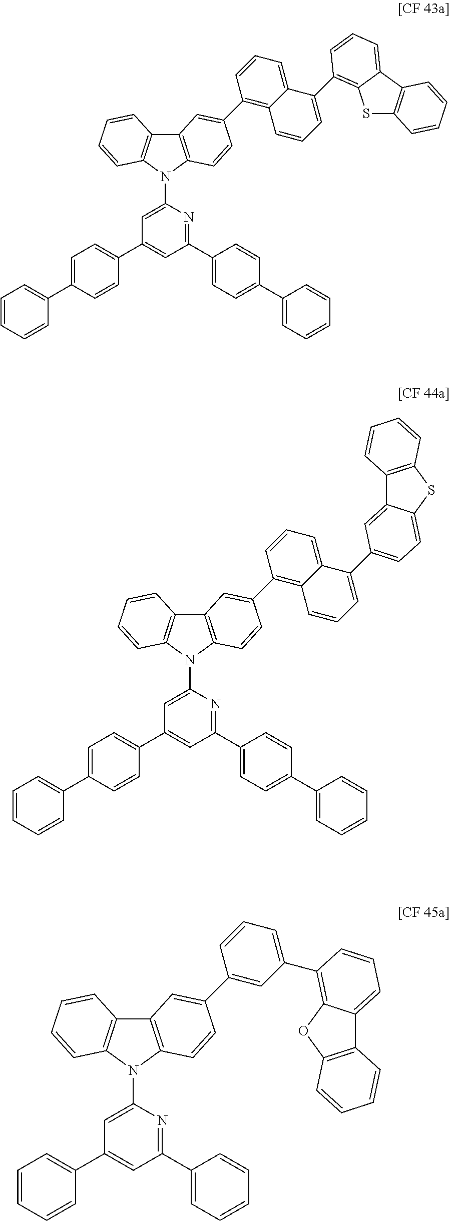 [SMILES: c1ccc(-c2ccc(-c3cc(-c4ccc(-c5ccccc5)cc4)nc(-n4c5ccccc5c5cc(-c6cccc7c(-c8cccc9c8sc8ccccc89)cccc67)ccc54)c3)cc2)cc1 ; c1ccc(-c2ccc(-c3cc(-c4ccc(-c5ccccc5)cc4)nc(-n4c5ccccc5c5cc(-c6cccc7c(-c8ccc9sc%10ccccc%10c9c8)cccc67)ccc54)c3)cc2)cc1 ; c1ccc(-c2cc(-c3ccccc3)nc(-n3c4ccccc4c4cc(-c5cccc(-c6cccc7c6oc6ccccc67)c5)ccc43)c2)cc1]

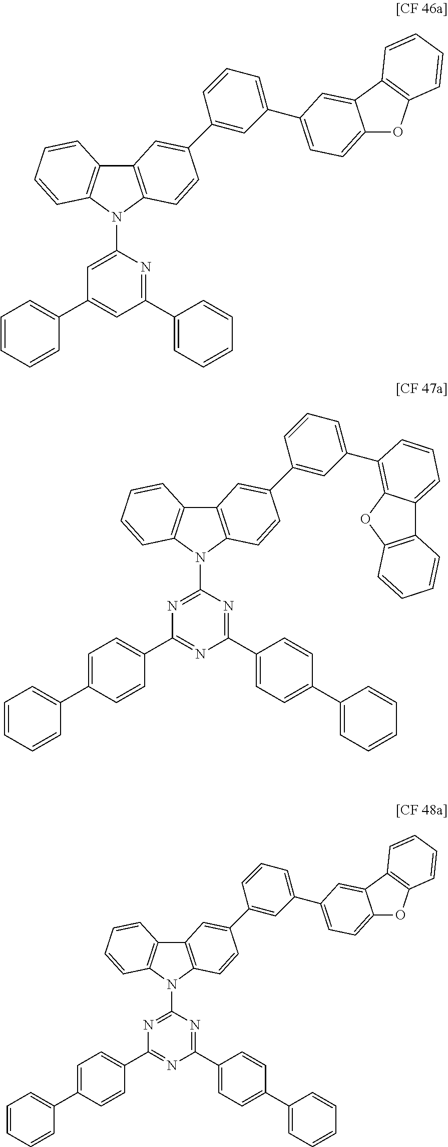 [SMILES: c1ccc(-c2cc(-c3ccccc3)nc(-n3c4ccccc4c4cc(-c5cccc(-c6ccc7oc8ccccc8c7c6)c5)ccc43)c2)cc1 ; c1ccc(-c2ccc(-c3nc(-c4ccc(-c5ccccc5)cc4)nc(-n4c5ccccc5c5cc(-c6cccc(-c7cccc8c7oc7ccccc78)c6)ccc54)n3)cc2)cc1 ; c1ccc(-c2ccc(-c3nc(-c4ccc(-c5ccccc5)cc4)nc(-n4c5ccccc5c5cc(-c6cccc(-c7ccc8oc9ccccc9c8c7)c6)ccc54)n3)cc2)cc1]

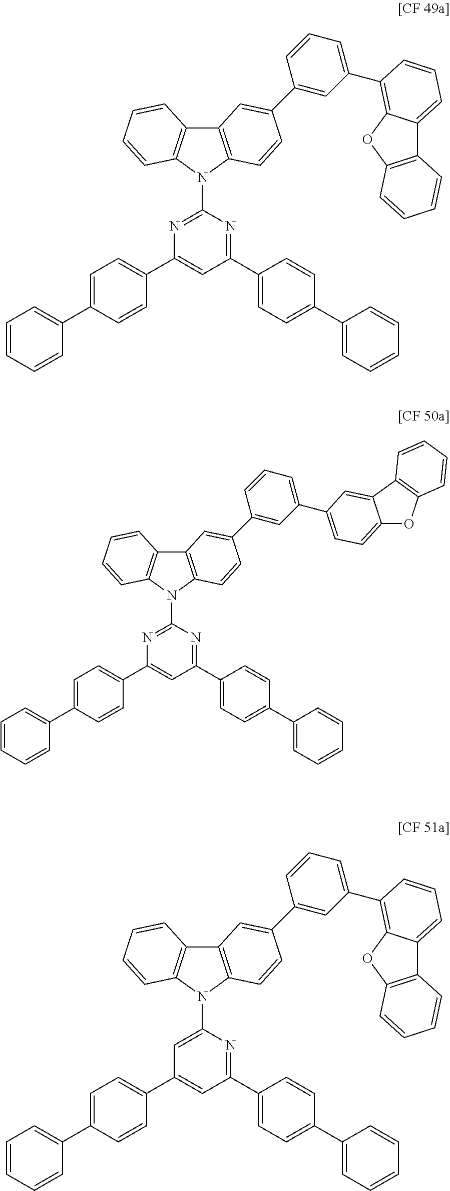 [SMILES: c1ccc(-c2ccc(-c3cc(-c4ccc(-c5ccccc5)cc4)nc(-n4c5ccccc5c5cc(-c6cccc(-c7cccc8c7oc7ccccc78)c6)ccc54)n3)cc2)cc1 ; c1ccc(-c2ccc(-c3cc(-c4ccc(-c5ccccc5)cc4)nc(-n4c5ccccc5c5cc(-c6cccc(-c7ccc8oc9ccccc9c8c7)c6)ccc54)n3)cc2)cc1 ; c1ccc(-c2ccc(-c3cc(-c4ccc(-c5ccccc5)cc4)nc(-n4c5ccccc5c5cc(-c6cccc(-c7cccc8c7oc7ccccc78)c6)ccc54)c3)cc2)cc1]

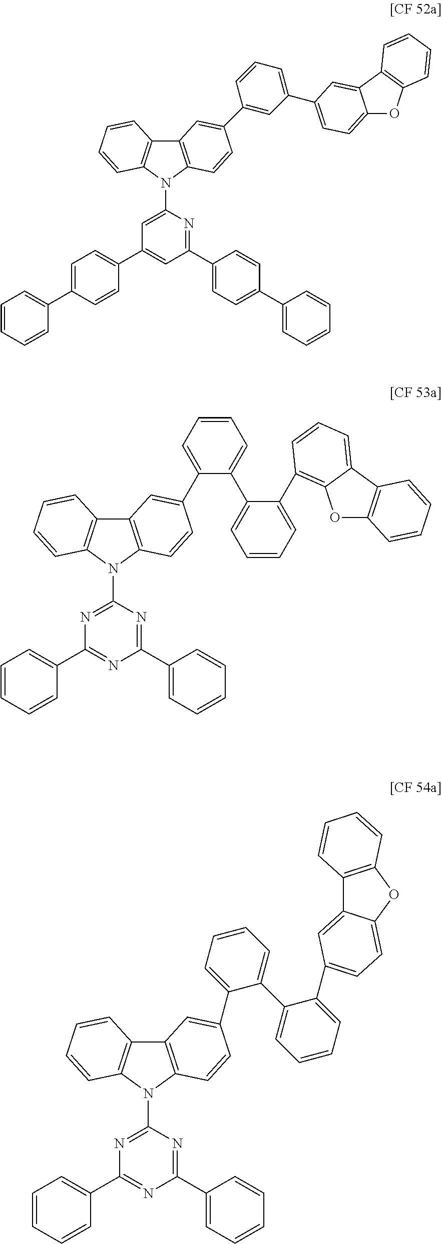 [SMILES: c1ccc(-c2ccc(-c3cc(-c4ccc(-c5ccccc5)cc4)nc(-n4c5ccccc5c5cc(-c6cccc(-c7ccc8oc9ccccc9c8c7)c6)ccc54)c3)cc2)cc1 ; c1ccc(-c2nc(-c3ccccc3)nc(-n3c4ccccc4c4cc(-c5ccccc5-c5ccccc5-c5cccc6c5oc5ccccc56)ccc43)n2)cc1 ; c1ccc(-c2nc(-c3ccccc3)nc(-n3c4ccccc4c4cc(-c5ccccc5-c5ccccc5-c5ccc6oc7ccccc7c6c5)ccc43)n2)cc1]

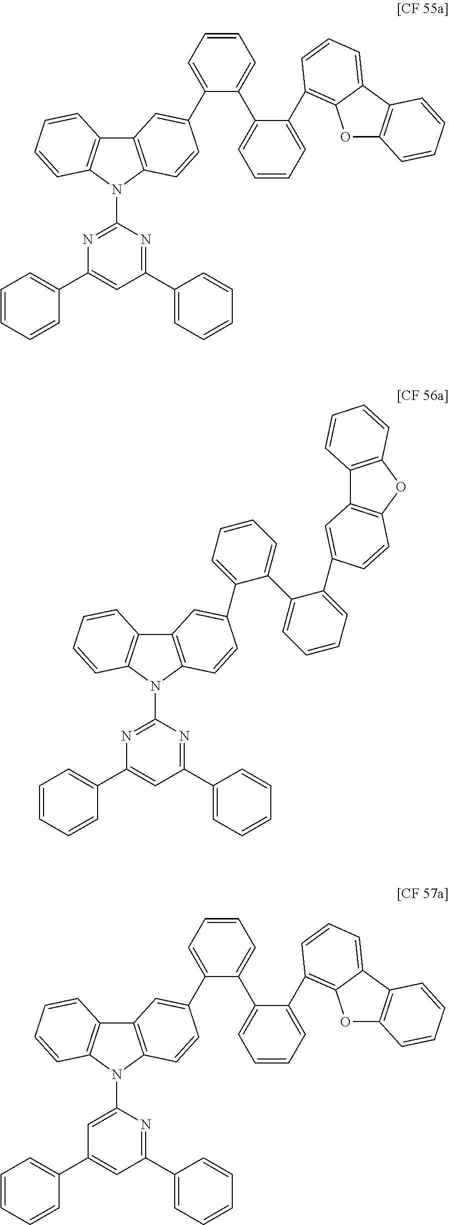 [SMILES: c1ccc(-c2cc(-c3ccccc3)nc(-n3c4ccccc4c4cc(-c5ccccc5-c5ccccc5-c5cccc6c5oc5ccccc56)ccc43)n2)cc1 ; c1ccc(-c2cc(-c3ccccc3)nc(-n3c4ccccc4c4cc(-c5ccccc5-c5ccccc5-c5ccc6oc7ccccc7c6c5)ccc43)n2)cc1 ; c1ccc(-c2cc(-c3ccccc3)nc(-n3c4ccccc4c4cc(-c5ccccc5-c5ccccc5-c5cccc6c5oc5ccccc56)ccc43)c2)cc1]

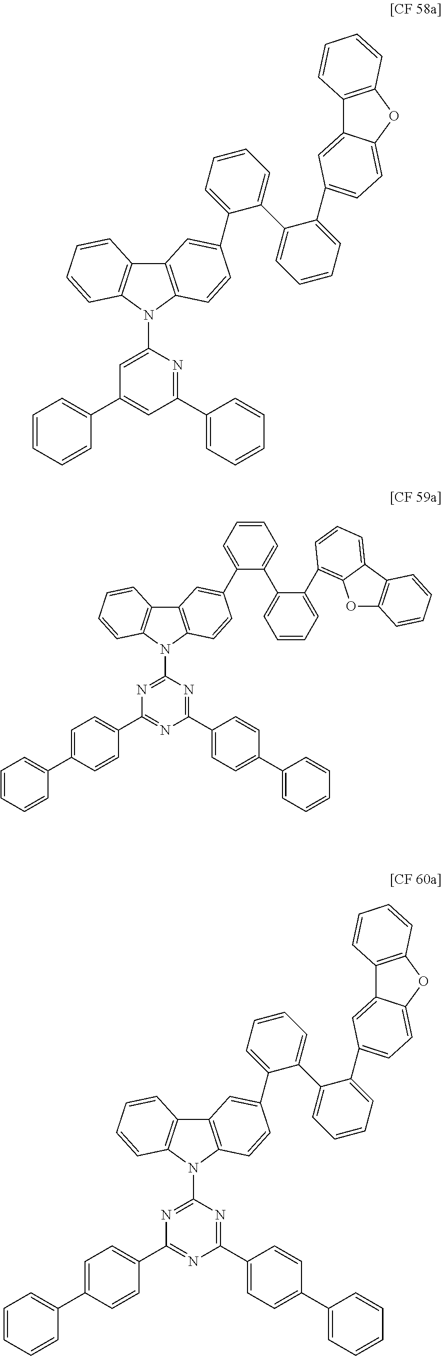 [SMILES: c1ccc(-c2cc(-c3ccccc3)nc(-n3c4ccccc4c4cc(-c5ccccc5-c5ccccc5-c5ccc6oc7ccccc7c6c5)ccc43)c2)cc1 ; c1ccc(-c2ccc(-c3nc(-c4ccc(-c5ccccc5)cc4)nc(-n4c5ccccc5c5cc(-c6ccccc6-c6ccccc6-c6cccc7c6oc6ccccc67)ccc54)n3)cc2)cc1 ; c1ccc(-c2ccc(-c3nc(-c4ccc(-c5ccccc5)cc4)nc(-n4c5ccccc5c5cc(-c6ccccc6-c6ccccc6-c6ccc7oc8ccccc8c7c6)ccc54)n3)cc2)cc1]

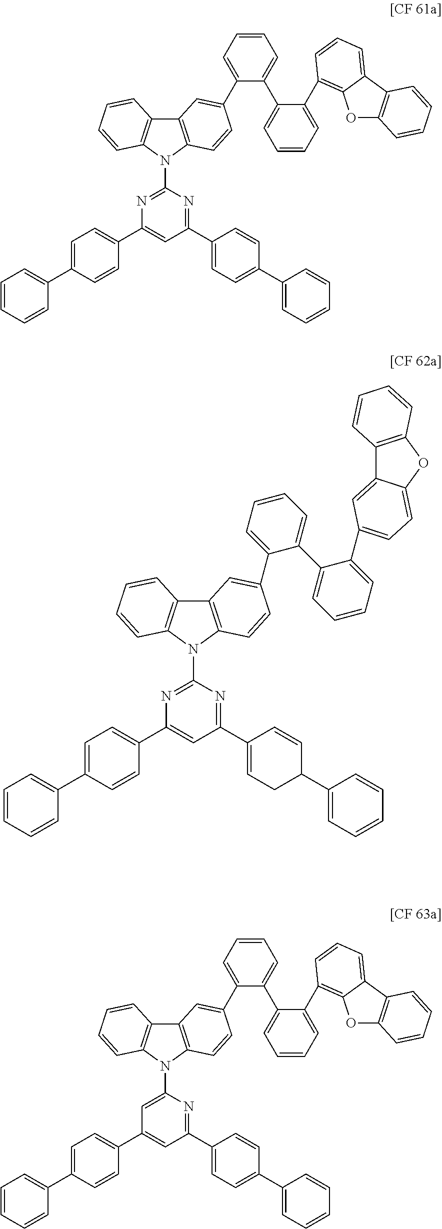 [SMILES: c1ccc(-c2ccc(-c3cc(-c4ccc(-c5ccccc5)cc4)nc(-n4c5ccccc5c5cc(-c6ccccc6-c6ccccc6-c6cccc7c6oc6ccccc67)ccc54)n3)cc2)cc1 ; C1=CC(c2ccccc2)CC=C1c1cc(-c2ccc(-c3ccccc3)cc2)nc(-n2c3ccccc3c3cc(-c4ccccc4-c4ccccc4-c4ccc5oc6ccccc6c5c4)ccc32)n1 ; c1ccc(-c2ccc(-c3cc(-c4ccc(-c5ccccc5)cc4)nc(-n4c5ccccc5c5cc(-c6ccccc6-c6ccccc6-c6cccc7c6oc6ccccc67)ccc54)c3)cc2)cc1]

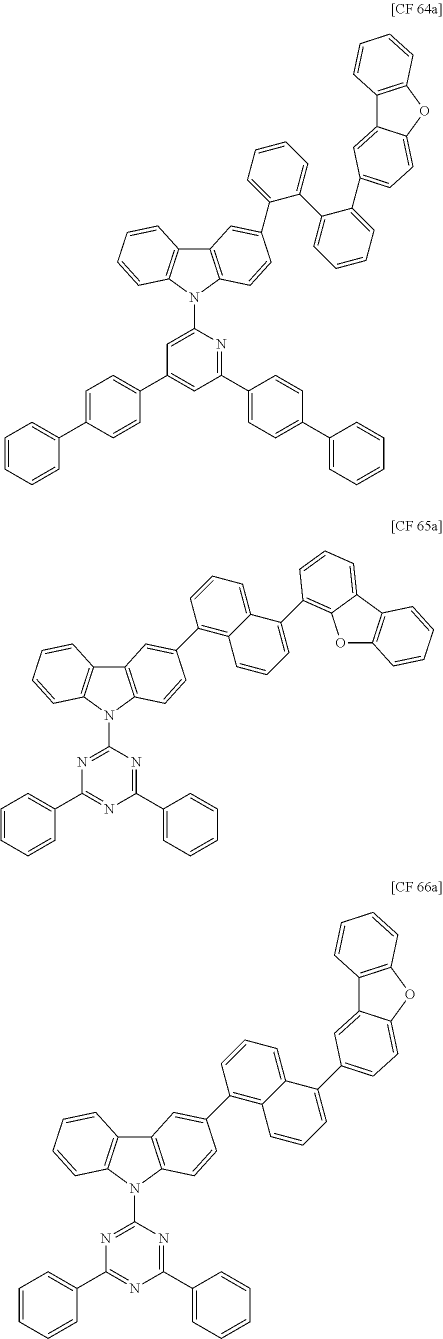 [SMILES: c1ccc(-c2ccc(-c3cc(-c4ccc(-c5ccccc5)cc4)nc(-n4c5ccccc5c5cc(-c6ccccc6-c6ccccc6-c6ccc7oc8ccccc8c7c6)ccc54)c3)cc2)cc1 ; c1ccc(-c2nc(-c3ccccc3)nc(-n3c4ccccc4c4cc(-c5cccc6c(-c7cccc8c7oc7ccccc78)cccc56)ccc43)n2)cc1 ; c1ccc(-c2nc(-c3ccccc3)nc(-n3c4ccccc4c4cc(-c5cccc6c(-c7ccc8oc9ccccc9c8c7)cccc56)ccc43)n2)cc1]

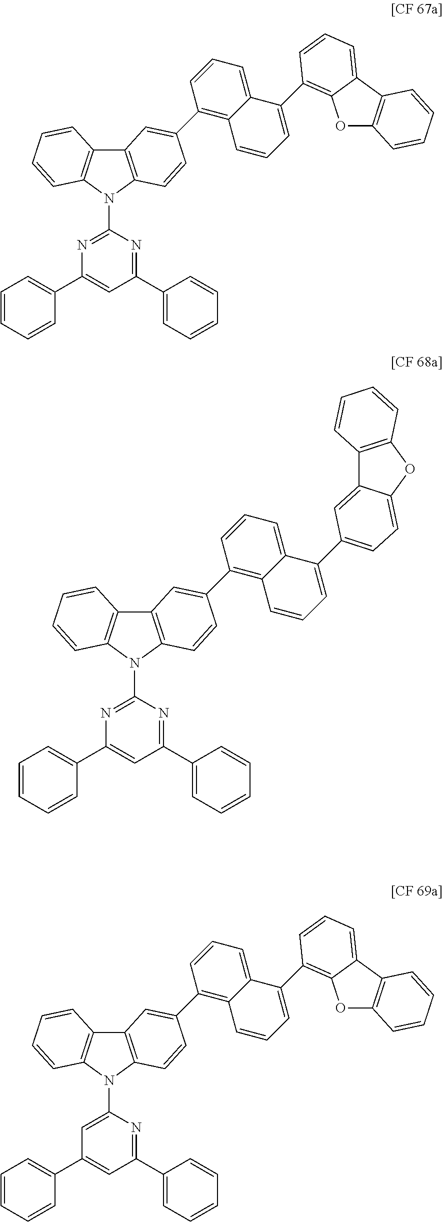 [SMILES: c1ccc(-c2cc(-c3ccccc3)nc(-n3c4ccccc4c4cc(-c5cccc6c(-c7cccc8c7oc7ccccc78)cccc56)ccc43)n2)cc1 ; c1ccc(-c2cc(-c3ccccc3)nc(-n3c4ccccc4c4cc(-c5cccc6c(-c7ccc8oc9ccccc9c8c7)cccc56)ccc43)n2)cc1 ; c1ccc(-c2cc(-c3ccccc3)nc(-n3c4ccccc4c4cc(-c5cccc6c(-c7cccc8c7oc7ccccc78)cccc56)ccc43)c2)cc1]

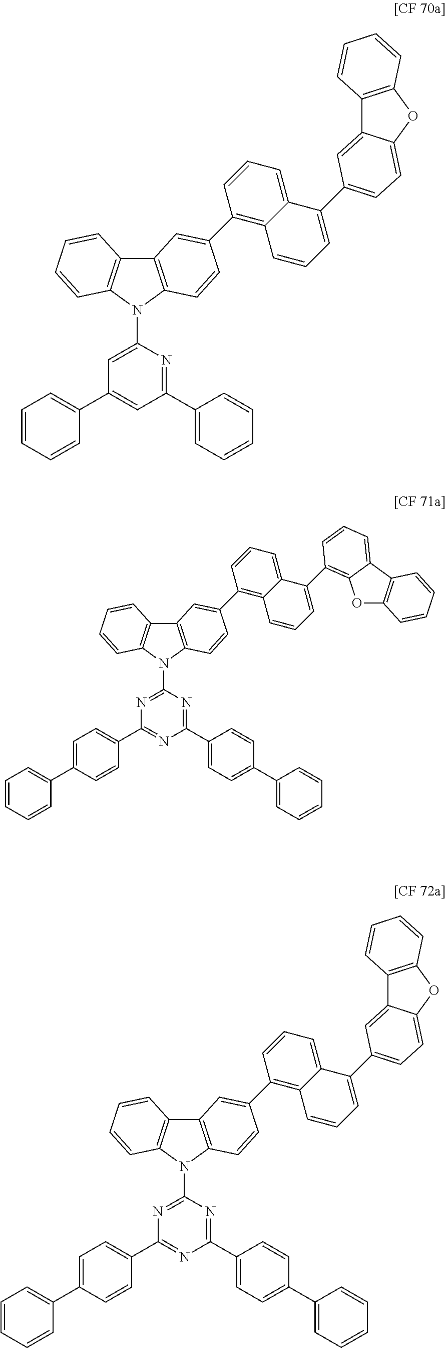 [SMILES: c1ccc(-c2cc(-c3ccccc3)nc(-n3c4ccccc4c4cc(-c5cccc6c(-c7ccc8oc9ccccc9c8c7)cccc56)ccc43)c2)cc1 ; c1ccc(-c2ccc(-c3nc(-c4ccc(-c5ccccc5)cc4)nc(-n4c5ccccc5c5cc(-c6cccc7c(-c8cccc9c8oc8ccccc89)cccc67)ccc54)n3)cc2)cc1 ; c1ccc(-c2ccc(-c3nc(-c4ccc(-c5ccccc5)cc4)nc(-n4c5ccccc5c5cc(-c6cccc7c(-c8ccc9oc%10ccccc%10c9c8)cccc67)ccc54)n3)cc2)cc1]

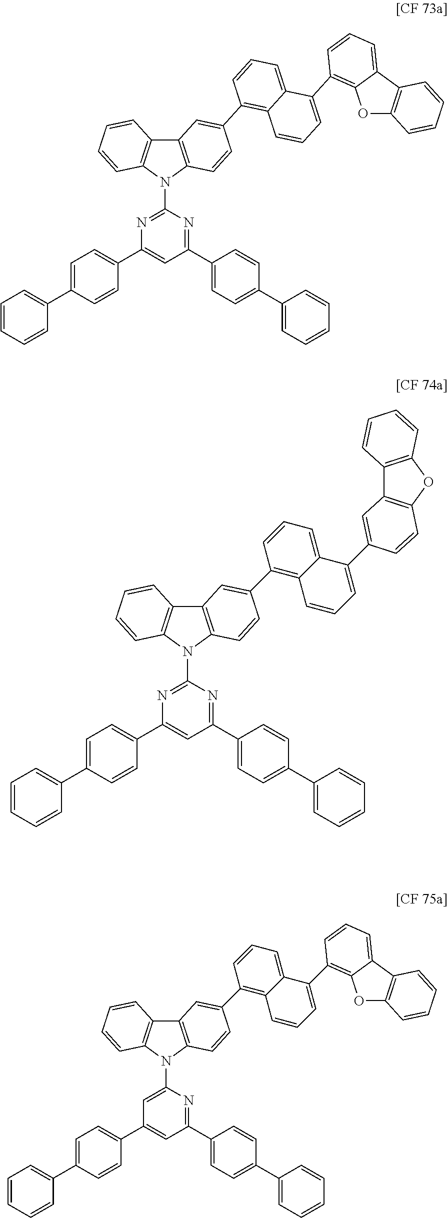 [SMILES: c1ccc(-c2ccc(-c3cc(-c4ccc(-c5ccccc5)cc4)nc(-n4c5ccccc5c5cc(-c6cccc7c(-c8cccc9c8oc8ccccc89)cccc67)ccc54)n3)cc2)cc1 ; c1ccc(-c2ccc(-c3cc(-c4ccc(-c5ccccc5)cc4)nc(-n4c5ccccc5c5cc(-c6cccc7c(-c8ccc9oc%10ccccc%10c9c8)cccc67)ccc54)n3)cc2)cc1 ; c1ccc(-c2ccc(-c3cc(-c4ccc(-c5ccccc5)cc4)nc(-n4c5ccccc5c5cc(-c6cccc7c(-c8cccc9c8oc8ccccc89)cccc67)ccc54)c3)cc2)cc1]

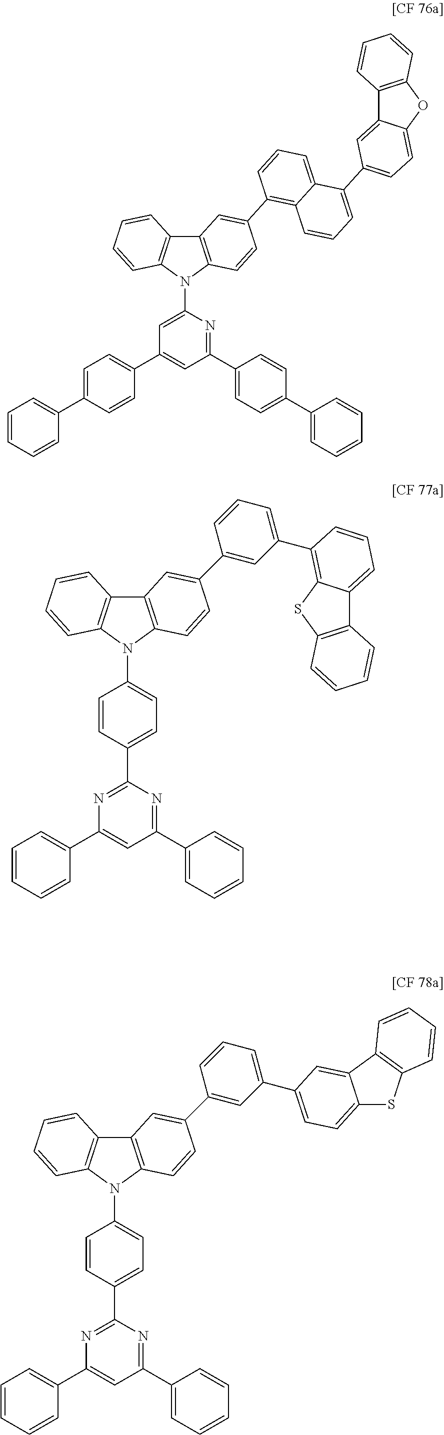 [SMILES: c1ccc(-c2ccc(-c3cc(-c4ccc(-c5ccccc5)cc4)nc(-n4c5ccccc5c5cc(-c6cccc7c(-c8ccc9oc%10ccccc%10c9c8)cccc67)ccc54)c3)cc2)cc1 ; c1ccc(-c2cc(-c3ccccc3)nc(-c3ccc(-n4c5ccccc5c5cc(-c6cccc(-c7cccc8c7sc7ccccc78)c6)ccc54)cc3)n2)cc1 ; c1ccc(-c2cc(-c3ccccc3)nc(-c3ccc(-n4c5ccccc5c5cc(-c6cccc(-c7ccc8sc9ccccc9c8c7)c6)ccc54)cc3)n2)cc1]

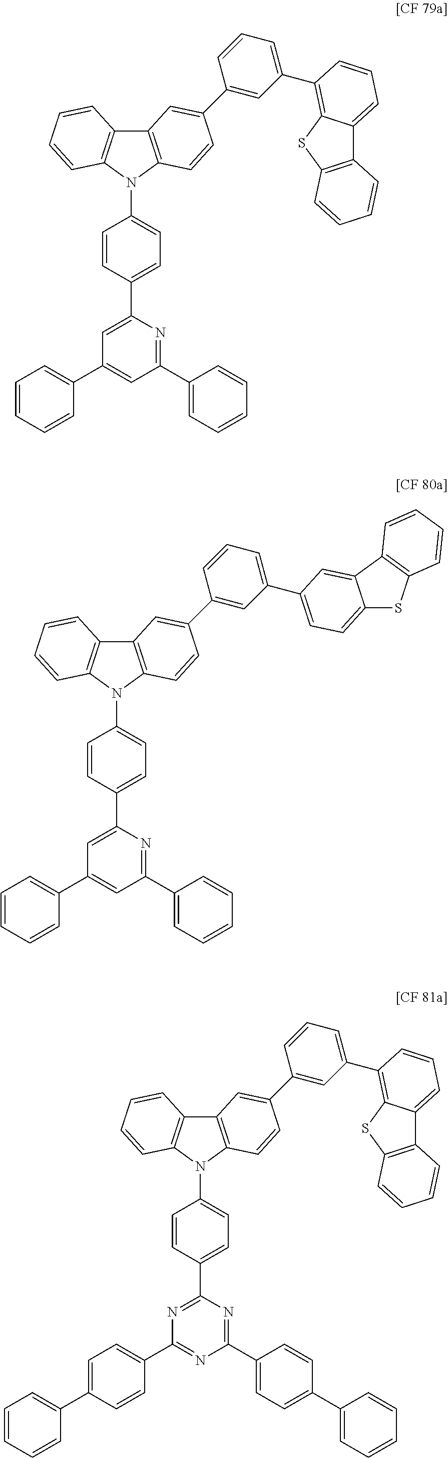 [SMILES: c1ccc(-c2cc(-c3ccccc3)nc(-c3ccc(-n4c5ccccc5c5cc(-c6cccc(-c7cccc8c7sc7ccccc78)c6)ccc54)cc3)c2)cc1 ; c1ccc(-c2cc(-c3ccccc3)nc(-c3ccc(-n4c5ccccc5c5cc(-c6cccc(-c7ccc8sc9ccccc9c8c7)c6)ccc54)cc3)c2)cc1 ; c1ccc(-c2ccc(-c3nc(-c4ccc(-c5ccccc5)cc4)nc(-c4ccc(-n5c6ccccc6c6cc(-c7cccc(-c8cccc9c8sc8ccccc89)c7)ccc65)cc4)n3)cc2)cc1]

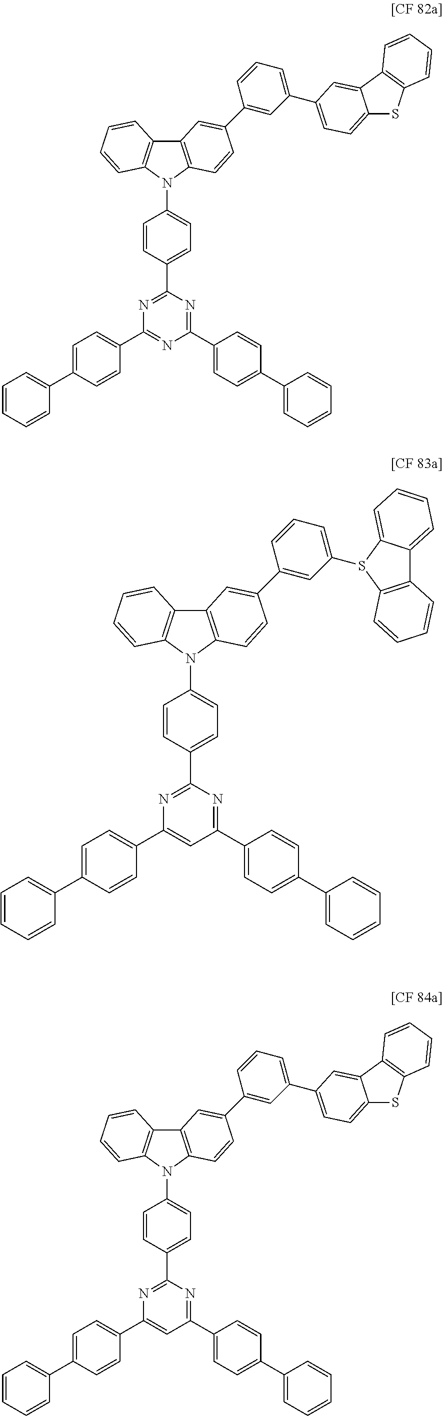

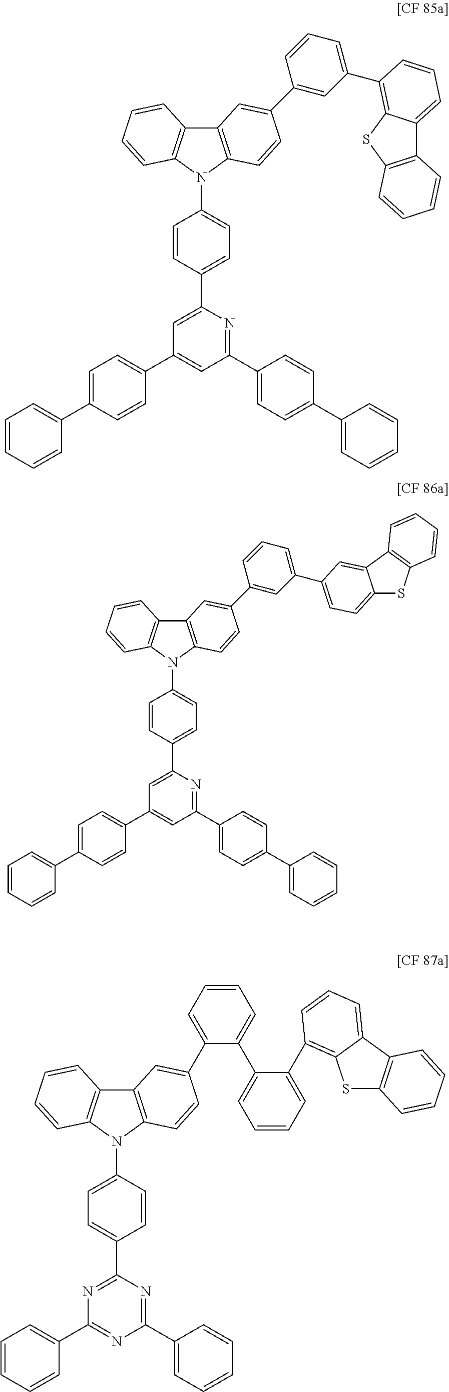 [SMILES: c1ccc(-c2ccc(-c3cc(-c4ccc(-c5ccccc5)cc4)nc(-c4ccc(-n5c6ccccc6c6cc(-c7cccc(-c8cccc9c8sc8ccccc89)c7)ccc65)cc4)c3)cc2)cc1 ; c1ccc(-c2ccc(-c3cc(-c4ccc(-c5ccccc5)cc4)nc(-c4ccc(-n5c6ccccc6c6cc(-c7cccc(-c8ccc9sc%10ccccc%10c9c8)c7)ccc65)cc4)c3)cc2)cc1 ; c1ccc(-c2nc(-c3ccccc3)nc(-c3ccc(-n4c5ccccc5c5cc(-c6ccccc6-c6ccccc6-c6cccc7c6sc6ccccc67)ccc54)cc3)n2)cc1]

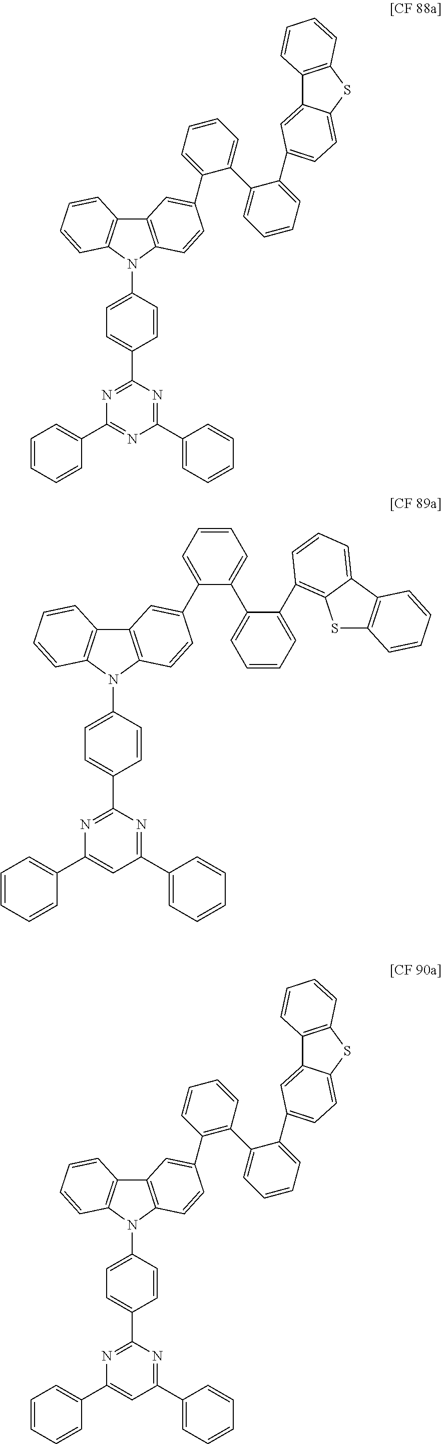 [SMILES: c1ccc(-c2nc(-c3ccccc3)nc(-c3ccc(-n4c5ccccc5c5cc(-c6ccccc6-c6ccccc6-c6ccc7sc8ccccc8c7c6)ccc54)cc3)n2)cc1 ; c1ccc(-c2cc(-c3ccccc3)nc(-c3ccc(-n4c5ccccc5c5cc(-c6ccccc6-c6ccccc6-c6cccc7c6sc6ccccc67)ccc54)cc3)n2)cc1 ; c1ccc(-c2cc(-c3ccccc3)nc(-c3ccc(-n4c5ccccc5c5cc(-c6ccccc6-c6ccccc6-c6ccc7sc8ccccc8c7c6)ccc54)cc3)n2)cc1]

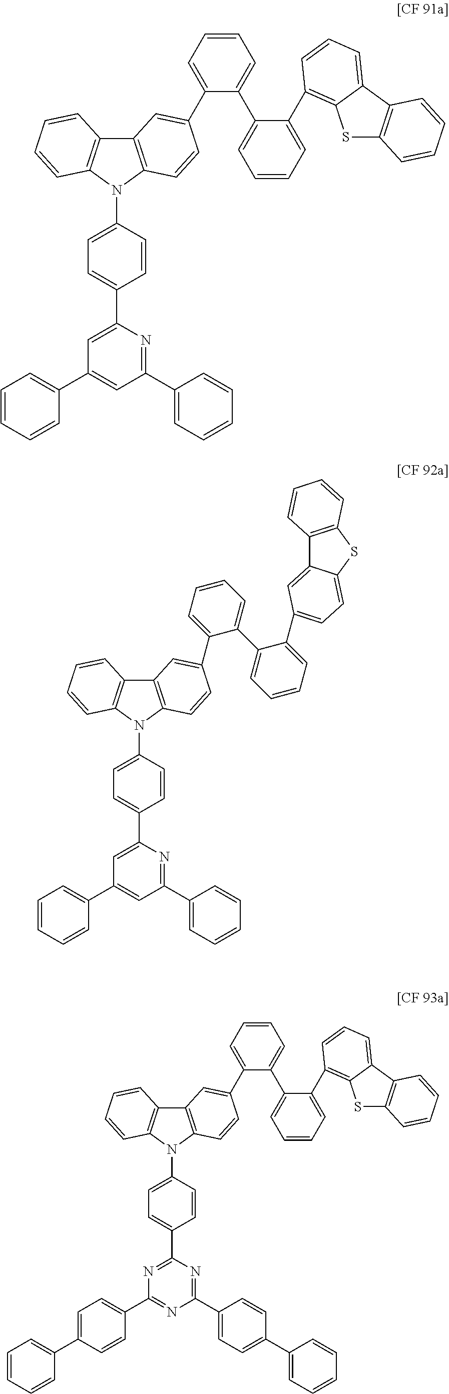 [SMILES: c1ccc(-c2cc(-c3ccccc3)nc(-c3ccc(-n4c5ccccc5c5cc(-c6ccccc6-c6ccccc6-c6cccc7c6sc6ccccc67)ccc54)cc3)c2)cc1 ; c1ccc(-c2cc(-c3ccccc3)nc(-c3ccc(-n4c5ccccc5c5cc(-c6ccccc6-c6ccccc6-c6ccc7sc8ccccc8c7c6)ccc54)cc3)c2)cc1 ; c1ccc(-c2ccc(-c3nc(-c4ccc(-c5ccccc5)cc4)nc(-c4ccc(-n5c6ccccc6c6cc(-c7ccccc7-c7ccccc7-c7cccc8c7sc7ccccc78)ccc65)cc4)n3)cc2)cc1]

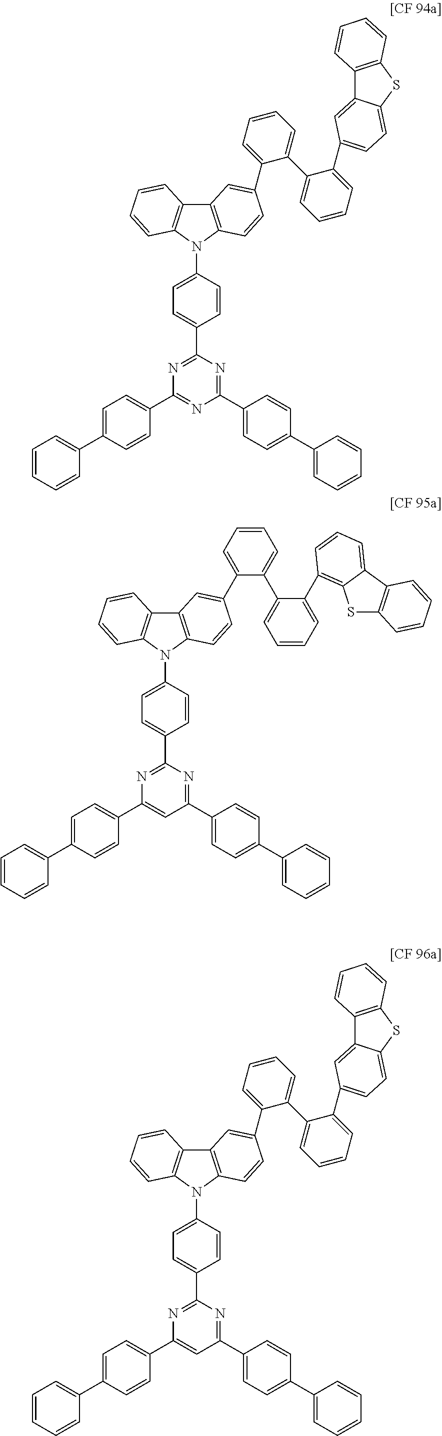 [SMILES: c1ccc(-c2ccc(-c3nc(-c4ccc(-c5ccccc5)cc4)nc(-c4ccc(-n5c6ccccc6c6cc(-c7ccccc7-c7ccccc7-c7ccc8sc9ccccc9c8c7)ccc65)cc4)n3)cc2)cc1 ; c1ccc(-c2ccc(-c3cc(-c4ccc(-c5ccccc5)cc4)nc(-c4ccc(-n5c6ccccc6c6cc(-c7ccccc7-c7ccccc7-c7cccc8c7sc7ccccc78)ccc65)cc4)n3)cc2)cc1 ; c1ccc(-c2ccc(-c3cc(-c4ccc(-c5ccccc5)cc4)nc(-c4ccc(-n5c6ccccc6c6cc(-c7ccccc7-c7ccccc7-c7ccc8sc9ccccc9c8c7)ccc65)cc4)n3)cc2)cc1]

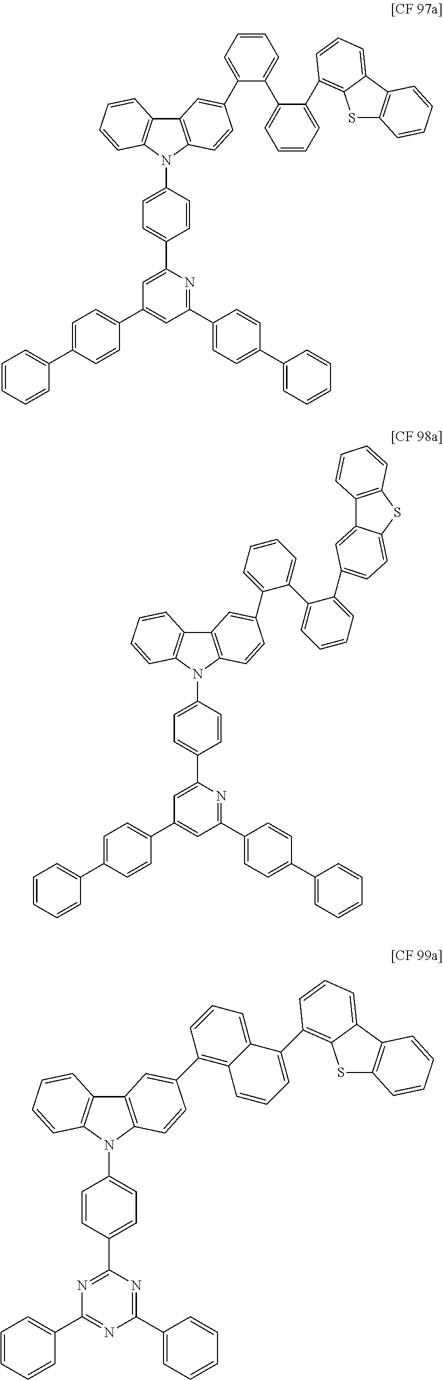 [SMILES: c1ccc(-c2ccc(-c3cc(-c4ccc(-c5ccccc5)cc4)nc(-c4ccc(-n5c6ccccc6c6cc(-c7ccccc7-c7ccccc7-c7cccc8c7sc7ccccc78)ccc65)cc4)c3)cc2)cc1 ; c1ccc(-c2ccc(-c3cc(-c4ccc(-c5ccccc5)cc4)nc(-c4ccc(-n5c6ccccc6c6cc(-c7ccccc7-c7ccccc7-c7ccc8sc9ccccc9c8c7)ccc65)cc4)c3)cc2)cc1 ; c1ccc(-c2nc(-c3ccccc3)nc(-c3ccc(-n4c5ccccc5c5cc(-c6cccc7c(-c8cccc9c8sc8ccccc89)cccc67)ccc54)cc3)n2)cc1]

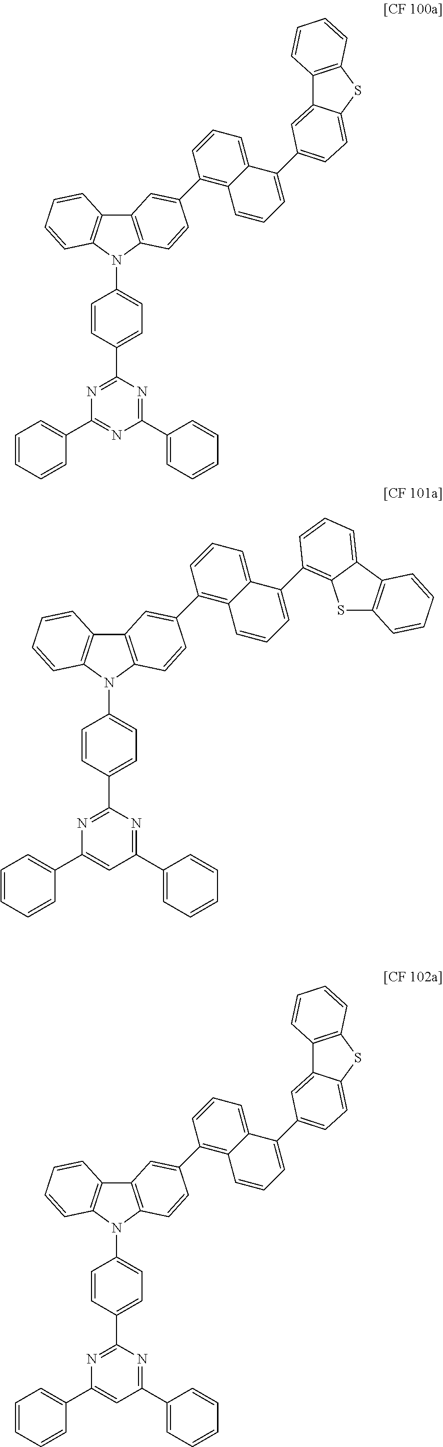 [SMILES: c1ccc(-c2nc(-c3ccccc3)nc(-c3ccc(-n4c5ccccc5c5cc(-c6cccc7c(-c8ccc9sc%10ccccc%10c9c8)cccc67)ccc54)cc3)n2)cc1 ; c1ccc(-c2cc(-c3ccccc3)nc(-c3ccc(-n4c5ccccc5c5cc(-c6cccc7c(-c8cccc9c8sc8ccccc89)cccc67)ccc54)cc3)n2)cc1 ; c1ccc(-c2cc(-c3ccccc3)nc(-c3ccc(-n4c5ccccc5c5cc(-c6cccc7c(-c8ccc9sc%10ccccc%10c9c8)cccc67)ccc54)cc3)n2)cc1]

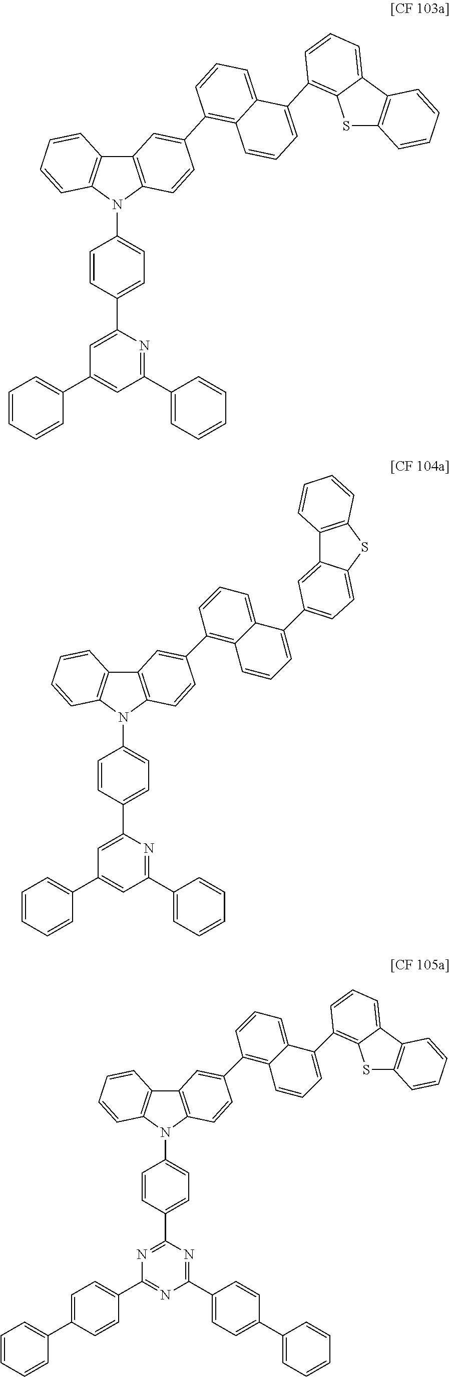 [SMILES: c1ccc(-c2cc(-c3ccccc3)nc(-c3ccc(-n4c5ccccc5c5cc(-c6cccc7c(-c8cccc9c8sc8ccccc89)cccc67)ccc54)cc3)c2)cc1 ; c1ccc(-c2cc(-c3ccccc3)nc(-c3ccc(-n4c5ccccc5c5cc(-c6cccc7c(-c8ccc9sc%10ccccc%10c9c8)cccc67)ccc54)cc3)c2)cc1 ; c1ccc(-c2ccc(-c3nc(-c4ccc(-c5ccccc5)cc4)nc(-c4ccc(-n5c6ccccc6c6cc(-c7cccc8c(-c9cccc%10c9sc9ccccc9%10)cccc78)ccc65)cc4)n3)cc2)cc1]

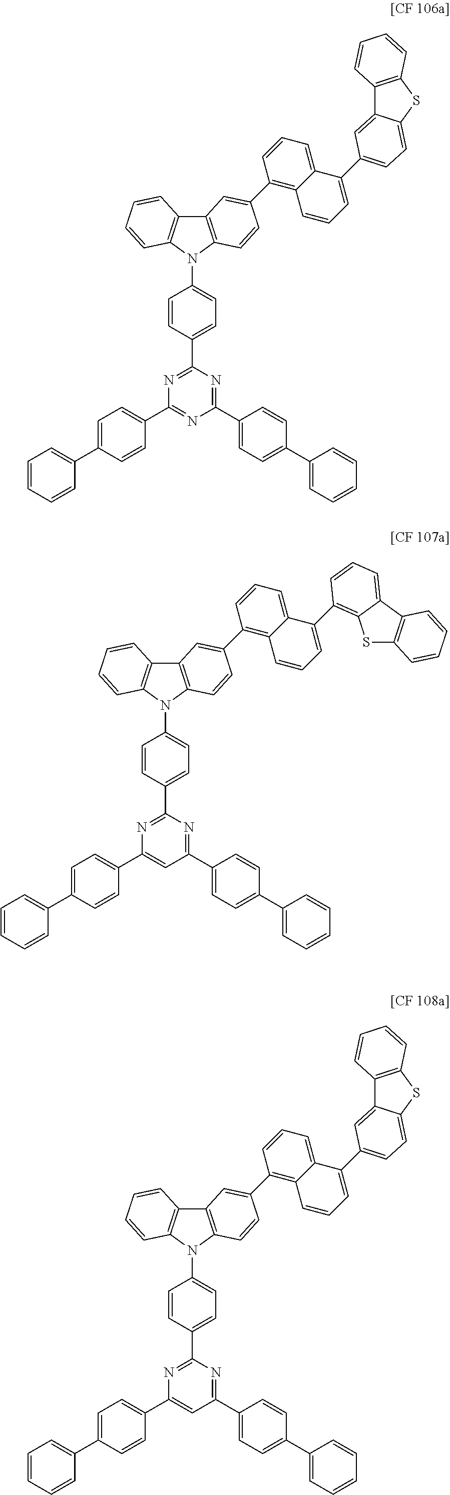 [SMILES: c1ccc(-c2ccc(-c3nc(-c4ccc(-c5ccccc5)cc4)nc(-c4ccc(-n5c6ccccc6c6cc(-c7cccc8c(-c9ccc%10sc%11ccccc%11c%10c9)cccc78)ccc65)cc4)n3)cc2)cc1 ; c1ccc(-c2ccc(-c3cc(-c4ccc(-c5ccccc5)cc4)nc(-c4ccc(-n5c6ccccc6c6cc(-c7cccc8c(-c9cccc%10c9sc9ccccc9%10)cccc78)ccc65)cc4)n3)cc2)cc1 ; c1ccc(-c2ccc(-c3cc(-c4ccc(-c5ccccc5)cc4)nc(-c4ccc(-n5c6ccccc6c6cc(-c7cccc8c(-c9ccc%10sc%11ccccc%11c%10c9)cccc78)ccc65)cc4)n3)cc2)cc1]

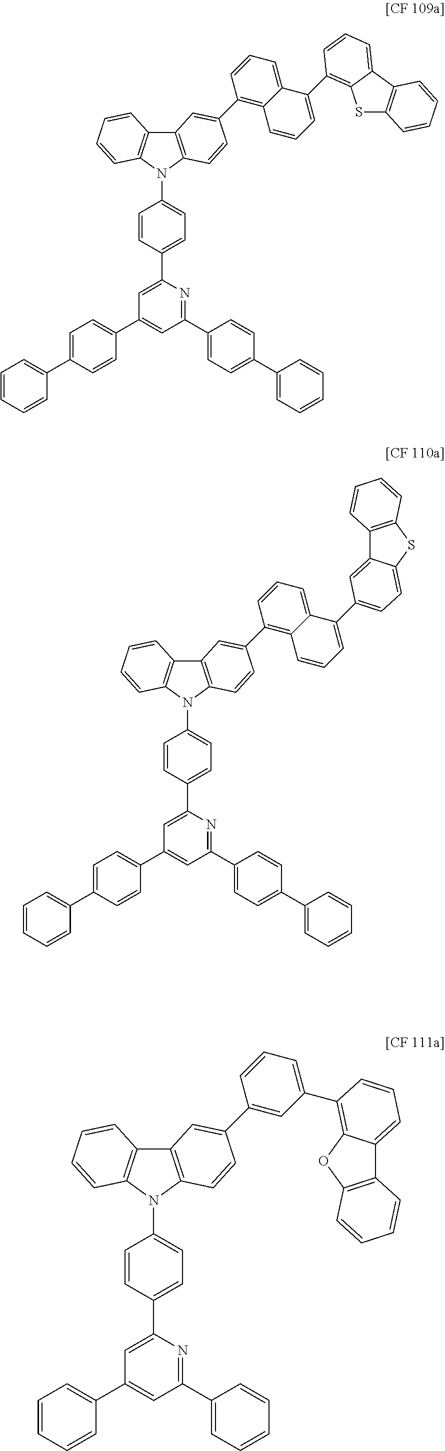 [SMILES: c1ccc(-c2ccc(-c3cc(-c4ccc(-c5ccccc5)cc4)nc(-c4ccc(-n5c6ccccc6c6cc(-c7cccc8c(-c9cccc%10c9sc9ccccc9%10)cccc78)ccc65)cc4)c3)cc2)cc1 ; c1ccc(-c2ccc(-c3cc(-c4ccc(-c5ccccc5)cc4)nc(-c4ccc(-n5c6ccccc6c6cc(-c7cccc8c(-c9ccc%10sc%11ccccc%11c%10c9)cccc78)ccc65)cc4)c3)cc2)cc1 ; c1ccc(-c2cc(-c3ccccc3)nc(-c3ccc(-n4c5ccccc5c5cc(-c6cccc(-c7cccc8c7oc7ccccc78)c6)ccc54)cc3)c2)cc1]

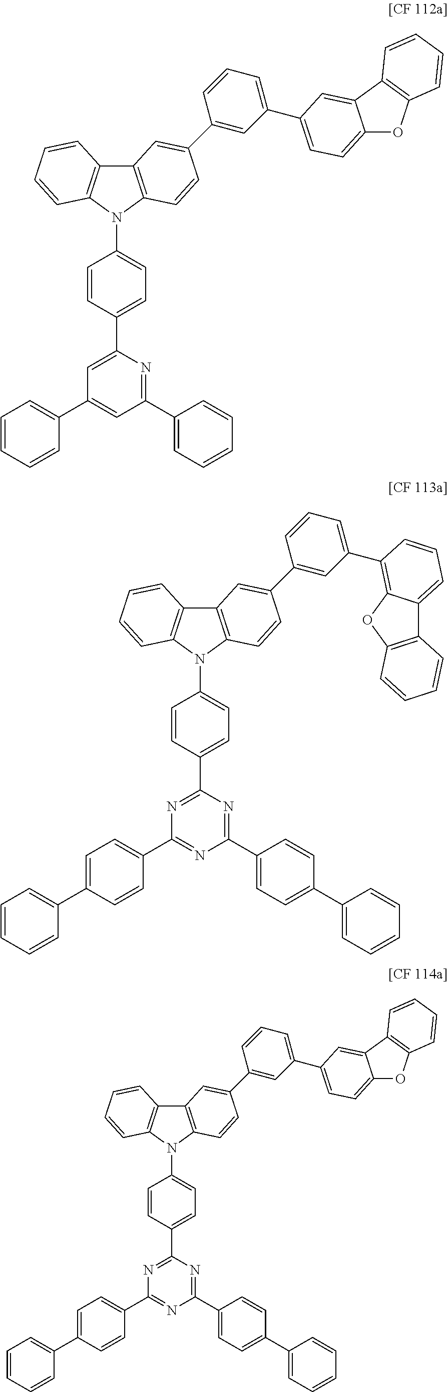 [SMILES: c1ccc(-c2cc(-c3ccccc3)nc(-c3ccc(-n4c5ccccc5c5cc(-c6cccc(-c7ccc8oc9ccccc9c8c7)c6)ccc54)cc3)c2)cc1 ; c1ccc(-c2ccc(-c3nc(-c4ccc(-c5ccccc5)cc4)nc(-c4ccc(-n5c6ccccc6c6cc(-c7cccc(-c8cccc9c8oc8ccccc89)c7)ccc65)cc4)n3)cc2)cc1 ; c1ccc(-c2ccc(-c3nc(-c4ccc(-c5ccccc5)cc4)nc(-c4ccc(-n5c6ccccc6c6cc(-c7cccc(-c8ccc9oc%10ccccc%10c9c8)c7)ccc65)cc4)n3)cc2)cc1]

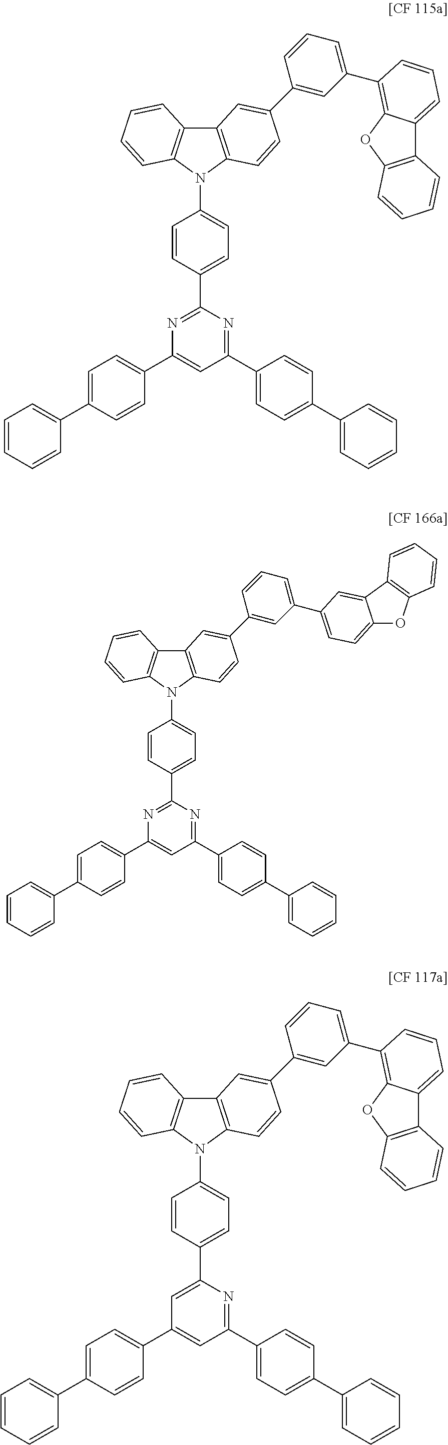 [SMILES: c1ccc(-c2ccc(-c3cc(-c4ccc(-c5ccccc5)cc4)nc(-c4ccc(-n5c6ccccc6c6cc(-c7cccc(-c8cccc9c8oc8ccccc89)c7)ccc65)cc4)n3)cc2)cc1 ; c1ccc(-c2ccc(-c3cc(-c4ccc(-c5ccccc5)cc4)nc(-c4ccc(-n5c6ccccc6c6cc(-c7cccc(-c8ccc9oc%10ccccc%10c9c8)c7)ccc65)cc4)n3)cc2)cc1 ; c1ccc(-c2ccc(-c3cc(-c4ccc(-c5ccccc5)cc4)nc(-c4ccc(-n5c6ccccc6c6cc(-c7cccc(-c8cccc9c8oc8ccccc89)c7)ccc65)cc4)c3)cc2)cc1]

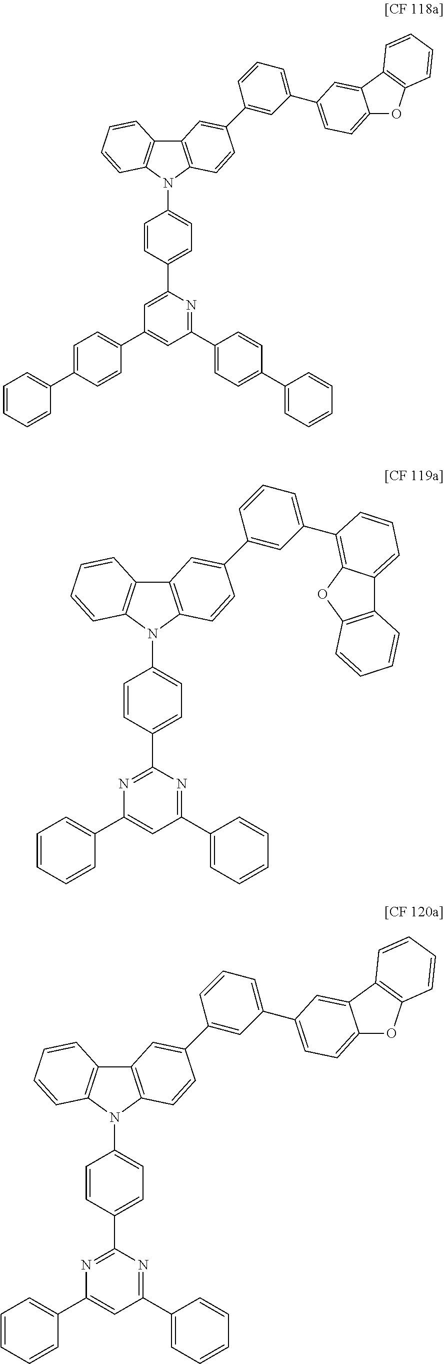 [SMILES: c1ccc(-c2ccc(-c3cc(-c4ccc(-c5ccccc5)cc4)nc(-c4ccc(-n5c6ccccc6c6cc(-c7cccc(-c8ccc9oc%10ccccc%10c9c8)c7)ccc65)cc4)c3)cc2)cc1 ; c1ccc(-c2cc(-c3ccccc3)nc(-c3ccc(-n4c5ccccc5c5cc(-c6cccc(-c7cccc8c7oc7ccccc78)c6)ccc54)cc3)n2)cc1 ; c1ccc(-c2cc(-c3ccccc3)nc(-c3ccc(-n4c5ccccc5c5cc(-c6cccc(-c7ccc8oc9ccccc9c8c7)c6)ccc54)cc3)n2)cc1]

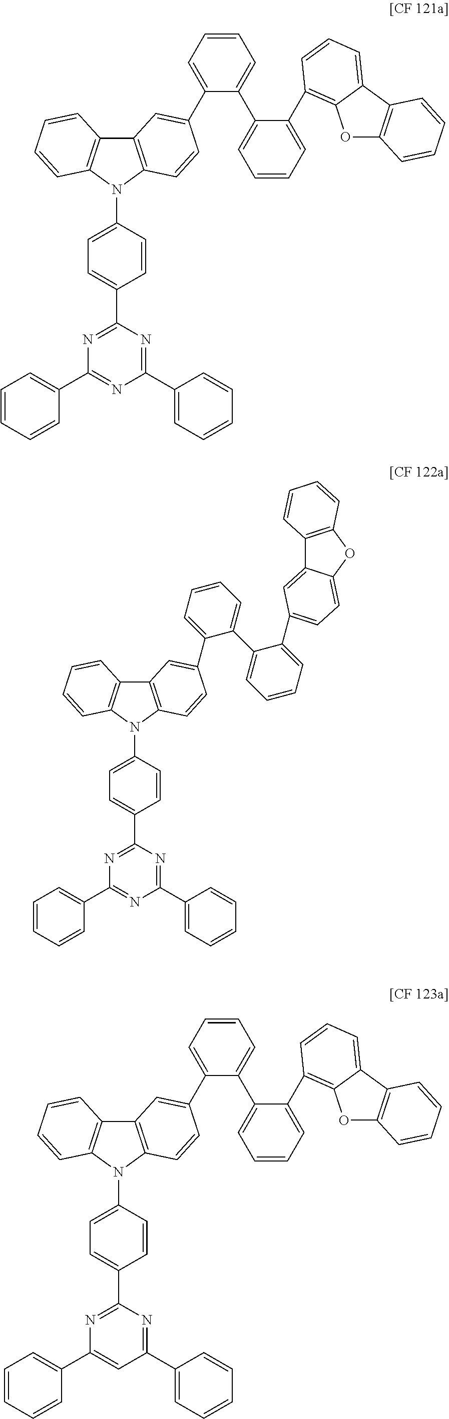 [SMILES: c1ccc(-c2nc(-c3ccccc3)nc(-c3ccc(-n4c5ccccc5c5cc(-c6ccccc6-c6ccccc6-c6cccc7c6oc6ccccc67)ccc54)cc3)n2)cc1 ; c1ccc(-c2nc(-c3ccccc3)nc(-c3ccc(-n4c5ccccc5c5cc(-c6ccccc6-c6ccccc6-c6ccc7oc8ccccc8c7c6)ccc54)cc3)n2)cc1 ; c1ccc(-c2cc(-c3ccccc3)nc(-c3ccc(-n4c5ccccc5c5cc(-c6ccccc6-c6ccccc6-c6cccc7c6oc6ccccc67)ccc54)cc3)n2)cc1]

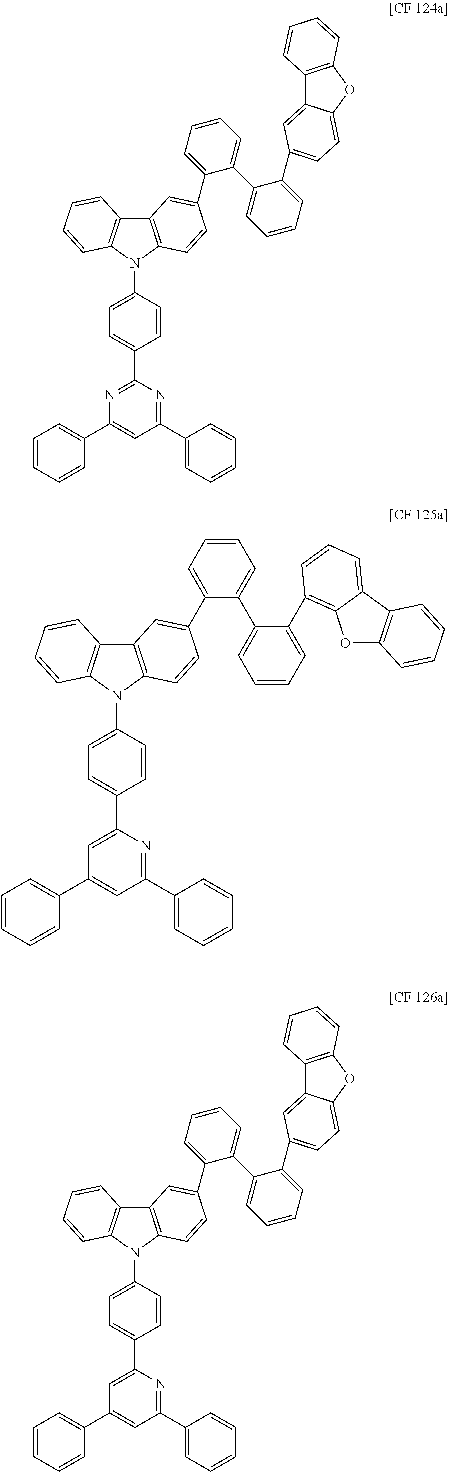 [SMILES: c1ccc(-c2cc(-c3ccccc3)nc(-c3ccc(-n4c5ccccc5c5cc(-c6ccccc6-c6ccccc6-c6ccc7oc8ccccc8c7c6)ccc54)cc3)n2)cc1 ; c1ccc(-c2cc(-c3ccccc3)nc(-c3ccc(-n4c5ccccc5c5cc(-c6ccccc6-c6ccccc6-c6cccc7c6oc6ccccc67)ccc54)cc3)c2)cc1 ; c1ccc(-c2cc(-c3ccccc3)nc(-c3ccc(-n4c5ccccc5c5cc(-c6ccccc6-c6ccccc6-c6ccc7oc8ccccc8c7c6)ccc54)cc3)c2)cc1]

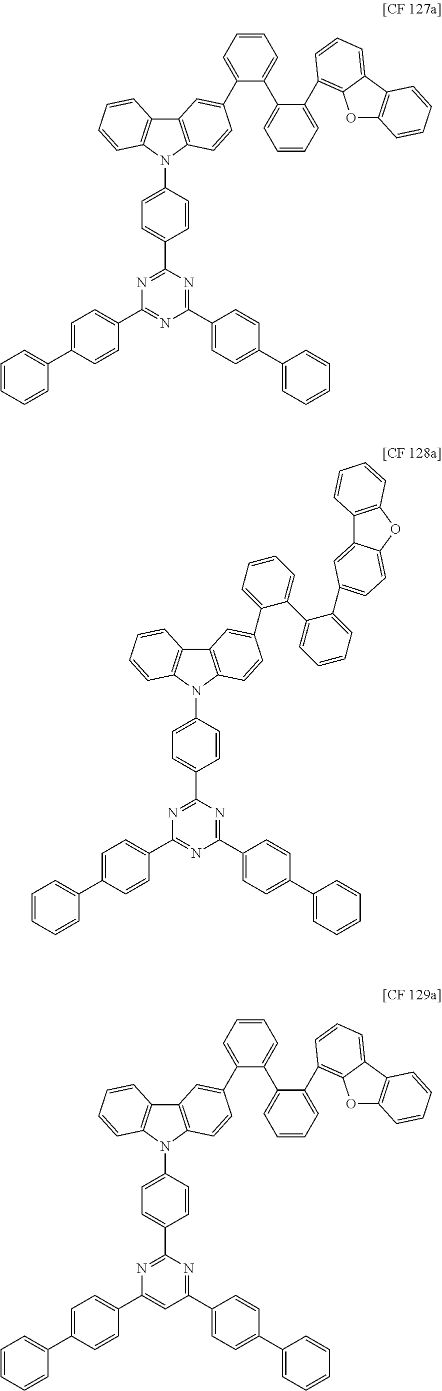 [SMILES: c1ccc(-c2ccc(-c3nc(-c4ccc(-c5ccccc5)cc4)nc(-c4ccc(-n5c6ccccc6c6cc(-c7ccccc7-c7ccccc7-c7cccc8c7oc7ccccc78)ccc65)cc4)n3)cc2)cc1 ; c1ccc(-c2ccc(-c3nc(-c4ccc(-c5ccccc5)cc4)nc(-c4ccc(-n5c6ccccc6c6cc(-c7ccccc7-c7ccccc7-c7ccc8oc9ccccc9c8c7)ccc65)cc4)n3)cc2)cc1 ; c1ccc(-c2ccc(-c3cc(-c4ccc(-c5ccccc5)cc4)nc(-c4ccc(-n5c6ccccc6c6cc(-c7ccccc7-c7ccccc7-c7cccc8c7oc7ccccc78)ccc65)cc4)n3)cc2)cc1]

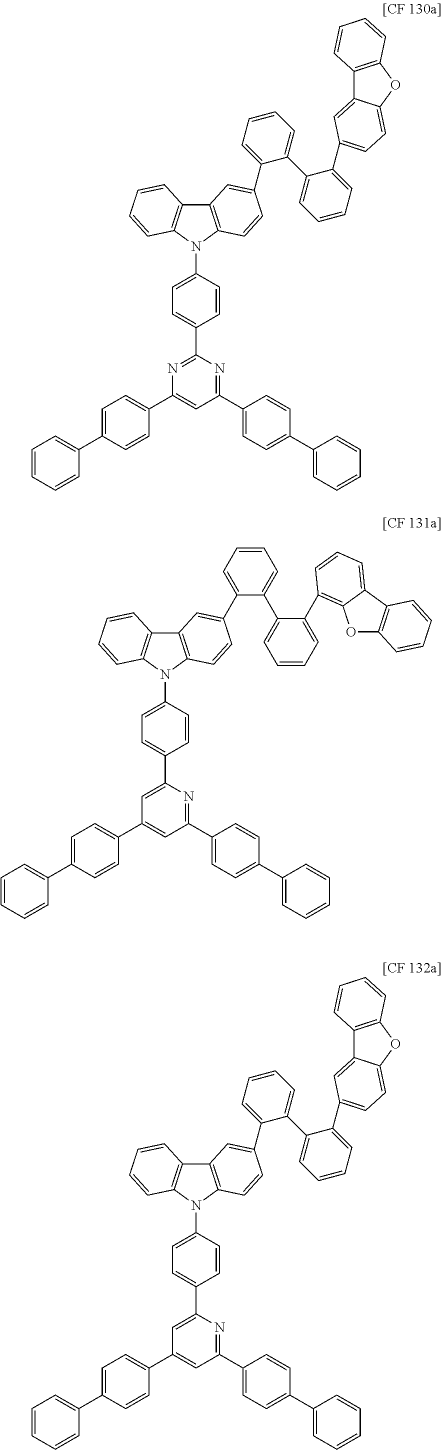 [SMILES: c1ccc(-c2ccc(-c3cc(-c4ccc(-c5ccccc5)cc4)nc(-c4ccc(-n5c6ccccc6c6cc(-c7ccccc7-c7ccccc7-c7ccc8oc9ccccc9c8c7)ccc65)cc4)n3)cc2)cc1 ; c1ccc(-c2ccc(-c3cc(-c4ccc(-c5ccccc5)cc4)nc(-c4ccc(-n5c6ccccc6c6cc(-c7ccccc7-c7ccccc7-c7cccc8c7oc7ccccc78)ccc65)cc4)c3)cc2)cc1 ; c1ccc(-c2ccc(-c3cc(-c4ccc(-c5ccccc5)cc4)nc(-c4ccc(-n5c6ccccc6c6cc(-c7ccccc7-c7ccccc7-c7ccc8oc9ccccc9c8c7)ccc65)cc4)c3)cc2)cc1]

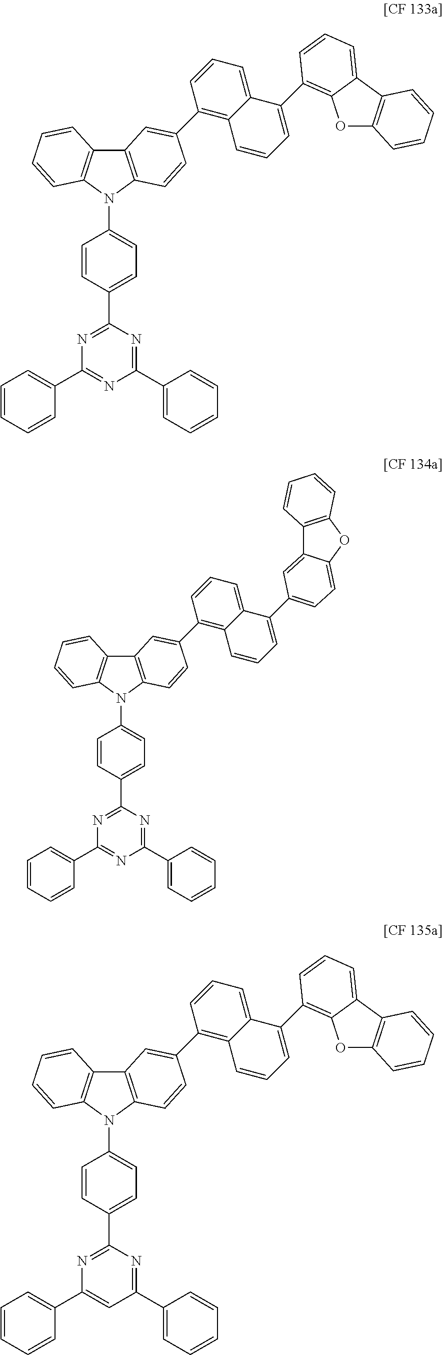 [SMILES: c1ccc(-c2nc(-c3ccccc3)nc(-c3ccc(-n4c5ccccc5c5cc(-c6cccc7c(-c8cccc9c8oc8ccccc89)cccc67)ccc54)cc3)n2)cc1 ; c1ccc(-c2nc(-c3ccccc3)nc(-c3ccc(-n4c5ccccc5c5cc(-c6cccc7c(-c8ccc9oc%10ccccc%10c9c8)cccc67)ccc54)cc3)n2)cc1 ; c1ccc(-c2cc(-c3ccccc3)nc(-c3ccc(-n4c5ccccc5c5cc(-c6cccc7c(-c8cccc9c8oc8ccccc89)cccc67)ccc54)cc3)n2)cc1]

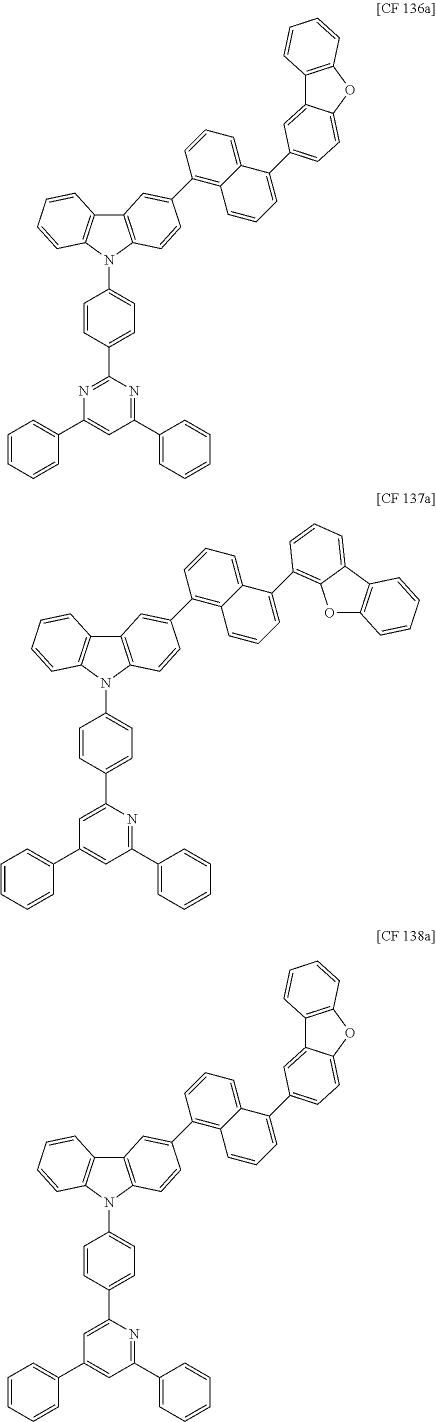 [SMILES: c1ccc(-c2cc(-c3ccccc3)nc(-c3ccc(-n4c5ccccc5c5cc(-c6cccc7c(-c8ccc9oc%10ccccc%10c9c8)cccc67)ccc54)cc3)n2)cc1 ; c1ccc(-c2cc(-c3ccccc3)nc(-c3ccc(-n4c5ccccc5c5cc(-c6cccc7c(-c8cccc9c8oc8ccccc89)cccc67)ccc54)cc3)c2)cc1 ; c1ccc(-c2cc(-c3ccccc3)nc(-c3ccc(-n4c5ccccc5c5cc(-c6cccc7c(-c8ccc9oc%10ccccc%10c9c8)cccc67)ccc54)cc3)c2)cc1]

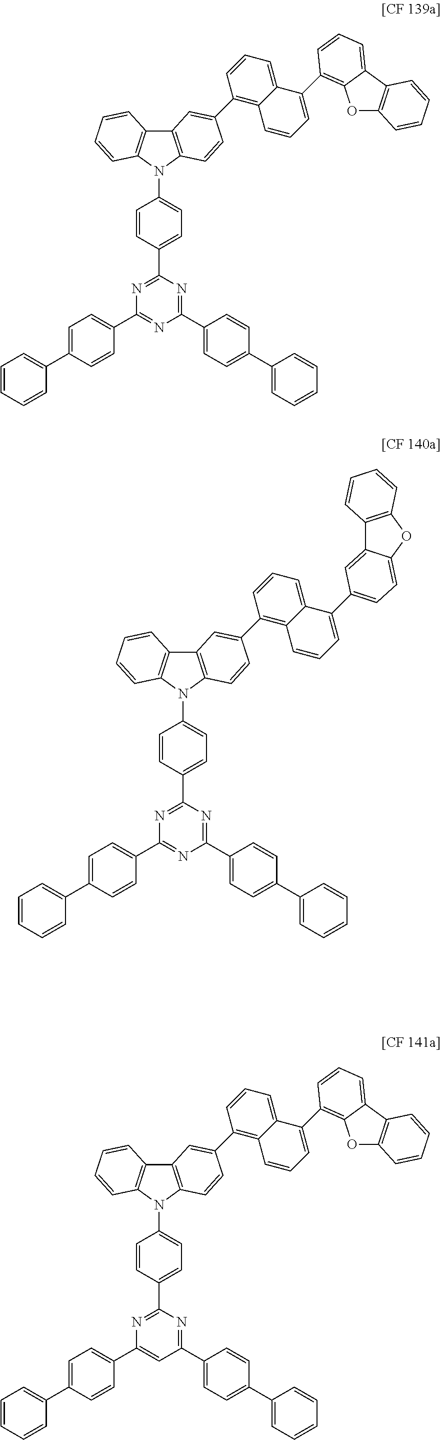 [SMILES: c1ccc(-c2ccc(-c3nc(-c4ccc(-c5ccccc5)cc4)nc(-c4ccc(-n5c6ccccc6c6cc(-c7cccc8c(-c9cccc%10c9oc9ccccc9%10)cccc78)ccc65)cc4)n3)cc2)cc1 ; c1ccc(-c2ccc(-c3nc(-c4ccc(-c5ccccc5)cc4)nc(-c4ccc(-n5c6ccccc6c6cc(-c7cccc8c(-c9ccc%10oc%11ccccc%11c%10c9)cccc78)ccc65)cc4)n3)cc2)cc1 ; c1ccc(-c2ccc(-c3cc(-c4ccc(-c5ccccc5)cc4)nc(-c4ccc(-n5c6ccccc6c6cc(-c7cccc8c(-c9cccc%10c9oc9ccccc9%10)cccc78)ccc65)cc4)n3)cc2)cc1]

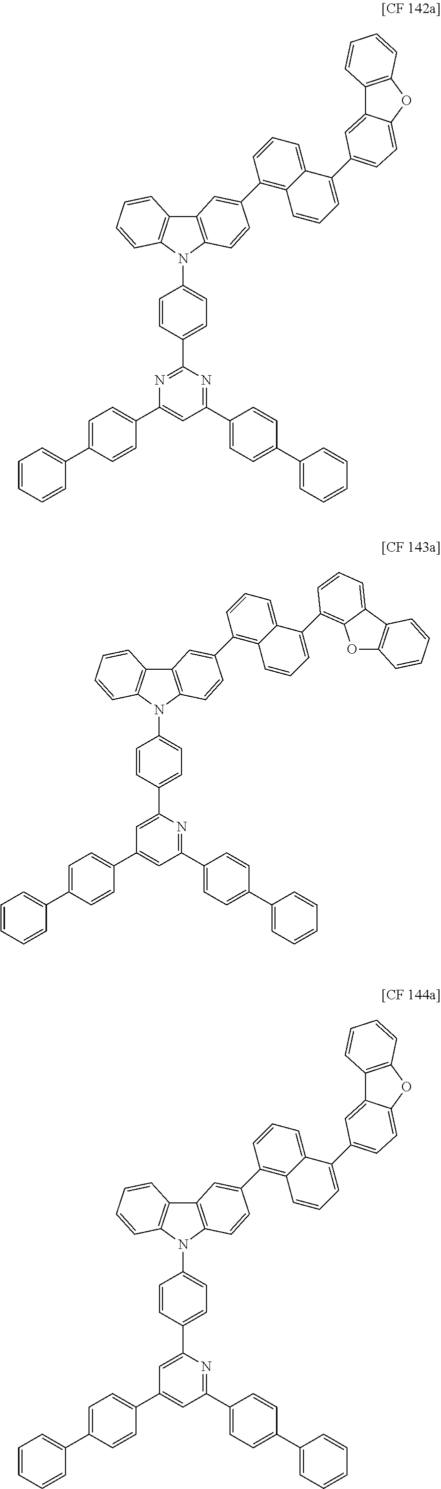 [SMILES: c1ccc(-c2ccc(-c3cc(-c4ccc(-c5ccccc5)cc4)nc(-c4ccc(-n5c6ccccc6c6cc(-c7cccc8c(-c9ccc%10oc%11ccccc%11c%10c9)cccc78)ccc65)cc4)n3)cc2)cc1 ; c1ccc(-c2ccc(-c3cc(-c4ccc(-c5ccccc5)cc4)nc(-c4ccc(-n5c6ccccc6c6cc(-c7cccc8c(-c9cccc%10c9oc9ccccc9%10)cccc78)ccc65)cc4)c3)cc2)cc1 ; c1ccc(-c2ccc(-c3cc(-c4ccc(-c5ccccc5)cc4)nc(-c4ccc(-n5c6ccccc6c6cc(-c7cccc8c(-c9ccc%10oc%11ccccc%11c%10c9)cccc78)ccc65)cc4)c3)cc2)cc1]

The compound for an organic optoelectronic device may be represented by one of the following Chemical Formulae (CF) 1b to 40b. However, it is not limited to the following compounds.

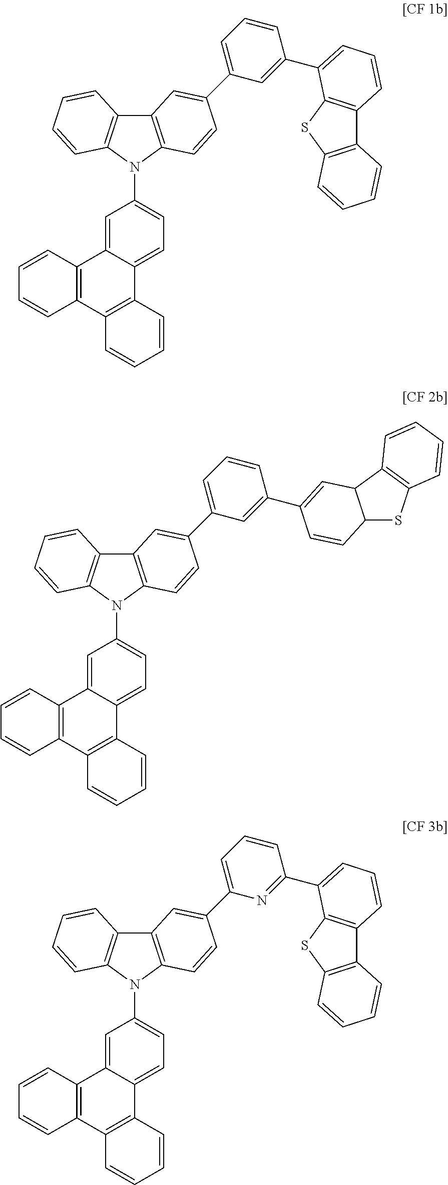 [SMILES: c1cc(-c2ccc3c(c2)c2ccccc2n3-c2ccc3c4ccccc4c4ccccc4c3c2)cc(-c2cccc3c2sc2ccccc23)c1 ; C1=CC2Sc3ccccc3C2C=C1c1cccc(-c2ccc3c(c2)c2ccccc2n3-c2ccc3c4ccccc4c4ccccc4c3c2)c1 ; c1cc(-c2ccc3c(c2)c2ccccc2n3-c2ccc3c4ccccc4c4ccccc4c3c2)nc(-c2cccc3c2sc2ccccc23)c1]

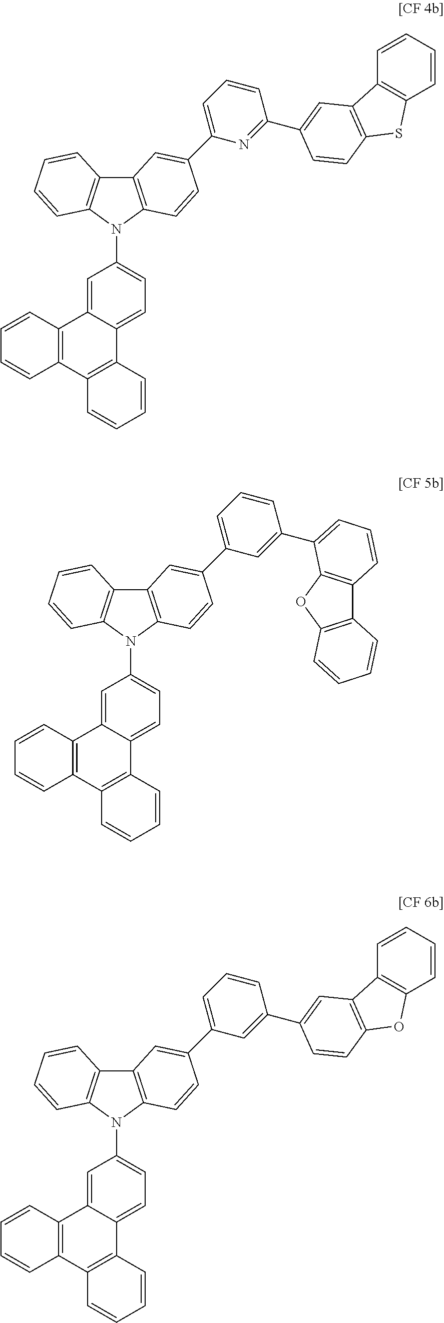 [SMILES: c1cc(-c2ccc3sc4ccccc4c3c2)nc(-c2ccc3c(c2)c2ccccc2n3-c2ccc3c4ccccc4c4ccccc4c3c2)c1 ; c1cc(-c2ccc3c(c2)c2ccccc2n3-c2ccc3c4ccccc4c4ccccc4c3c2)cc(-c2cccc3c2oc2ccccc23)c1 ; c1cc(-c2ccc3oc4ccccc4c3c2)cc(-c2ccc3c(c2)c2ccccc2n3-c2ccc3c4ccccc4c4ccccc4c3c2)c1]

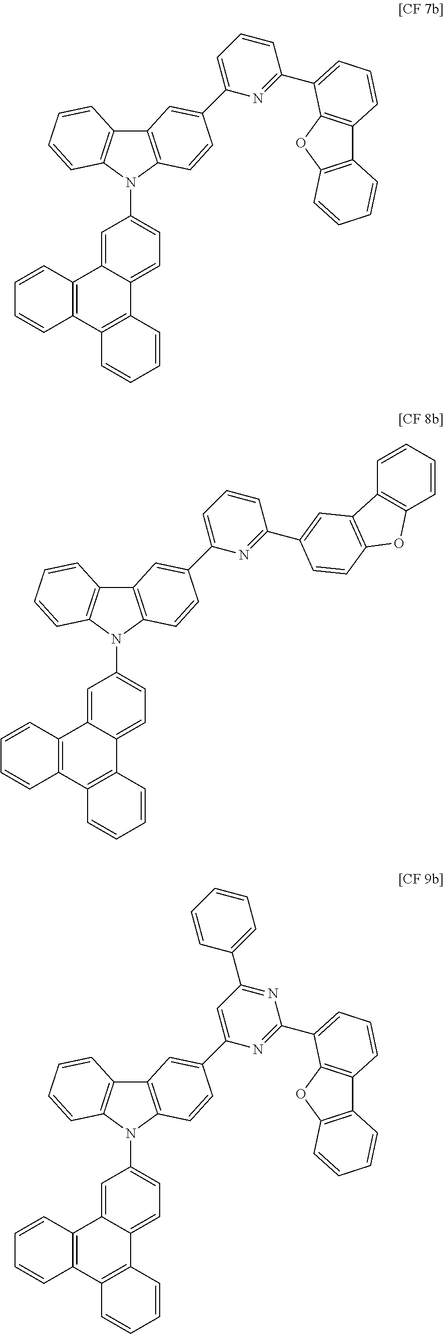 [SMILES: c1cc(-c2ccc3c(c2)c2ccccc2n3-c2ccc3c4ccccc4c4ccccc4c3c2)nc(-c2cccc3c2oc2ccccc23)c1 ; c1cc(-c2ccc3oc4ccccc4c3c2)nc(-c2ccc3c(c2)c2ccccc2n3-c2ccc3c4ccccc4c4ccccc4c3c2)c1 ; c1ccc(-c2cc(-c3ccc4c(c3)c3ccccc3n4-c3ccc4c5ccccc5c5ccccc5c4c3)nc(-c3cccc4c3oc3ccccc34)n2)cc1]

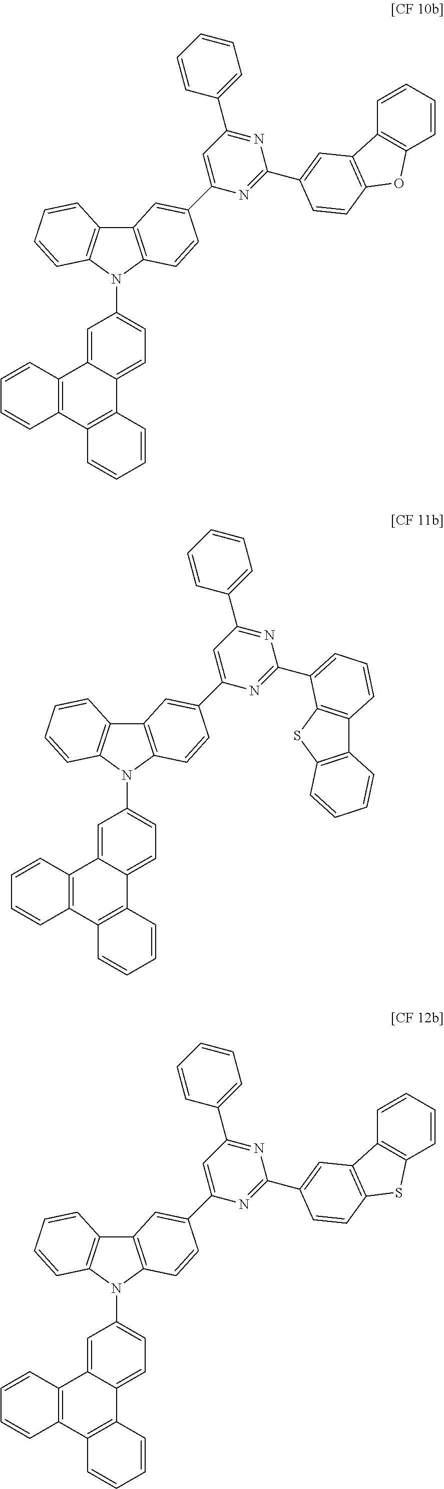 [SMILES: c1ccc(-c2cc(-c3ccc4c(c3)c3ccccc3n4-c3ccc4c5ccccc5c5ccccc5c4c3)nc(-c3ccc4oc5ccccc5c4c3)n2)cc1 ; c1ccc(-c2cc(-c3ccc4c(c3)c3ccccc3n4-c3ccc4c5ccccc5c5ccccc5c4c3)nc(-c3cccc4c3sc3ccccc34)n2)cc1 ; c1ccc(-c2cc(-c3ccc4c(c3)c3ccccc3n4-c3ccc4c5ccccc5c5ccccc5c4c3)nc(-c3ccc4sc5ccccc5c4c3)n2)cc1]

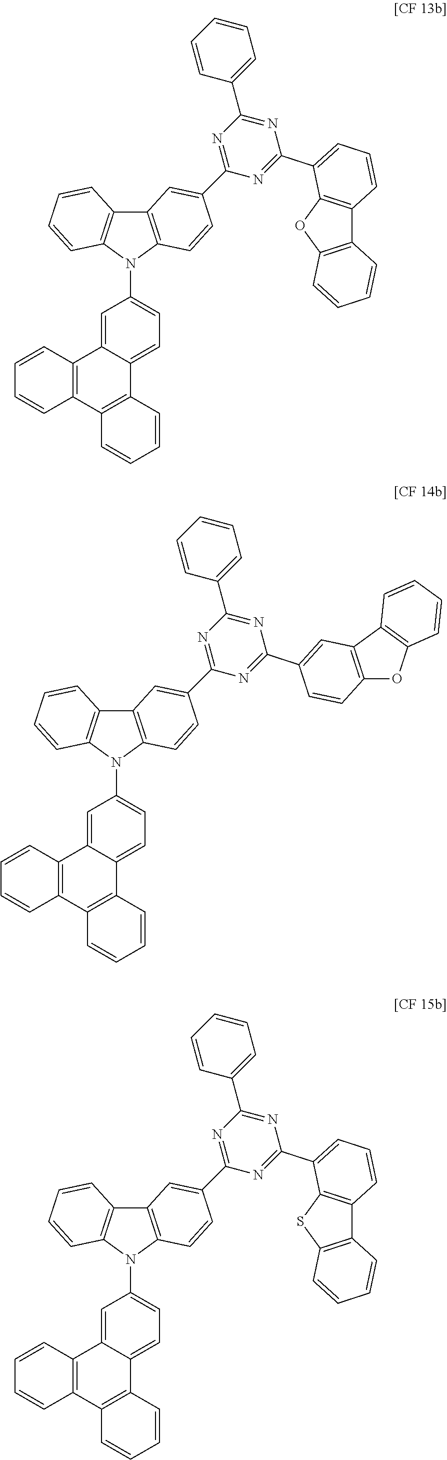 [SMILES: c1ccc(-c2nc(-c3ccc4c(c3)c3ccccc3n4-c3ccc4c5ccccc5c5ccccc5c4c3)nc(-c3cccc4c3oc3ccccc34)n2)cc1 ; c1ccc(-c2nc(-c3ccc4oc5ccccc5c4c3)nc(-c3ccc4c(c3)c3ccccc3n4-c3ccc4c5ccccc5c5ccccc5c4c3)n2)cc1 ; c1ccc(-c2nc(-c3ccc4c(c3)c3ccccc3n4-c3ccc4c5ccccc5c5ccccc5c4c3)nc(-c3cccc4c3sc3ccccc34)n2)cc1]

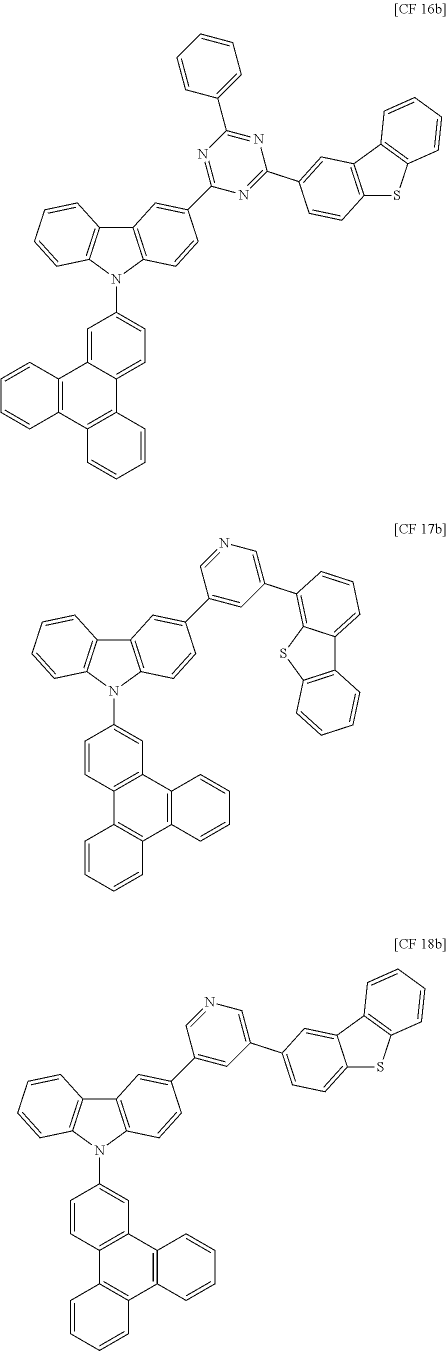 [SMILES: c1ccc(-c2nc(-c3ccc4sc5ccccc5c4c3)nc(-c3ccc4c(c3)c3ccccc3n4-c3ccc4c5ccccc5c5ccccc5c4c3)n2)cc1 ; c1ccc2c(c1)sc1c(-c3cncc(-c4ccc5c(c4)c4ccccc4n5-c4ccc5c6ccccc6c6ccccc6c5c4)c3)cccc12 ; c1ccc2c(c1)sc1ccc(-c3cncc(-c4ccc5c(c4)c4ccccc4n5-c4ccc5c6ccccc6c6ccccc6c5c4)c3)cc12]

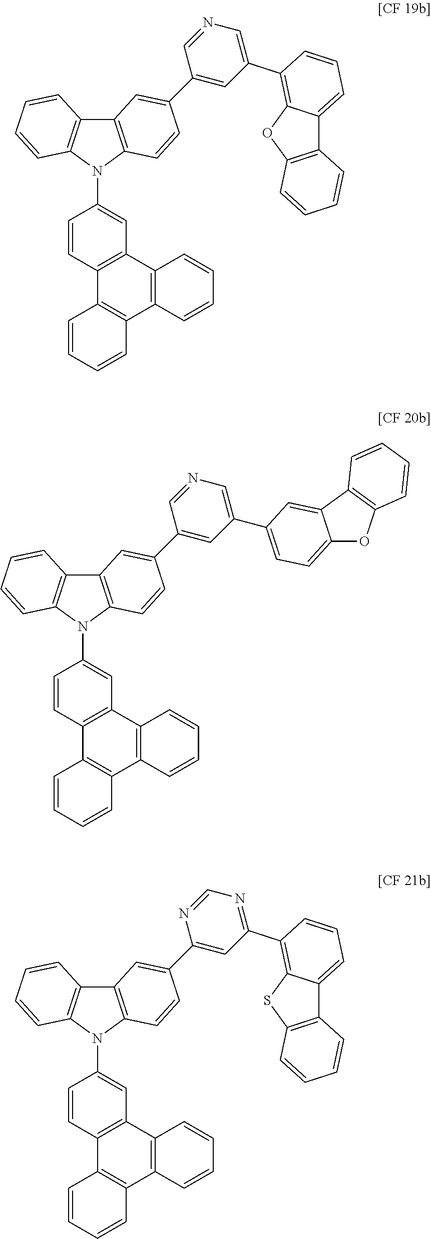 [SMILES: c1ccc2c(c1)oc1c(-c3cncc(-c4ccc5c(c4)c4ccccc4n5-c4ccc5c6ccccc6c6ccccc6c5c4)c3)cccc12 ; c1ccc2c(c1)oc1ccc(-c3cncc(-c4ccc5c(c4)c4ccccc4n5-c4ccc5c6ccccc6c6ccccc6c5c4)c3)cc12 ; c1ccc2c(c1)sc1c(-c3cc(-c4ccc5c(c4)c4ccccc4n5-c4ccc5c6ccccc6c6ccccc6c5c4)ncn3)cccc12]

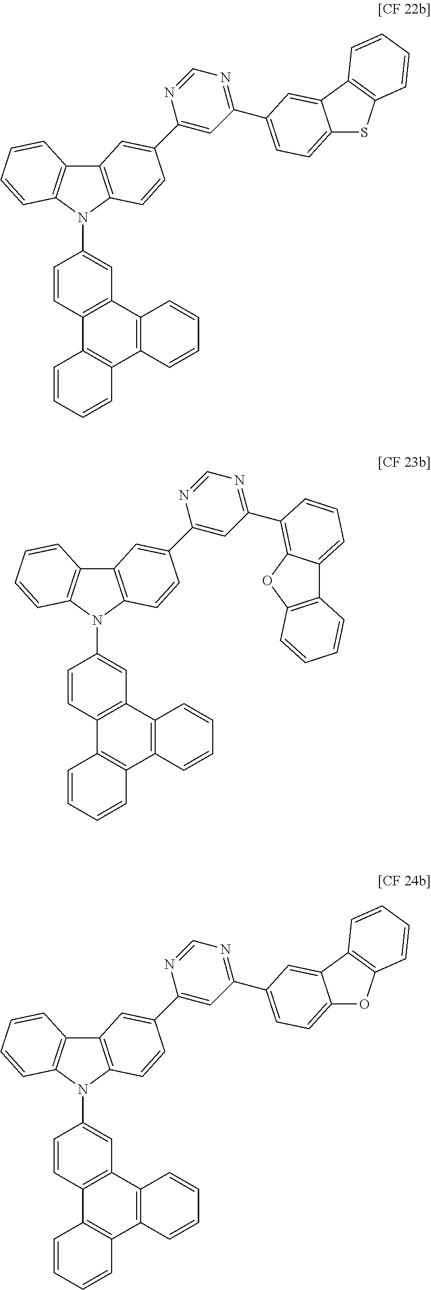 [SMILES: c1ccc2c(c1)sc1ccc(-c3cc(-c4ccc5c(c4)c4ccccc4n5-c4ccc5c6ccccc6c6ccccc6c5c4)ncn3)cc12 ; c1ccc2c(c1)oc1c(-c3cc(-c4ccc5c(c4)c4ccccc4n5-c4ccc5c6ccccc6c6ccccc6c5c4)ncn3)cccc12 ; c1ccc2c(c1)oc1ccc(-c3cc(-c4ccc5c(c4)c4ccccc4n5-c4ccc5c6ccccc6c6ccccc6c5c4)ncn3)cc12]

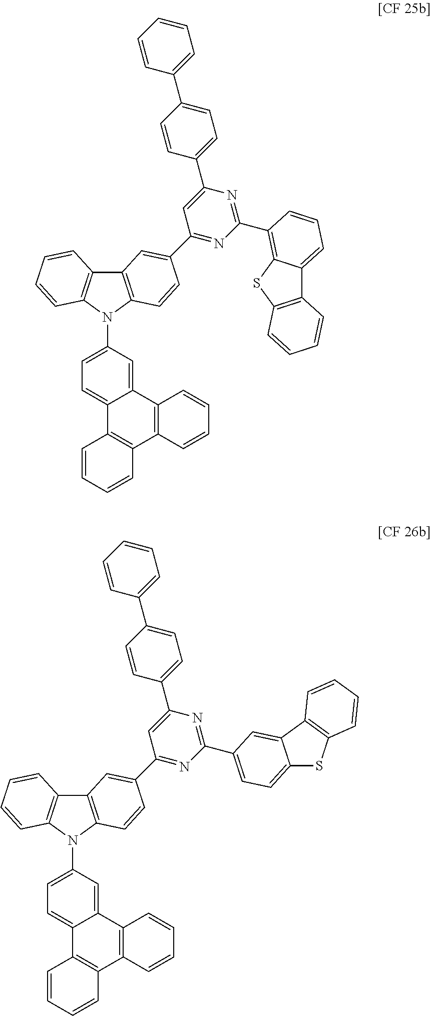 [SMILES: c1ccc(-c2ccc(-c3cc(-c4ccc5c(c4)c4ccccc4n5-c4ccc5c6ccccc6c6ccccc6c5c4)nc(-c4cccc5c4sc4ccccc45)n3)cc2)cc1 ; c1ccc(-c2ccc(-c3cc(-c4ccc5c(c4)c4ccccc4n5-c4ccc5c6ccccc6c6ccccc6c5c4)nc(-c4ccc5sc6ccccc6c5c4)n3)cc2)cc1]

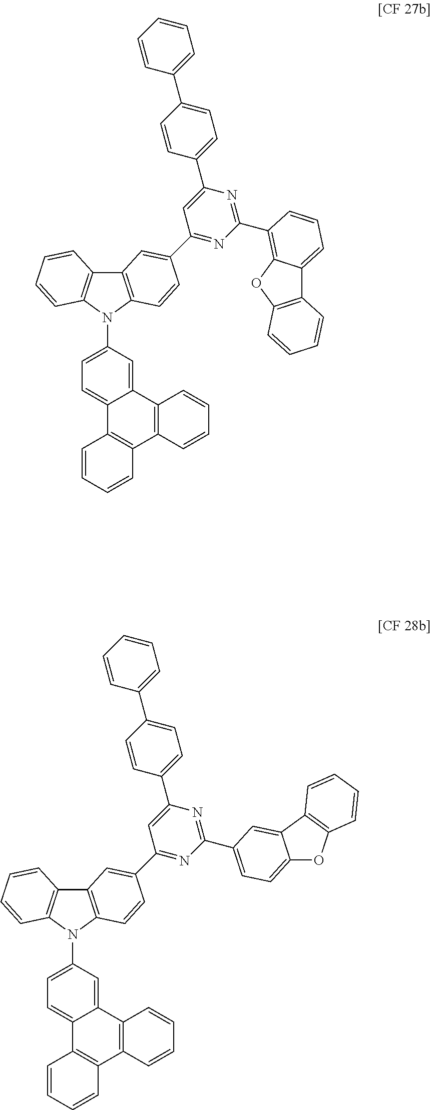 [SMILES: c1ccc(-c2ccc(-c3cc(-c4ccc5c(c4)c4ccccc4n5-c4ccc5c6ccccc6c6ccccc6c5c4)nc(-c4cccc5c4oc4ccccc45)n3)cc2)cc1 ; c1ccc(-c2ccc(-c3cc(-c4ccc5c(c4)c4ccccc4n5-c4ccc5c6ccccc6c6ccccc6c5c4)nc(-c4ccc5oc6ccccc6c5c4)n3)cc2)cc1]

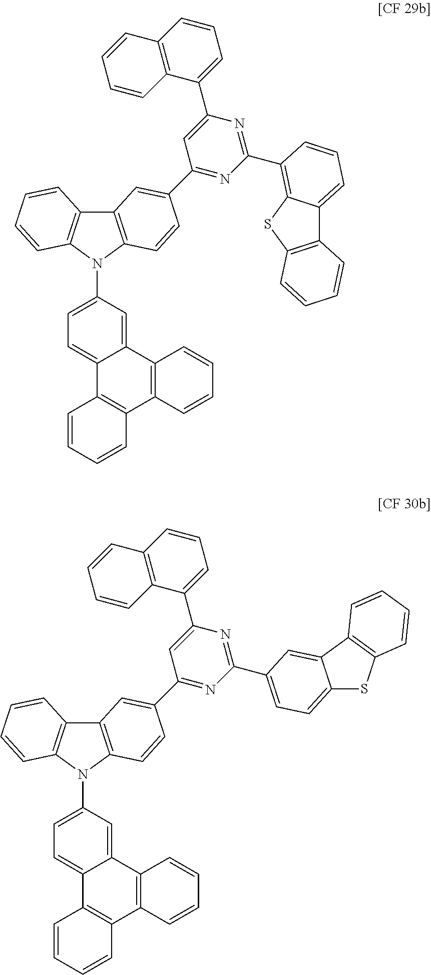 [SMILES: c1ccc2c(-c3cc(-c4ccc5c(c4)c4ccccc4n5-c4ccc5c6ccccc6c6ccccc6c5c4)nc(-c4cccc5c4sc4ccccc45)n3)cccc2c1 ; c1ccc2c(-c3cc(-c4ccc5c(c4)c4ccccc4n5-c4ccc5c6ccccc6c6ccccc6c5c4)nc(-c4ccc5sc6ccccc6c5c4)n3)cccc2c1]

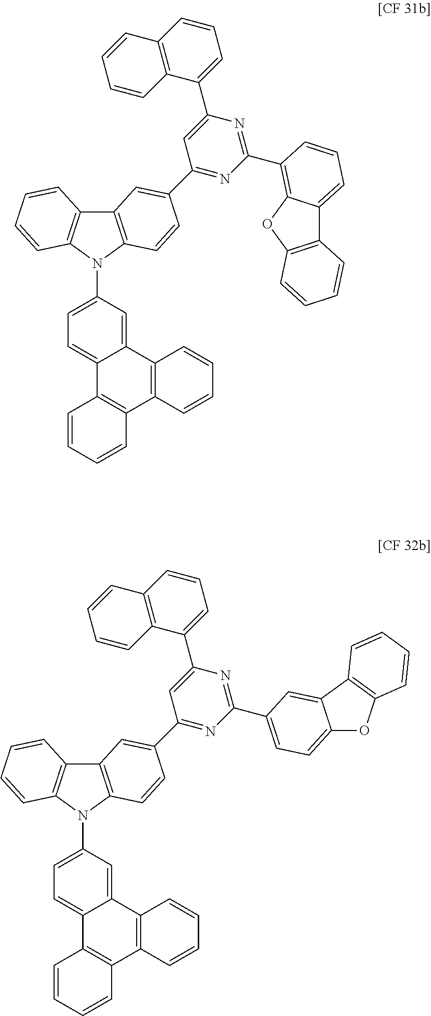 [SMILES: c1ccc2c(-c3cc(-c4ccc5c(c4)c4ccccc4n5-c4ccc5c6ccccc6c6ccccc6c5c4)nc(-c4cccc5c4oc4ccccc45)n3)cccc2c1 ; c1ccc2c(-c3cc(-c4ccc5c(c4)c4ccccc4n5-c4ccc5c6ccccc6c6ccccc6c5c4)nc(-c4ccc5oc6ccccc6c5c4)n3)cccc2c1]

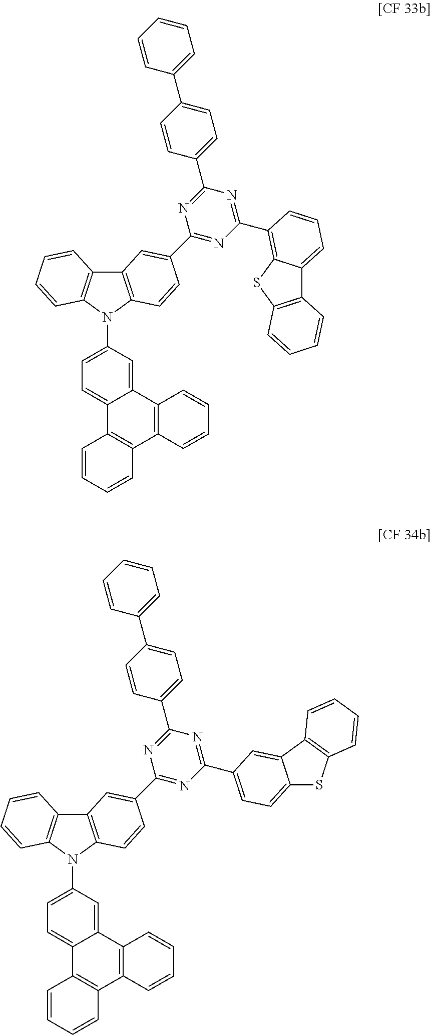 [SMILES: c1ccc(-c2ccc(-c3nc(-c4ccc5c(c4)c4ccccc4n5-c4ccc5c6ccccc6c6ccccc6c5c4)nc(-c4cccc5c4sc4ccccc45)n3)cc2)cc1 ; c1ccc(-c2ccc(-c3nc(-c4ccc5sc6ccccc6c5c4)nc(-c4ccc5c(c4)c4ccccc4n5-c4ccc5c6ccccc6c6ccccc6c5c4)n3)cc2)cc1]

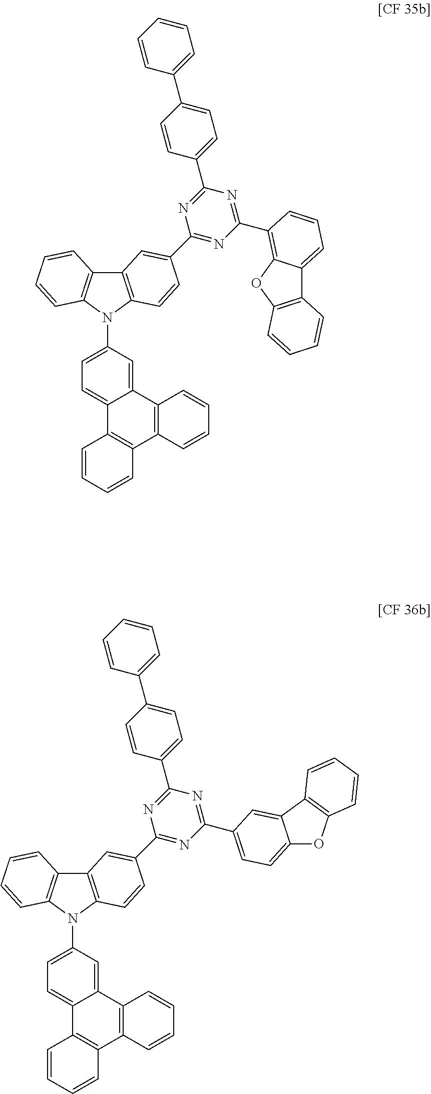 [SMILES: c1ccc(-c2ccc(-c3nc(-c4ccc5c(c4)c4ccccc4n5-c4ccc5c6ccccc6c6ccccc6c5c4)nc(-c4cccc5c4oc4ccccc45)n3)cc2)cc1 ; c1ccc(-c2ccc(-c3nc(-c4ccc5oc6ccccc6c5c4)nc(-c4ccc5c(c4)c4ccccc4n5-c4ccc5c6ccccc6c6ccccc6c5c4)n3)cc2)cc1]

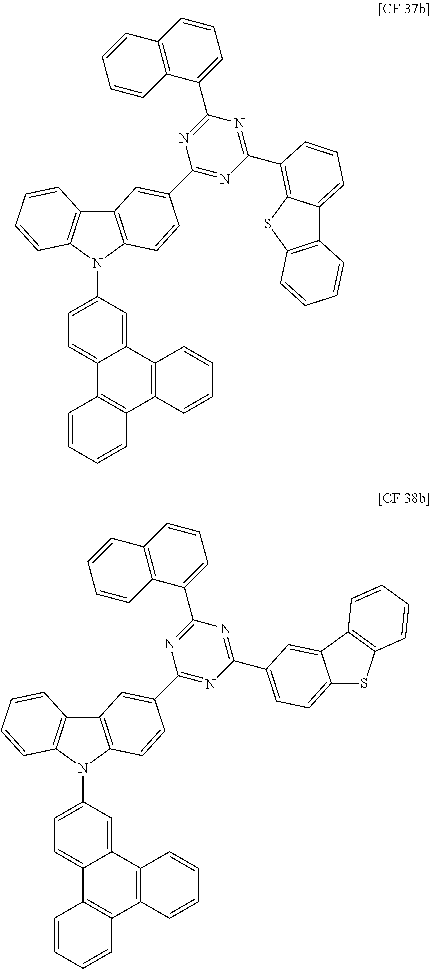 [SMILES: c1ccc2c(-c3nc(-c4ccc5c(c4)c4ccccc4n5-c4ccc5c6ccccc6c6ccccc6c5c4)nc(-c4cccc5c4sc4ccccc45)n3)cccc2c1 ; c1ccc2c(-c3nc(-c4ccc5sc6ccccc6c5c4)nc(-c4ccc5c(c4)c4ccccc4n5-c4ccc5c6ccccc6c6ccccc6c5c4)n3)cccc2c1]

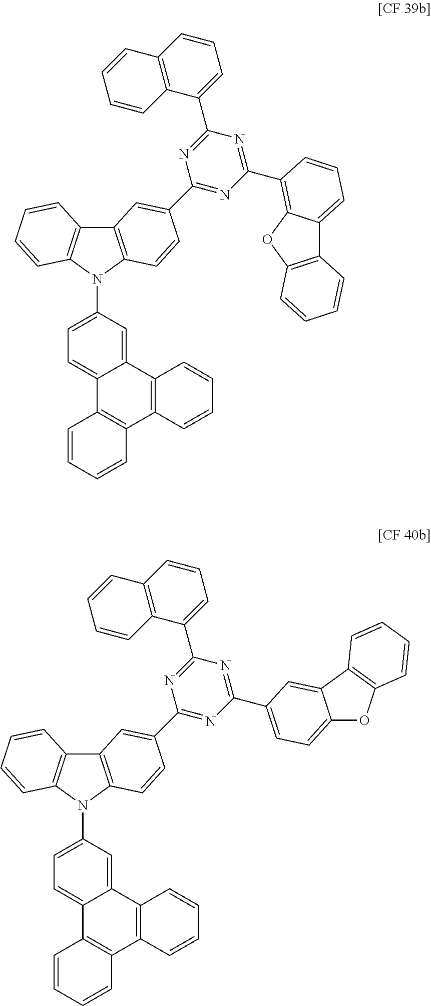 [SMILES: c1ccc2c(-c3nc(-c4ccc5c(c4)c4ccccc4n5-c4ccc5c6ccccc6c6ccccc6c5c4)nc(-c4cccc5c4oc4ccccc45)n3)cccc2c1 ; c1ccc2c(-c3nc(-c4ccc5oc6ccccc6c5c4)nc(-c4ccc5c(c4)c4ccccc4n5-c4ccc5c6ccccc6c6ccccc6c5c4)n3)cccc2c1]

The compound for an organic optoelectronic device including the above compounds may exhibit a glass transition temperature of greater than or equal to about 110° C. and a thermal decomposition temperature of greater than or equal to about 400° C., indicating improved thermal stability. Thereby, it may be possible to produce an organic optoelectronic device having a high efficiency.

The compound for an organic optoelectronic device including the above compounds may play a role for emitting light or injecting and/or transporting electrons, and may also act as a light emitting host with an appropriate dopant. Thus, the compound for an organic optoelectronic device may be used as, e.g., a phosphorescent or fluorescent host material, a blue light emitting dopant material, or an electron transport material.

The compound for an organic optoelectronic device according to an example embodiment may be used for an organic thin layer, and it may improve the life-span characteristics, efficiency characteristics, electrochemical stability, and thermal stability of an organic optoelectronic device and decrease the driving voltage.

An organic optoelectronic device according to an example embodiment includes the compound for an organic optoelectronic device. The organic optoelectronic device may include an organic photoelectric device, an organic light emitting diode, an organic solar cell, an organic transistor, an organic photo conductor drum, an organic memory device, or the like. For example, a compound for an organic optoelectronic device according to an example embodiment may be included in an electrode or an electrode buffer layer in the organic solar cell to improve the quantum efficiency, and it may be used as an electrode material for a gate, a source-drain electrode, or the like in the organic transistor.

An organic light emitting diode according to another example embodiment may include an anode, a cathode, and at least one organic thin layer between the anode and the cathode. The at least one organic thin layer may include a compound for an organic optoelectronic device according to an example embodiment.

The organic thin layer that may include the compound for an organic optoelectronic device may include a layer selected from the group of an emission layer, a hole transport layer (HTL), a hole injection layer (HIL), an electron transport layer (ETL), an electron injection layer (EIL), a hole blocking layer, and a combination thereof. The at least one layer may include the compound for an organic optoelectronic device according to an example embodiment. In an implementation, a compound for an organic optoelectronic device according to an example embodiment may be included in an electron transport layer (ETL) or an electron injection layer (EIL). When the compound for an organic optoelectronic device is included in the emission layer, the compound for an organic optoelectronic device may be included as a phosphorescent or fluorescent host, or as a fluorescent blue dopant material.

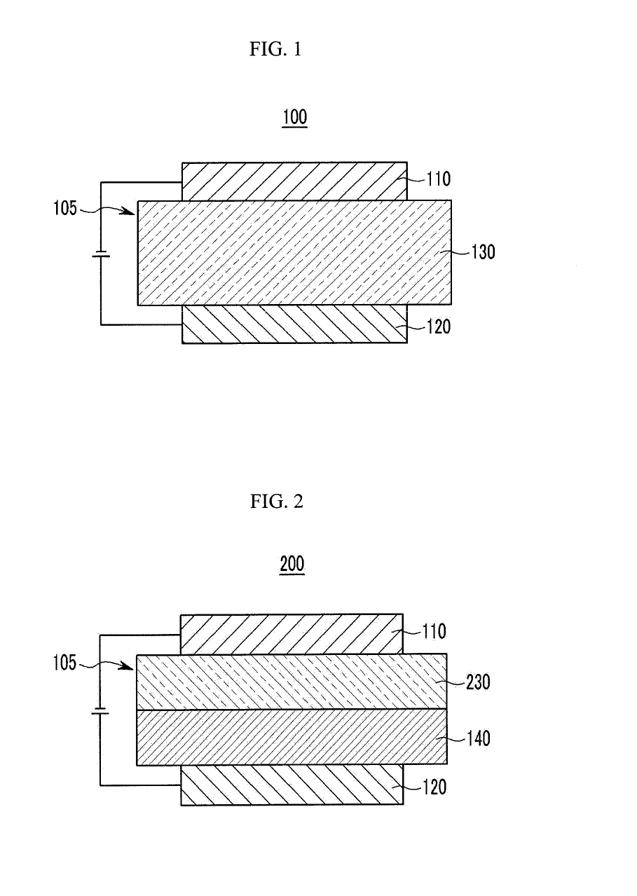

FIGS. 1 to 5 are cross-sectional views showing organic light emitting diodes including the compound for an organic optoelectronic device according to an example embodiment.

Referring to FIGS. 1 to 5, organic light emitting diodes 100, 200, 300, 400, and 500 according to example embodiments include at least one organic thin layer 105 interposed between an anode 120 and a cathode 110.

The anode 120 may include an anode material that may have a large work function to help hole injection into an organic thin layer. The anode material may include: a metal such as nickel, platinum, vanadium, chromium, copper, zinc, and gold, or alloys thereof; a metal oxide such as zinc oxide, indium oxide, indium tin oxide (ITO), and indium zinc oxide (IZO); a bonded metal and oxide such as ZnO:Al or SnO₂:Sb; or a conductive polymer such as poly(3-methylthiophene), poly[3,4-(ethylene-1,2-dioxy)thiophene] (PEDT), polypyrrole, and polyaniline, etc. In an implementation, the OLED may include a transparent electrode including indium tin oxide (ITO) as an anode.

The cathode 110 may include a cathode material having a small work function to help electron injection into an organic thin layer. The cathode material may include: a metal such as magnesium, calcium, sodium, potassium, titanium, indium, yttrium, lithium, gadolinium, aluminum, silver, tin, and lead, or alloys thereof; or a multi-layered material such as LiF/Al, Liq/Al, LiO₂/Al, LiF/Ca, LiF/Al, and BaF₂/Ca, etc. In an implementation, the OLED may include a metal electrode including aluminum as a cathode.

In the example embodiment shown in FIG. 1, the organic light emitting diode 100 includes an organic thin layer 105 including only an emission layer 130.

In the example embodiment shown in FIG. 2, a double-layered organic light emitting diode 200 includes an organic thin layer 105 including an emission layer 230 including an electron transport layer (ETL), and a hole transport layer (HTL) 140. As shown in FIG. 2, the organic thin layer 105 includes a double layer of the emission layer 230 and hole transport layer (HTL) 140. The emission layer 130 also functions as an electron transport layer (ETL), and the hole transport layer (HTL) 140 layer may have an excellent binding property with a transparent electrode such as ITO or an excellent hole transport capability.

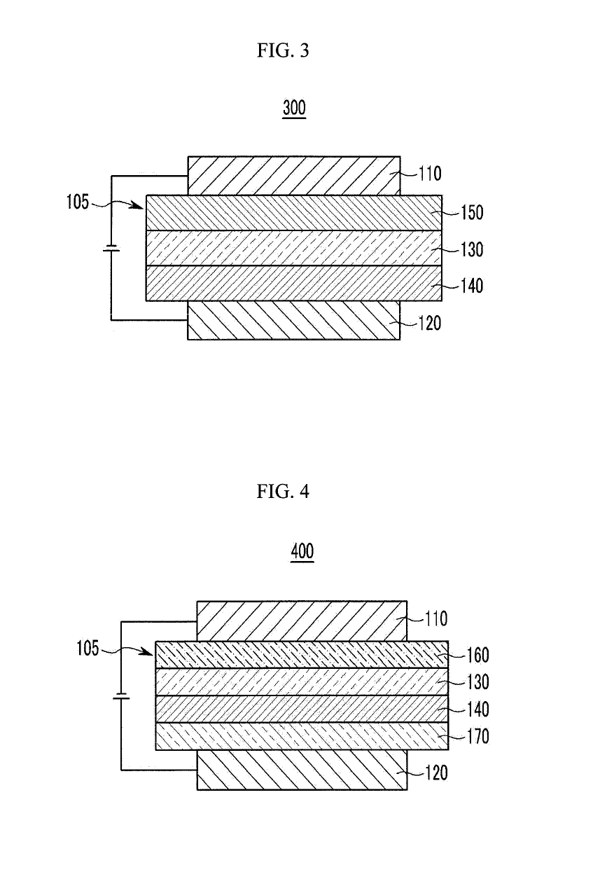

In the example embodiment shown in FIG. 3, a three-layered organic light emitting diode 300 includes an organic thin layer 105 including an electron transport layer (ETL) 150, an emission layer 130, and a hole transport layer (HTL) 140. The emission layer 130 is independently installed, and layers having an excellent electron transport capability or an excellent hole transport capability may be separately stacked.

In the example embodiment shown in FIG. 4, a four-layered organic light emitting diode 400 includes an organic thin layer 105 including an electron injection layer (EIL) 160, an emission layer 130, a hole transport layer (HTL) 140, and a hole injection layer (HIL) 170 that may help adherence with the anode of ITO.

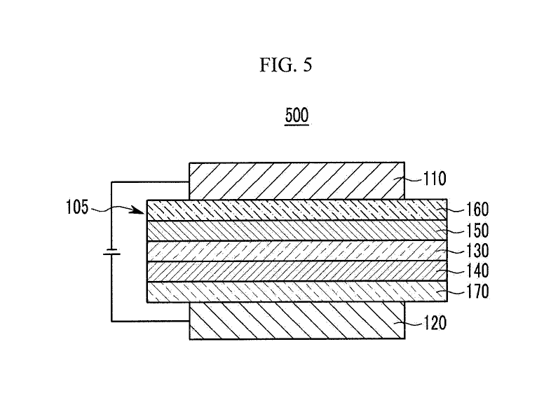

In the example embodiment shown in FIG. 5, a five layered organic light emitting diode 500 includes an organic thin layer 105 including an electron transport layer (ETL) 150, an emission layer 130, a hole transport layer (HTL) 140, and a hole injection layer (HIL) 170, and further includes an electron injection layer (EIL) 160 that may help achieve a low voltage.

In the example embodiments shown in FIGS. 1 to 5, the organic thin layer 105, which may include at least one selected from the group of an electron transport layer (ETL) 150, an electron injection layer (EIL) 160, emission layers 130 and 230, a hole transport layer (HTL) 140, a hole injection layer (HIL) 170, and combinations thereof, includes a compound for an organic optoelectronic device according to an embodiment. The compound for an organic optoelectronic device according to an embodiment may be used for an electron transport layer (ETL) 150 including the electron transport layer (ETL) 150 or electron injection layer (EIL) 160. When it is used for the electron transport layer (ETL), it may be possible to provide an organic light emitting diode having a simpler structure that does not use an additional hole blocking layer (not shown).

When the compound for an organic optoelectronic device is included in the emission layers 130 and 230, the compound for an organic optoelectronic device may be included as, e.g., a phosphorescent or fluorescent host or a fluorescent blue dopant.

The organic light emitting diode may be fabricated by, e.g., forming an anode on a substrate; forming an organic thin layer in accordance with a dry coating method such as evaporation, sputtering, plasma plating, and ion plating or a wet coating method such as spin coating, dipping, and flow coating; and providing a cathode thereon.

Another example embodiment is directed to a display device including the organic light emitting diode according to the above embodiment.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Preparation of Compound for Organic Optoelectronic Device

### Example 1

### Synthesis of Compound Represented by Chemical Formula 3b

A compound represented by the above Chemical Formula 3b as a compound for an organic optoelectronic device was synthesized according to the following Reaction Scheme 1.

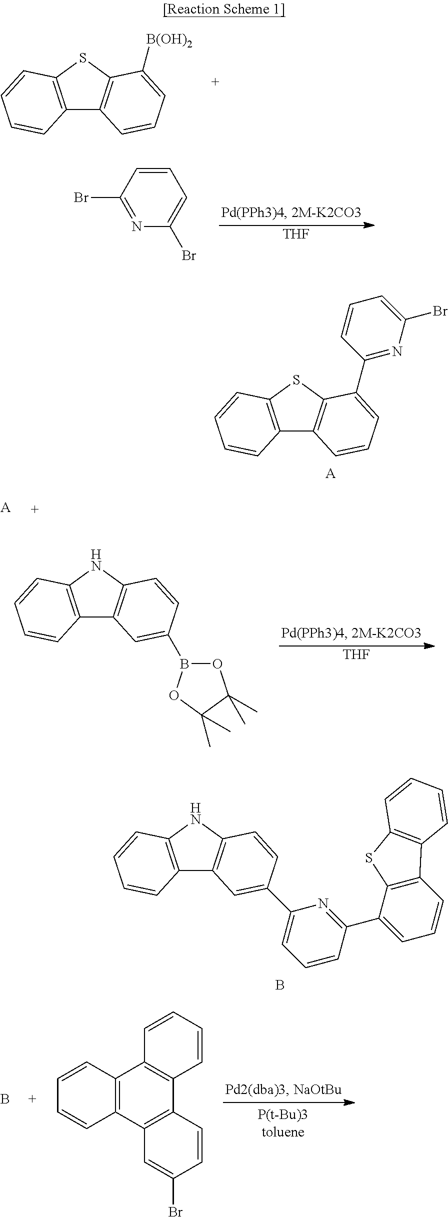

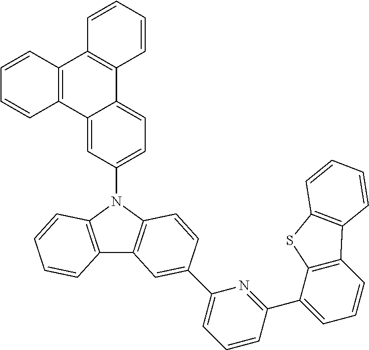 [SMILES: c1cc(-c2ccc3c(c2)c2ccccc2n3-c2ccc3c4ccccc4c4ccccc4c3c2)nc(-c2cccc3c2sc2ccccc23)c1]

### Step 1: Synthesis of Compound A

16.76 g (73.48 mmol) of dibenzothiophene-4-boronic acid, 25 g (105.81 mmol) of 2,6-dibromopyridine, and 4.25 g (3.67 mmol) of tetrakis(triphenylphosphine) palladium (0) were mixed with 250 mL of tetrahydrofuran and 100 mL of a 2 M potassium carbonate aqueous solution in a 500 mL round-bottomed flask equipped with an agitator under a nitrogen atmosphere, and the solution was refluxed under a nitrogen gas stream for 12 hours. When the reaction was complete, an organic layer produced therein was separated, and a mixture obtained by adding an anhydrous magnesium sulfate thereto was agitated. The obtained solution was filtered, and a solvent therein was all removed. 19 g of a compound A (76% yield) was obtained using column chromatography.

### Step 2: Synthesis of Compound B

13.3 g (39.08 mmol) of the compound A, 11.5 g (39.08 mmol) of carbazole-3-boronic acid pinacolate, and 2.26 g (1.95 mmol) of tetrakis(triphenylphosphine) palladium (0) were mixed with 120 mL of tetrahydrofuran and 60 mL of a 2 M potassium carbonate aqueous solution in a 500 mL round-bottomed flask equipped with an agitator under a nitrogen atmosphere, and the mixture was heated and refluxed for 12 hours under a nitrogen gas stream. When the reaction was complete, an organic layer produced therein was separated, and a mixture obtained by adding anhydrous magnesium sulfate thereto was agitated. The obtained solution was filtered, and a solvent therein was all removed. The resultant was recrystallized using chlorobenzene, obtaining 7 g of a compound B (42% yield).

### Step 3: Synthesis of Compound Represented by Chemical Formula 3b

7 g (16.41 mmol) of the compound B, 6.6 g (21.34 mmol) of bromotriphenylene, and 4.7 g (49.24 mmol) of tertiarybutoxy sodium were dissolved in 180 mL of toluene a 500 mL round-bottomed flask equipped with an agitator under a nitrogen atmosphere, and 0.751 g (0.82 mmol) of palladium dibenzylidene amine and 0.996 g (2.46 mmol) of tertiarybutyl phosphine (50%) were added thereto in a dropwise fashion. The reaction solution was heated and agitated at 110° C. under a nitrogen gas stream for 12 hours. When the reaction was complete, a solid produced by pouring methanol into the reactant was filtered and dissolved in chlorobenzene again, and a mixture obtained by adding activated carbon and anhydrous magnesium sulfate thereto was agitated. The agitated solution was filtered and recrystallized using chlorobenzene, obtaining 6.3 g of a compound 3b (59% yield).

calcd. C₄₇H₂₈N₂S: C, 86.47; H, 4.32; N, 4.29. found: C, 86.52; H, 4.48; N, 4.47

### Example 2

### Compound Represented by Chemical Formula 1b

A compound represented by the above Chemical Formula 1b as a compound for an organic optoelectronic device according to an embodiment was synthesized according to the following Reaction Scheme 2.

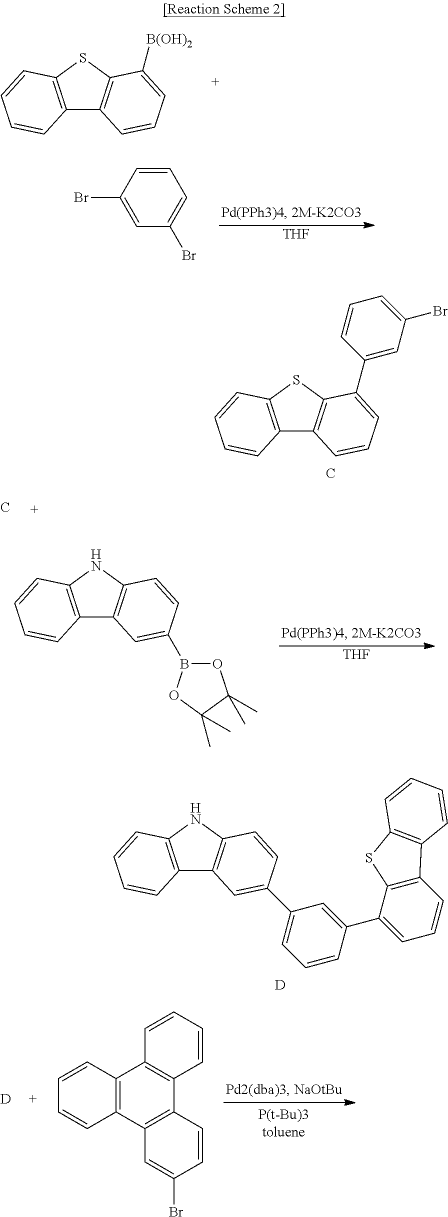

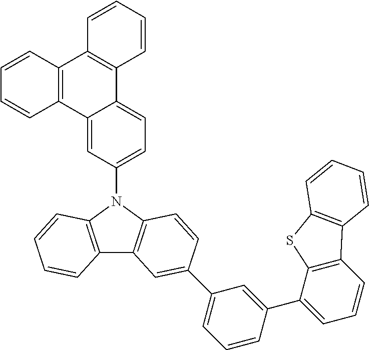 [SMILES: c1cc(-c2ccc3c(c2)c2ccccc2n3-c2ccc3c4ccccc4c4ccccc4c3c2)cc(-c2cccc3c2sc2ccccc23)c1]

### Step 1: Synthesis of Compound C

39.2 g (171.95 mmol) of dibenzothiophene-4-boronic acid, 81.1 g (343.90 mmol) of 1,3-dibromobenzene, and 9.94 g (8.6 mmol) of tetrakis(triphenylphosphine) palladium (0) were mixed with 1 L of tetrahydrofuran and 500 mL of a 2 M potassium carbonate aqueous solution in a 500 mL round-bottomed flask equipped with an agitator under a nitrogen atmosphere, and a mixture was heated and refluxed for 12 hours under the nitrogen atmosphere. When the reaction was complete, an organic layer produced therein was separated, and a mixture obtained by adding anhydrous magnesium sulfate thereto was agitated. The obtained solution was filtered, and a solvent was all removed. 41 g of a compound A (70% yield) was obtained using column chromatography.

### Step 2: Synthesis of Compound D

11.96 g (35.25 mmol) of the compound C, 13.43 g (45.82 mmol) of carbazol-3-boronic acid pinacolate, and 2.04 g (1.76 mmol) of tetrakis(triphenylphosphine) palladium (0) were mixed with 200 mL of tetrahydrofuran and 100 mL of a 2 M potassium carbonate aqueous solution in a 500 mL round-bottomed flask, and the mixture was heated and refluxed for 12 hours under a nitrogen gas stream. When the reaction was complete, an organic layer produced therein was separated, and a mixture obtained by adding anhydrous magnesium sulfate thereto was agitated. The obtained solution was filtered, and a solvent therein was all removed. 8.5 g of a compound D (57% yield) was separated using column chromatography.

### Step 3: Synthesis of Compound Represented by Chemical Formula 1b

8.9 g (20.97 mmol) of the compound D, 9.6 g (31.45 mmol) of bromo triphenylene, and 4.03 g (41.93 mmol) of tertiarybutoxy sodium were dissolved in 130 mL of toluene in a 500 mL round-bottomed flask equipped with an agitator under a nitrogen atmosphere, and 0.603 g (1.05 mmol) of palladium dibenzylideneamine and 0.636 g (3.15 mmol) of tertiarybutyl phosphine (50%) were added thereto in a dropwise fashion. The reaction solution was heated and agitated at 110° C. under a nitrogen gas stream for 12 hours. When the reaction was complete, a solid produced by pouring methanol into the reactant was filtered and dissolved in chlorobenzene again, and a mixture obtained by adding activated carbon and anhydrous magnesium sulfate thereto was agitated. The obtained solution was filtered and recrystallized in chlorobenzene, obtaining 7 g of a compound 1b (51% yield).

calcd. C₄₈H₂₉NS: C, 88.45; H, 4.48; N, 2.15. found: C, 88.52; H, 4.56; N, 2.23

### Example 3

### Compound Represented by Chemical Formula 4a

A compound represented by the above Chemical Formula 4a as a compound for an organic optoelectronic device according to an embodiment was synthesized according to the following Reaction Scheme 3.

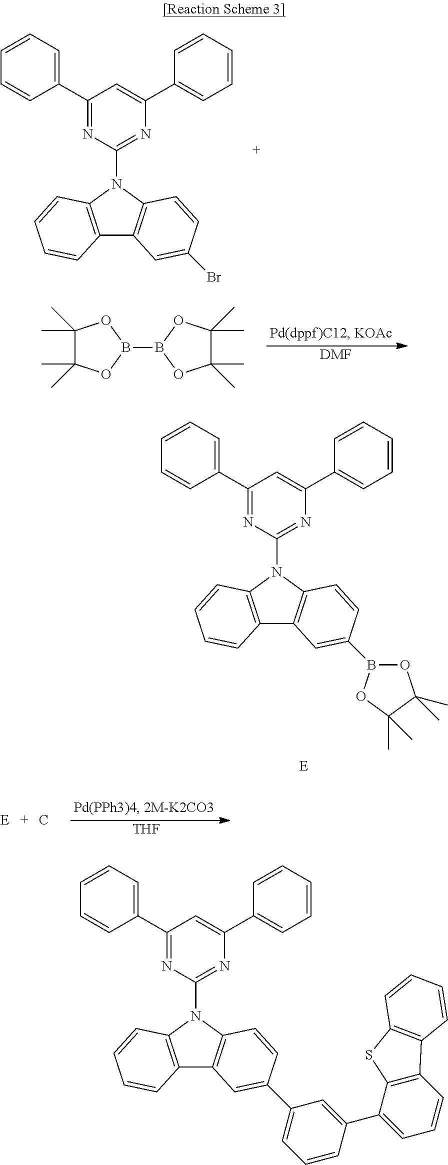

### Step 1: Synthesis of Compound E

40.95 g (85.97 mmol) of N-(4,6-diphenyl pyrimidin-2-yl)carbazol-3-bromide, 32.75 g (128.96 mmol) of bis(pinacolato)diboron, 25.31 g (257.91 mmol) of potassium acetate, and 3.51 g (4.3 mmol) of [1,1′-bis(diphenylphosphino)ferrocene]dichloro palladium were mixed with 480 mL of dimethylformamide in a 1 L round-bottomed flask equipped with an agitator under a nitrogen atmosphere, and the mixture was heated and refluxed under a nitrogen gas stream for 12 hours. When the reaction was complete, a solid produced by pouring the reactant into water was filtered and dissolved in dichloromethane, and a mixture obtained by adding anhydrous magnesium sulfate and activated carbon thereto was agitated. The obtained solution was filtered, and a solvent therein was all removed. Then, the resultant was dissolved in dichloromethane, and the solution was precipitated by an excessive amount of hexane, obtaining 30 g of a compound E (67% yield).

### Step 2: Synthesis of Compound Represented by Chemical Formula 4a

9.05 g (26.68 mmol) of the compound C, 13.97 g (26.68 mmol) of the compound D, and 1.54 g (1.33 mmol) of tetrakis(triphenylphosphine) palladium (0) were mixed with 200 mL of tetrahydrofuran and 100 mL of a 2 M potassium carbonate aqueous solution in a 500 mL round-bottomed flask equipped with an agitator under a nitrogen atmosphere, and the mixture was heated and refluxed under a nitrogen gas stream for 12 hours. When the reaction was complete, an organic layer produced therein was separated, and a mixture obtained by adding anhydrous magnesium sulfate and activated carbon thereto was agitated. The obtained solution was filtered, and a solvent therein was all removed. The resultant was recrystallized using toluene and hexane, obtaining 13.8 g of a compound 4a (79% yield).

calcd. C₄₆H₂₉N₃S: C, 84.25; H, 4.46; N, 6.41. found: C, 84.34; H, 4.48; N, 6.52

### Example 4

### Compound Represented by Chemical Formula 8a

A compound represented by the above Chemical Formula 8a as a compound for an organic optoelectronic device according to the an embodiment was synthesized according to the following Reaction Scheme 4.

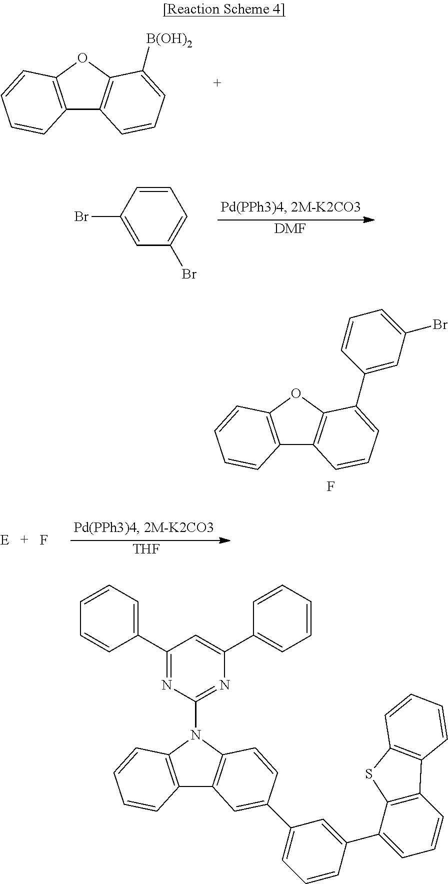

### Step 1: Synthesis of Compound F

17.5 g (82.51 mmol) of dibenzofuran-4-boronic acid, 38.93 g (165.03 mmol) of 1,3-dibromobenzene, and 4.77 g (4.13 mmol) of tetrakis(triphenylphosphine) palladium (0) were mixed with 520 mL of tetrahydrofuran and 200 mL of a 2 M potassium carbonate aqueous solution in a 500 mL round-bottomed flask equipped with an agitator under a nitrogen atmosphere, and the mixture was heated and refluxed under a nitrogen gas stream for 12 hours. When the reaction was complete, an organic layer produced therein was separated, and a mixture obtained by adding anhydrous magnesium sulfate thereto was agitated. The obtained solution was filtered, and a solvent therein was all removed. 16 g of a compound F (60% yield) was obtained using column chromatography.

### Step 2: Synthesis of Compound Represented by Chemical Formula 8a

15 g (28.66 mmol) of the compound E, 13.89 g (42.99 mmol) of the compound F, and 1.66 g (1.43 mmol) of tetrakis(triphenylphosphine) palladium (0) were mixed with 260 mL of tetrahydrofuran and 100 mL of a 2 M potassium carbonate aqueous solution in a 500 mL round-bottomed flask equipped with an agitator under a nitrogen atmosphere, and the mixture was heated and refluxed under a nitrogen gas stream for 12 hours. When the reaction was complete, and an organic layer produced therein was separated, and a mixture obtained by adding anhydrous magnesium sulfate and activated carbon thereto was agitated. The obtained solution was filtered, and a solvent therein was all removed. The resultant was recrystallized by using chlorobenzene and hexane, obtaining 13 g of a compound 8a (71% yield).

calcd. C₄₆H₂₉N₃S: C, 84.25; H, 4.46; N, 6.41. found: C, 84.31; H, 4.49; N, 6.54

### Fabrication of Organic Light Emitting Diode

### Example 5

### Fabrication of Organic Light Emitting Diode Using Compound of Example 3

An organic light emitting diode was fabricated by using the compound according to Example 3 and Ir(PPy)₃ as a dopant. 1000 Å-thick ITO was used as an anode, while 1000 Å-thick aluminum (Al) was used as a cathode.

Specifically, a method of manufacturing the organic light emitting diode included cutting an ITO glass substrate having sheet resistance of 15 Ω/cm² into a size of 50 mm×50 mm×0.7 mm and ultrasonic wave-cleaning it in acetone, isopropyl alcohol, and pure water for 15 minutes respectively and then, UV-ozone cleaning it for 30 minutes.

On the substrate, a 800 Å-thick hole transport layer (HTL) was formed by depositing N,N′-di(1-naphthyl)-N,N′-diphenylbenzidine (NPB) (70 nm) and 4,4′,4″-tri(N-carbazolyl)triphenylamine (TCTA) (10 nm) under conditions of a vacuum degree of 650×10⁻⁷ Pa and a deposition rate of 0.1 to 0.3 nm/s.

Then, a 300 Å-thick emission layer was formed thereon using the compound according to Example 2 under the same vacuum deposit conditions, and Ir(PPy)₃ as a phosphorescent dopant was simultaneously deposited. Herein, the deposition rate of the phosphorescent dopant was adjusted to include 7 wt % of the phosphorescent dopant based on 100 wt % of the emission layer.

On the emission layer, bis(8-hydroxy-2-methylquinolinolato)-aluminum biphenoxide (BAlq) was deposit to form a 50 Å-thick hole-blocking layer under the same vacuum deposit conditions.

Subsequently, a 200 Å-thick electron transport layer (ETL) was formed thereon by depositing Alg₃ under the same vacuum deposit conditions.

On the electron transport layer (ETL), LiF and Al were sequentially deposited to form a cathode, fabricating an organic light emitting diode.

The organic light emitting diode had a structure of ITO/NPB (70 nm)/TCTA (10 nm)/EML (the compound of Example 3 (93 wt %)+Ir(PPy)₃ (7 wt %), 30 nm)/Balq (5 nm)/Alq₃ (20 nm)/LiF (1 nm)/Al (100 nm).

### Example 6

### Fabrication of Organic Light Emitting Diode Using Compound of Example 4

An organic light emitting diode was fabricated according to the same method as Example 5 except for using the compound according to Example 4 as a host for an emission layer instead of the compound according to Example 3.

### Comparative Example 1

### Carbazolebiphenyl (CBP)

An organic light emitting diode was fabricated according to the same method as Example 5 except for using 4,4-N,N-dicarbazolebiphenyl (CBP) as a host for an emission layer instead of the compound according to Example 3.

Performance Measurement of Organic Light Emitting Diode

Each organic light emitting diode according to Examples 5 and 6 and Comparative Example 1 was measured regarding current density and luminance changes depending on voltage and luminous efficiency. The measurements were specifically performed in the following method. The results are provided in the following Table 1.

(1) Measurement of Current Density Change Depending on Voltage Change

The fabricated organic light emitting diodes were measured for current value flowing in the unit device while increasing the voltage from 0 V to 10 V using a current-voltage meter (Keithley 2400), and the measured current value was divided by area to provide the result.

(2) Measurement of Luminance Change Depending on Voltage Change

The fabricated organic light emitting diodes were measured for luminance while increasing the voltage form 0 V to 10 V using a luminance meter (Minolta Cs-1000A).

(3) Measurement of Luminous Efficiency

Current efficiency (cd/A) and electric power efficiency (lm/W) at the same luminance (9000 cd/m²) were calculated by using luminance and current density from the items (1) and (2) and voltage.

(4) Color coordinate was measured using a luminance meter (Minolta Cs-1000A), and the results were shown.

TABLE 1

| | | | 9000 cd/m² | |
|---|---|---|---|---|
| | | Driving | Luminous | Color |
| | Host material of | voltage | efficiency | coordinate |
| | emission layer | (V) | (cd/A) | (x, y) |
| Example 5 | Example 3 | 5.7 | 52.7 | 0.32, 0.66 |
| Example 6 | Example 4 | 5.5 | 52.2 | 0.33, 0.66 |
| Comparative | CBP | 4.8 | 31.4 | 0.33, 0.63 |
| Example 1 | | | | |

Referring to Table 1, the organic light emitting diode using the compound synthesized according to embodiments showed luminous efficiency of greater than or equal to 50 cd/A, which exceeded the luminous efficiency of CBP in Comparative Example 1. Therefore, the compounds according to embodiments may be used to form a good material for an organic light emitting diode.

By way of summation and review, an organic light emitting diode (OLED) may convert electrical energy into light by applying current to an organic light emitting material. The OLED may have a structure in which a functional organic material layer is interposed between an anode and a cathode. The organic material layer may include a multi-layer including different materials, for example a hole injection layer (HIL), a hole transport layer (HTL), an emission layer, an electron transport layer (ETL), and an electron injection layer (EIL), in order to improve efficiency and stability of an organic photoelectric device.

In such an organic light emitting diode, when a voltage is applied between an anode and a cathode, holes from the anode and electrons from the cathode may be injected to an organic material layer and recombined to generate excitons having high energy. The generated excitons may generate light having certain wavelengths while shifting to a ground state.

A phosphorescent light emitting material may be used for a light emitting material of an organic optoelectronic device, in addition to the fluorescent light emitting material. Such a phosphorescent material may emits light by transporting the electrons from a ground state to an exited state, non-radiance transiting of a singlet exciton to a triplet exciton through intersystem crossing, and transiting a triplet exciton to a ground state to emit light.

As described above, in an organic light emitting diode, an organic material layer may include a light emitting material and a charge transport material, for example a hole injection material, a hole transport material, an electron transport material, an electron injection material, and the like.

The light emitting material may be classified as blue, green, and red light emitting materials according to emitted colors, and yellow and orange light emitting materials to emit colors approaching natural colors.

When one material is used as a light emitting material, a maximum light emitting wavelength may be shifted to a long wavelength or color purity may decrease because of interactions between molecules, or device efficiency may decrease because of a light emitting quenching effect. Therefore, a host/dopant system may be included as a light emitting material in order to improve color purity, and increase luminous efficiency and stability through energy transfer.

In order to implement excellent performance of an organic light emitting diode, a material constituting an organic material layer, for example a hole injection material, a hole transport material, a light emitting material, an electron transport material, an electron injection material, and a light emitting material such as a host and/or a dopant, should be stable and have good efficiency. This material may also be suitable for other organic optoelectronic devices.

A low molecular weight organic material-containing light emitting diode may be manufactured as a thin film in a vacuum deposition method, and may afford good efficiency and life-span performance. A polymeric organic material-containing light emitting diode may be manufactured in an inkjet or spin coating method, and may afford advantages of low initial cost and suitability for large-sized substrates

Both low molecular weight material-containing and polymeric organic material-containing light emitting diodes may afford advantages of self-light emitting, high speed response, wide viewing angle, ultra-thin, high image quality, durability, large driving temperature range, and the like. In particular, they may afford good visibility due to self-light emitting characteristics compared with an LCD (liquid crystal display) and have an advantage of decreasing thickness and weight, relative to an LCD, up to a third, because they do not need a backlight.

In addition, since they have a fast response speed, e.g., 1000 times faster in microsecond units than LCD, they may be used to realize a motion picture without after-image. Based on these advantages, they have been remarkably developed to have 80 times efficiency and more than 100 times life-span since they come out for the first time in the late 1980s. Recently, they are being considered for increasingly larger applications such as a 40-inch organic light emitting diode panel.

Improved luminous efficiency and life-span are desired. Further, luminous efficiency may be enhanced by smooth combination between holes and electrons in an emission layer. If an organic material has slower electron mobility than hole mobility, it may exhibit inefficient combination between holes and electrons. Accordingly, it is desirable for a compound to increase electron injection and mobility from a cathode while simultaneously preventing movement of holes.

As described above, embodiments may provide a compound for an organic optoelectronic device having excellent life-span, efficiency, electrochemical stability, driving voltage, and thermal stability, an organic light emitting diode including the compound, and a display device including the organic light emitting diode. Embodiments may provide a compound for an organic optoelectronic device that may act as light emission, or electron injection and transport material, and also act as a light emitting host along with an appropriate dopant. Embodiments may provide an organic light emitting diode having high luminous efficiency at a low driving voltage.

< Description of Symbols>

| | |
|---|---|
| 100: organic light emitting diode | 110: cathode |
| 120 anode | 105: organic thin layer |
| 130: emission layer | 140: hole transport layer (HTL) |
| 150: electron transport layer (ETL) | 160: electron injection layer (EIL) |
| 170: hole injection layer (HIL) | 230: emission layer + electron |
| | transport layer (ETL) |

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A compound for an organic optoelectronic device, the compound being represented by the following Chemical Formula 1: 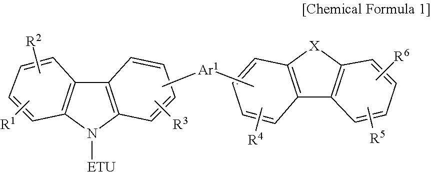
wherein, in the above Chemical Formula 1,
X is S, O, or Se,
ETU is a substituted or unsubstituted C2 to C30 heteroaryl group having electron characteristics,
Ar¹ is a substituted or unsubstituted C6 to C30 aryl group; or a substituted or unsubstituted C2 to C30 heteroaryl group, and
R¹ to R⁶ are each independently hydrogen; deuterium; a substituted or unsubstituted C1 to C20 alkyl group; a substituted or unsubstituted C6 to C30 aryl group; or a substituted or unsubstituted C2 to C30 heteroaryl group having electron characteristics.

2. The compound for an organic optoelectronic device as claimed in claim 1, wherein the compound for an organic optoelectronic device is represented by the following Chemical Formula 2-1 or 2-2: 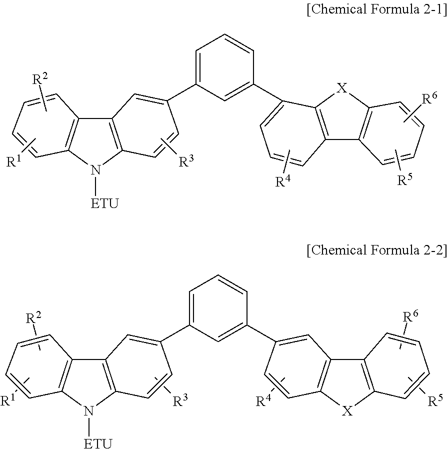
wherein, in the above Chemical Formulae 2-1 and 2-2,
X is S, O, or Se,
ETU is a substituted or unsubstituted C₂ to C₃₀ heteroaryl group having electron characteristics, and
R¹ to R⁶ are each independently hydrogen; deuterium; a substituted or unsubstituted C1 to C20 alkyl group; a substituted or unsubstituted C6 to C30 aryl group; or a substituted or unsubstituted C2 to C30 heteroaryl group having electron characteristics.

3. The compound for an organic optoelectronic device as claimed in claim 1, wherein the ETU is a substituted or unsubstituted imidazolyl group, a substituted or unsubstituted triazolyl group, a substituted or unsubstituted tetrazolyl group, a substituted or unsubstituted oxadiazolyl group, a substituted or unsubstituted oxatriazolyl group, a substituted or unsubstituted thiatriazolyl group, a substituted or unsubstituted benzimidazolyl group, a substituted or unsubstituted benzotriazolyl group, a substituted or unsubstituted pyridinyl group, a substituted or unsubstituted pyrimidinyl group, a substituted or unsubstituted triazinyl group, a substituted or unsubstituted pyrazinyl group, a substituted or unsubstituted pyridazinyl group, a substituted or unsubstituted purinyl group, a substituted or unsubstituted quinolinyl group, a substituted or unsubstituted isoquinolinyl group, a substituted or unsubstituted phthalazinyl group, a substituted or unsubstituted naphpyridinyl group, a substituted or unsubstituted quinazolinyl group, a substituted or unsubstituted acridinyl group, a substituted or unsubstituted phenanthrolinyl group, a substituted or unsubstituted phenazinyl group, or a combination thereof.

4. A compound for an organic optoelectronic device, the compound being represented by the following Chemical Formula 3: 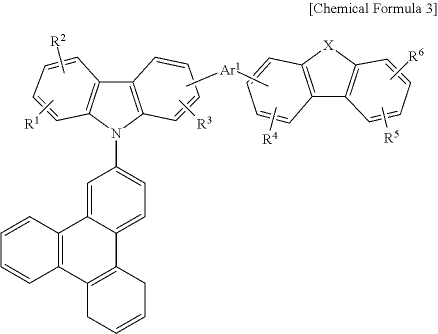
wherein, in the above Chemical Formula 3,
X is S, O, or Se,
Ar¹ is a substituted or unsubstituted C6 to C30 aryl group; or a substituted or unsubstituted C2 to C30 heteroaryl group, and
R¹ to R⁶ are each independently hydrogen; deuterium; a substituted or unsubstituted C1 to C20 alkyl group; a substituted or unsubstituted C6 to C30 aryl group; or a substituted or unsubstituted C2 to C30 heteroaryl group having electron characteristics.

5. The compound for an organic optoelectronic device as claimed in claim 4, wherein the Ar¹ is a substituted or unsubstituted pyridinylene group, a substituted or unsubstituted pyrimidinylene group, a substituted or unsubstituted triazinylene group, or a combination thereof.

6. The compound for an organic optoelectronic device as claimed in claim 4, wherein the Ar¹ is a substituted or unsubstituted pyridinylene group, and X is S.

7. The compound for an organic optoelectronic device as claimed in claim 4, wherein the compound for an organic optoelectronic device is represented by the following Chemical Formula 4-1 or 4-2: 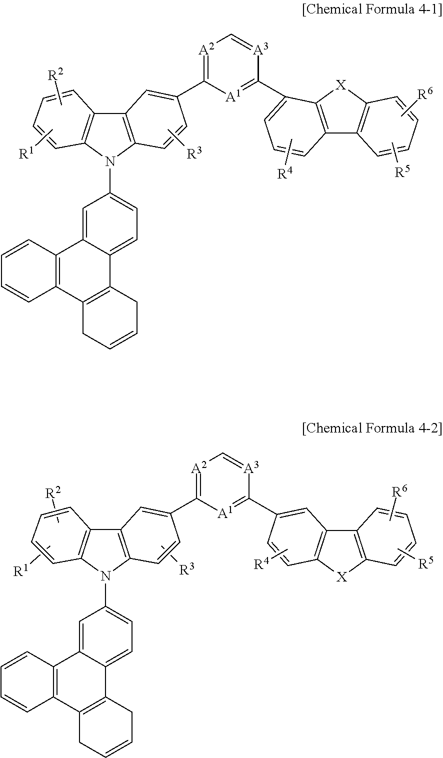
wherein, in the above Chemical Formulae 4-1 and 4-2,
X is S, O, or Se,
A¹ to A³ are each independently CR′ or a heteroatom, and
R′ and R¹ to R⁶ are each independently hydrogen; deuterium; a substituted or unsubstituted C1 to C20 alkyl group; a substituted or unsubstituted C6 to C30 aryl group; or a substituted or unsubstituted C2 to C30 heteroaryl group having electron characteristics.

8. The compound for an organic optoelectronic device as claimed in claim 7, wherein the A¹ to A³ are each independently CR′ or a nitrogen atom.

9. The compound for an organic optoelectronic device as claimed in claim 8, wherein at least one of A¹ to A³ is nitrogen.

10. The compound for an organic optoelectronic device as claimed in claim 1, wherein the organic optoelectronic device is selected from an organic photoelectric device, an organic light emitting diode, an organic solar cell, an organic transistor, an organic photo-conductor drum, and an organic memory device.

11. An organic light emitting diode, comprising:
an anode, a cathode, and at least one organic thin layer between the anode and the cathode,
wherein the at least one organic thin layer includes the compound for an organic optoelectronic device as claimed in claim 1.

12. The organic light emitting diode as claimed in claim 11, wherein the at least one organic thin layer is selected from an emission layer, a hole transport layer, a hole injection layer, an electron transport layer, an electron injection layer, a hole blocking layer, and a combination thereof.

13. The organic light emitting diode as claimed in claim 11, wherein the compound for an organic optoelectronic device is included in an electron transport layer or an electron injection layer.

14. The organic light emitting diode as claimed in claim 11, wherein the compound for an organic optoelectronic device is included in an emission layer.

15. The organic light emitting diode as claimed in claim 11, wherein the compound for an organic optoelectronic device is a phosphorescent or fluorescent host material in an emission layer.

16. The organic light emitting diode as claimed in claim 11, wherein the compound for an organic optoelectronic device is a fluorescent blue dopant material in an emission layer.

17. A display device comprising the organic light emitting diode as claimed in claim 11.

18. An organic light emitting diode, comprising:
an anode, a cathode, and at least one organic thin layer between the anode and the cathode,
wherein the at least one organic thin layer includes the compound for an organic optoelectronic device according to claim 4.

19. The organic light emitting diode as claimed in claim 18, wherein the at least one organic thin layer is selected from an emission layer, a hole transport layer, a hole injection layer, an electron transport layer, an electron injection layer, a hole blocking layer, and a combination thereof.

20. The organic light emitting diode as claimed in claim 18, wherein the compound for an organic optoelectronic device is included in an electron transport layer or an electron injection layer.

21. The organic light emitting diode as claimed in claim 18, wherein the compound for an organic optoelectronic device is included in an emission layer.

22. The organic light emitting diode as claimed in claim 18, wherein the compound for an organic optoelectronic device is a phosphorescent or fluorescent host material in an emission layer.

23. The organic light emitting diode as claimed in claim 18, wherein the compound for an organic optoelectronic device is a fluorescent blue dopant material in an emission layer.

24. A display device comprising the organic light emitting diode as claimed in claim 18.
